(19) United States
(12) Patent Application Publication
(10) Pub. No.: US 2025/0280655 A1
(43) Pub. Date: Sep. 4, 2025

(54) DISPLAY DEVICE, DISPLAY MODULE, ELECTRONIC DEVICE, AND A METHOD FOR MANUFACTURING DISPLAY DEVICE

(71) Applicant: Semiconductor Energy Laboratory Co., Ltd., Atsugi-shi (JP)

(72) Inventors: Daiki NAKAMURA, Atsugi (JP); Nozomu SUGISAWA, Isehara (JP); Toshiyuki ISA, Atsugi (JP); Yasumasa YAMANE, Atsugi (JP); Ryota HODO, Atsugi (JP); Kentaro SUGAYA, Isehara (JP)

(21) Appl. No.: 19/058,218

(22) Filed: Feb. 20, 2025

(30) Foreign Application Priority Data
Feb. 29, 2024 (JP) 2024-030328
Nov. 1, 2024 (JP) 2024-192652

(51) Int. Cl. H10K 50/19; H10K 50/17

(52) U.S. Cl. CPC H10K 50/19; H10K 50/17

(57) ABSTRACT

To provide a method for manufacturing a novel display device that is highly convenient, useful, or reliable, a display device includes a first light-emitting device including first and second electrodes, a first unit containing a first light-emitting material and having a first side surface, and a first layer containing a carrier-injection material; and a second light-emitting device including a third electrode adjacent to the first electrode, a fourth electrode, a second unit having a second side surface, and a second layer containing a carrier-injection material. The first layer has a higher concentration of the carrier-injection material than the first side surface because of a step of reducing the size of the outer shape of the first unit. The second layer has a higher concentration of the carrier-injection material than the second side surface because of a step of reducing the size of the outer shape of the second unit.

### BACKGROUND OF THE INVENTION

### 1. Field of the Invention

One embodiment of the present invention relates to a display device, a display module, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a data processing device, a semiconductor device, a memory device, a driving method thereof, and a manufacturing method thereof.

### 2. Description of the Related Art

In recent years, higher-resolution display panels have been required. Examples of devices that require high-resolution display panels include a smartphone, a tablet terminal, and a laptop computer. Furthermore, higher resolution has been required for a stationary display apparatus such as a television device or a monitor device along with an increase in definition. An example of a device absolutely required to have the highest resolution display panel is a device for virtual reality (VR) or augmented reality (AR).

Typical examples of a display device that can be used for a display panel include a liquid crystal display device, a light-emitting apparatus including a light-emitting element such as an organic EL (Electro Luminescence) element or a light-emitting diode (LED), and electronic paper performing display by an electrophoretic method or the like.

The organic EL element generally has a structure in which a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

Patent Document 2 discloses a display device for VR using an organic EL element.

### REFERENCES

### Patent Documents

[Patent Document 1] Japanese Published Patent Application No. 2002-324673
[Patent Document 2] PCT International Publication No. 2018/087625

### SUMMARY OF THE INVENTION

An object of one embodiment of the present invention is to provide a novel display device that is highly convenient, useful, or reliable. Another object is to provide a novel display module that is highly convenient, useful, or reliable. Another object is to provide a novel electronic device that is highly convenient, useful, or reliable. Another object is to provide a novel display device, a novel display module, a novel electronic device, or a novel semiconductor device.

Note that the description of these objects does not preclude the existence of other objects. One embodiment of the present invention does not need to achieve all of these objects. Note that other objects will be apparent from the description of the specification, the drawings, the claims, and the like, and other objects can be derived from the description of the specification, the drawings, the claims, and the like.
(1) One embodiment of the present invention is a method for manufacturing a display device including a first phase to a sixth phase.

In the first phase, a first electrode, a second electrode, and a first gap are formed over an insulating layer. The first gap is sandwiched between the first electrode and the second electrode.

In a first step of the second phase, a first film is formed over the first electrode and the second electrode.

In a second step of the second phase, a second film is formed over the first film.

In a third step of the second phase, a third film is formed over the second film.

In a fourth step of the second phase, a fourth film is formed over the third film.

In a fifth step of the second phase, the fourth film is removed from above the second electrode by a photolithography method to form a first layer overlapping with the first electrode.

In a sixth step of the second phase, the third film and the second film are removed from above the second electrode by an etching method using the first layer to form a second layer, a first unit, and a third layer. The second layer is sandwiched between the first layer and the first electrode, and the first unit is sandwiched between the second layer and the first electrode.

In a first step of the third phase, a fifth film is formed over the first layer and the second electrode.

In a second step of the third phase, a sixth film is formed over the fifth film.

In a third step of the third phase, a seventh film is formed over the sixth film.

In a fourth step of the third phase, an eighth film is formed over the seventh film.

In a fifth step of the third phase, the eighth film is removed from above the first layer by a photolithography method to form a fourth layer overlapping with the second electrode.

In a sixth step of the third phase, the seventh film and the sixth film are removed from the first layer and the first gap by an etching method using the fourth layer to form a fifth layer, a second unit, a sixth layer, and a second gap. Note that the fifth layer is sandwiched between the fourth layer and the second electrode, the second unit is sandwiched between the fifth layer and the second electrode, and the second gap overlaps with the first gap.

In a first step of the fourth phase, a ninth film is formed and then a photoresist is formed.

In a second step of the fourth phase, a seventh layer and an eighth layer are formed by an etching method using the photoresist. The seventh layer overlaps with the first electrode and has an outer shape smaller than an outer shape of the first layer. The eighth layer overlaps with the second electrode and has an outer shape smaller than an outer shape of the fourth layer.

In a third step of the fourth phase, by an etching method using the seventh layer and the eighth layer, the outer shape of the first layer and the outer shape of the fourth layer are made smaller.

In a fourth step of the fourth phase, by an etching method using the first layer and the fourth layer, the outer shape of each of the second layer, the fifth layer, the first unit, the second unit, the third layer, and the sixth layer is made smaller.

In a fifth step of the fourth phase, the first layer and the fourth layer are removed by an etching method.

In a first step of the fifth phase, a ninth layer is formed. Note that the ninth layer is in contact with the insulating layer in the first gap and covers the first unit and the second unit.

In a second step of the fifth phase, a tenth layer is formed. The tenth layer fills the first gap and the second gap. The tenth layer includes a first opening portion overlapping with the first electrode and a second opening portion overlapping with the second electrode.

In a third step of the fifth phase, by an etching method using the tenth layer, the ninth layer and the second layer overlapping with the first opening portion are removed, and the ninth layer and the fifth layer overlapping with the second opening portion are removed.

In a first step of the sixth phase, an eleventh layer is formed over the first unit and the second unit.

In a second step of the sixth phase, a conductive film is formed over the eleventh layer.

Thus, a carrier-injection material attached to a first side surface in the first step of the third phase can be removed in the fourth step of the fourth phase, for example. Moreover, current flowing between the first electrode and a third electrode through the first side surface can be reduced. Furthermore, current flowing between the second electrode and a fourth electrode through a second side surface can be reduced. Furthermore, current that does not contribute to light emission of a first or second light-emitting device can be reduced. In addition, the current efficiency of light emission of the display device can be increased. As a result, a method for manufacturing a novel display device that is highly convenient, useful, or reliable can be provided.
(2) Another embodiment of the present invention is the method for manufacturing a display device in which a tenth film is formed over the insulating layer in a first step of the first phase.

In a second step of the first phase, the first electrode, the second electrode, and the first gap are formed over the tenth film. Note that the first gap is sandwiched between the first electrode and the second electrode.

In the fifth step of the fourth phase, the first layer, the fourth layer, and the tenth film are removed by an etching method to form a twelfth layer, a thirteenth layer, and a third gap. The twelfth layer is sandwiched between the first electrode and the insulating layer. The thirteenth layer is sandwiched between the second electrode and the insulating layer. The third gap overlaps with the first gap.

Accordingly, in the fourth step of the fourth phase, the outer shape of each of the first unit and the second unit can be adjusted by etching treatment using an oxygen-containing gas. With the use of the ninth film, the insulating layer can be protected from the etching treatment using an oxygen-containing gas. Furthermore, even in the case where the ninth film has conductivity, the formation of the third gap can prevent electrical continuity between the first and second electrodes. As a result, a method for manufacturing a novel display device that is highly convenient, useful, or reliable can be provided.
(3) One embodiment of the present invention is a display device including a first light-emitting device, a second light-emitting device, and an insulating layer.

The first light-emitting device includes a first electrode, a second electrode, a first unit, and a first layer. The first electrode is over the insulating layer, the first unit is sandwiched between the first electrode and the second electrode, the first unit contains a first light-emitting material, and the first unit has a first side surface.

The first layer is sandwiched between the first electrode and the first unit, the first layer is in contact with the first electrode, the first layer contains a carrier-injection material, and the first layer has a higher concentration of the carrier-injection material than the first side surface.

The second light-emitting device includes a third electrode, a fourth electrode, a second unit, and a second layer. The third electrode is over the insulating layer, the third electrode is adjacent to the first electrode, and a first gap is between the third electrode and the first electrode. The second unit is sandwiched between the second layer and the fourth electrode, the second unit contains a second light-emitting material, a second gap is between the second unit and the first unit, and the second gap overlaps with the first gap. The second unit has a second side surface facing to the first side surface.

The second layer is sandwiched between the third electrode and the second unit, the second layer is in contact with the third electrode, a third gap is between the second layer and the first layer, and the third gap overlaps with the first gap. The second layer contains the carrier-injection material, and the second layer has a higher concentration of the carrier-injection material than the second side surface.

Accordingly, current flowing between the first and second electrodes through the first side surface can be reduced. Moreover, current flowing between the third and fourth electrodes through the second side surface can be reduced. Furthermore, current that does not contribute to light emission of the first or second light-emitting device can be reduced. In addition, the current efficiency of light emission of the display device can be increased. As a result, a novel display device that is highly convenient, useful, or reliable can be provided.
(4) Another embodiment of the present invention is the display device in which an etching rate of the insulating layer is lower than an etching rate of the first unit in etching treatment using an oxygen-containing gas.

Thus, the outer shapes of the first and second units can be adjusted by the etching treatment using an oxygen-containing gas. The carrier-injection material attached to the first or second side surface can be removed, so that the first or second side surface can be brought into a clean state. In addition, the insulating layer can be protected from the etching treatment using an oxygen-containing gas. As a result, a novel display device that is highly convenient, useful, or reliable can be provided.
(5) Another embodiment of the present invention is the display device including a third layer and a fourth layer.

The first electrode includes a region sandwiched between the first layer and the third layer, and the third electrode includes a region sandwiched between the second layer and the fourth layer.

The third layer includes a region sandwiched between the first electrode and the insulating layer, an etching rate of the third layer is lower than an etching rate of the first unit in etching treatment using an oxygen-containing gas, and the third layer has conductivity.

The fourth layer includes a region sandwiched between the third electrode and the insulating layer, the fourth layer is adjacent to the third layer, and a fourth gap is between the fourth layer and the third layer. The fourth layer contains a material identical to a material of the third layer.

Thus, the outer shapes of the first and second units can be adjusted by the etching treatment using an oxygen-containing gas. The carrier-injection material attached to the first or second side surface can be removed, so that the first or second side surface can be brought into a clean state. In addition, the insulating layer can be protected from the etching treatment using an oxygen-containing gas. Furthermore, electrical continuity between the first and third electrodes can be prevented using the fourth gap. As a result, a novel display device that is highly convenient, useful, or reliable can be provided.
(6) Another embodiment of the present invention is the display device including a fifth layer, a sixth layer, and a conductive film.

The fifth layer overlaps with the first gap, and the fifth layer is in contact with the insulating layer. The fifth layer includes a first opening portion and a second opening portion, the first opening portion overlaps with the first electrode, and the second opening portion overlaps with the third electrode.

The sixth layer fills the first gap and the second gap, and the sixth layer is sandwiched between the conductive film and the fifth layer. The sixth layer includes a third opening portion and a fourth opening portion, the third opening portion overlaps with the first electrode, and the fourth opening portion overlaps with the third electrode. The conductive film includes the second electrode and the fourth electrode.
(7) Another embodiment of the present invention is a display module including the above-described display device and at least one of a connector and an integrated circuit.
(8) Another embodiment of the present invention is an electronic device including the above-described display device and at least one of a battery, a camera, a speaker, and a microphone.

One embodiment of the present invention can provide a novel display device that is highly convenient, useful, or reliable. Alternatively, a novel display module that is highly convenient, useful, or reliable can be provided. Alternatively, a novel electronic device that is highly convenient, useful, or reliable can be provided. Alternatively, a novel display device, a novel display module, a novel electronic device, or a novel semiconductor device can be provided.

Note that the description of these effects does not preclude the existence of other effects. Note that one embodiment of the present invention does not need to have all the effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

In the accompanying drawings:

FIGS. 1A to 1C illustrate a structure of a display device of an embodiment;

FIGS. 2A and 2B illustrate structures of a display device of an embodiment;

FIGS. 3A and 3B illustrate a structure of a display device of an embodiment;

FIGS. 4A and 4B illustrate a structure of a display device of an embodiment;

FIGS. 5A and 5B illustrate structures of a display device of an embodiment;

FIG. 6 is a flow chart showing a manufacturing method of a display device of an embodiment;

FIG. 7 illustrates the manufacturing method of the display device of an embodiment;

FIG. 8 illustrates the manufacturing method of the display device of an embodiment;

FIG. 9 illustrates the manufacturing method of the display device of an embodiment;

FIG. 10 illustrates the manufacturing method of the display device of an embodiment;

FIG. 11 illustrates the manufacturing method of the display device of an embodiment;

FIG. 12 illustrates the manufacturing method of the display device of an embodiment;

FIG. 13 illustrates the manufacturing method of the display device of an embodiment;

FIG. 14 illustrates the manufacturing method of the display device of an embodiment;

FIG. 15 illustrates the manufacturing method of the display device of an embodiment;

FIG. 16 illustrates the manufacturing method of the display device of an embodiment;

FIG. 17 illustrates the manufacturing method of the display device of an embodiment;

FIG. 18 illustrates the manufacturing method of the display device of an embodiment;

FIG. 19 illustrates the manufacturing method of the display device of an embodiment;

FIG. 20 illustrates the manufacturing method of the display device of an embodiment;

FIG. 21 illustrates the manufacturing method of the display device of an embodiment;

FIG. 22 illustrates the manufacturing method of the display device of an embodiment;

FIG. 23 illustrates the manufacturing method of the display device of an embodiment;

FIG. 24 illustrates the manufacturing method of the display device of an embodiment;

FIGS. 25A and 25B illustrate a structure of a display module of an embodiment;

FIGS. 26A to 26E illustrate structures of the display device of an embodiment;

FIG. 27 illustrates a structure of a display device of an embodiment;

FIGS. 28A and 28B illustrate a structure of the display device of an embodiment;

FIG. 29 illustrates a structure of a display device of an embodiment;

FIG. 30 illustrates a structure of a display device of an embodiment;

FIG. 31 illustrates a structure of a display device of an embodiment;

FIG. 32 illustrates a structure of a display device of an embodiment;

FIG. 33 illustrates a structure of a display device of an embodiment;

FIGS. 34A to 34C illustrate a structure of the display device of an embodiment;

FIG. 35 illustrates a structure of a display device of an embodiment;

FIGS. 36A to 36D illustrate structures of a display device of an embodiment;

FIGS. 37A to 37E illustrate structures of the display device of an embodiment;

FIG. 38 illustrates a structure of a display device of an embodiment;

FIGS. 39A to 39D illustrate structures of electronic devices of an embodiment;

FIGS. 40A to 40F illustrate structures of electronic devices of an embodiment;

FIGS. 41A to 41G illustrate structures of electronic devices of an embodiment;

FIGS. 42A to 42C illustrate a structure of a workpiece of Example;

FIG. 43 is a graph showing current density-luminance characteristics of light-emitting devices of Example;

FIG. 44 is a graph showing luminance-current efficiency characteristics of the light-emitting devices of Example;

FIG. 45 is a graph showing voltage-luminance characteristics of the light-emitting devices of Example;

FIG. 46 is a graph showing voltage-current density characteristics of the light-emitting devices of Example;

FIG. 47 is a graph showing emission spectra of the light-emitting devices of Example;

FIG. 48 illustrates a structure of a workpiece of Example;

FIG. 49 shows current density-luminance characteristics of light-emitting devices of Example;

FIG. 50 shows luminance-current efficiency characteristics of the light-emitting devices of Example;

FIG. 51 shows voltage-luminance characteristics of the light-emitting devices of Example;

FIG. 52 shows voltage-current density characteristics of the light-emitting devices of Example;

FIG. 53 shows emission spectra of the light-emitting devices of Example;

FIG. 54 shows voltage-current density characteristics of the light-emitting devices of Example;

FIG. 55 shows current density-current efficiency characteristics of the light-emitting devices fabricated in this example;

FIG. 56 shows current density-external quantum efficiency characteristics of the light-emitting devices fabricated in this example; and

FIG. 57 shows luminance-blue index characteristics of the light-emitting device fabricated in this example.

### DETAILED DESCRIPTION OF THE INVENTION

The method for manufacturing the display device of one embodiment of the present invention is a method for manufacturing the display device in which a first light-emitting device, a second light-emitting device, and an insulating layer are included. The first light-emitting device includes a first electrode, a second electrode, a first unit, and a first layer. The first electrode is formed over the insulating layer. The first unit is sandwiched between the first electrode and the second electrode. The first unit contains a first light-emitting material. The first unit has a first side surface. The first layer is sandwiched between the first electrode and the first unit. The first layer is in contact with the first electrode. The first layer contains a carrier-injection material. The first layer has a higher concentration of the carrier-injection material than the first side surface because a step of reducing the size of the outer shape of the first unit is included. The second light-emitting device includes a third electrode, a fourth electrode, a second unit, and a second layer. The third electrode is formed over the insulating layer. The third electrode is adjacent to the first electrode. A first gap is provided between the third electrode and the first electrode. The second unit is sandwiched between the second layer and the fourth electrode. The second unit contains a second light-emitting material. A second gap is provided between the second unit and the first unit. The second gap overlaps with the first gap. The second unit has a second side surface facing to the first side surface. The second layer is sandwiched between the third electrode and the second unit. The second layer is in contact with the third electrode. A third gap is provided between the second layer and the first layer. The third gap overlaps with the first gap. The second layer contains the carrier-injection material. The second layer has a higher concentration of the carrier-injection material than the second side surface because a step of reducing the size of the outer shape of the second unit is included.

Accordingly, current flowing between the first and second electrodes through the first side surface can be reduced. Moreover, current flowing between the third and fourth electrodes through the second side surface can be reduced. Furthermore, current that does not contribute to light emission of the first or second light-emitting device can be reduced. In addition, the current efficiency of light emission of the display device can be increased. As a result, a novel display device that is highly convenient, useful, or reliable can be provided.

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

Although a block diagram in which components are classified by their functions and shown as independent blocks is shown in the drawing attached to this specification, it is difficult to completely separate actual components according to their functions and one component can relate to a plurality of functions.

### Embodiment 1

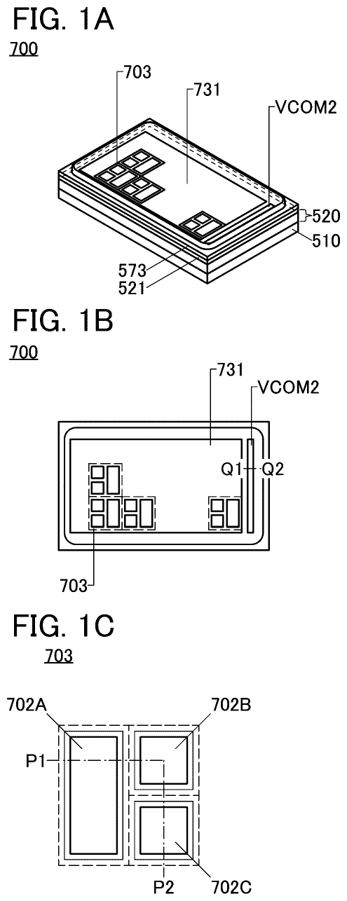

In this embodiment, a display device of one embodiment of the present invention will be described with reference to FIGS. 1A to 1C, FIGS. 2A and 2B, FIGS. 3A and 3B, FIGS. 4A and 4B, and FIGS. 5A and 5B.

FIG. 1A is a perspective view illustrating a structure of the display device of one embodiment of the present invention. FIG. 1B is a front view of FIG. 1A, and FIG. 1C is a front view illustrating part of FIG. 1A.

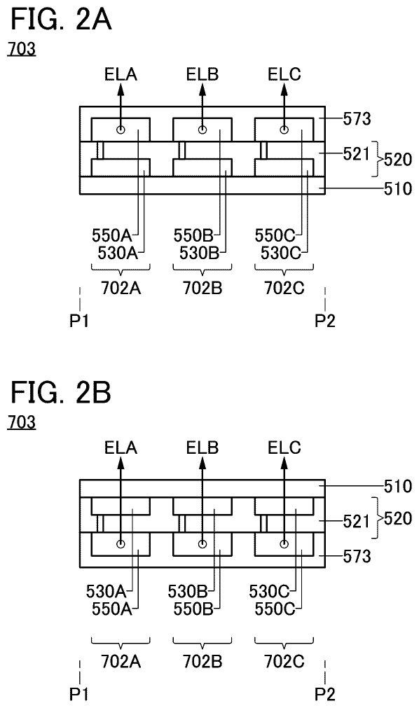

FIG. 2A is a cross-sectional view illustrating a structure of the display device of one embodiment of the present invention along a cutting line P1-P2 in FIG. 1C, and FIG. 2B is a cross-sectional view illustrating a structure different from that in FIG. 2A.

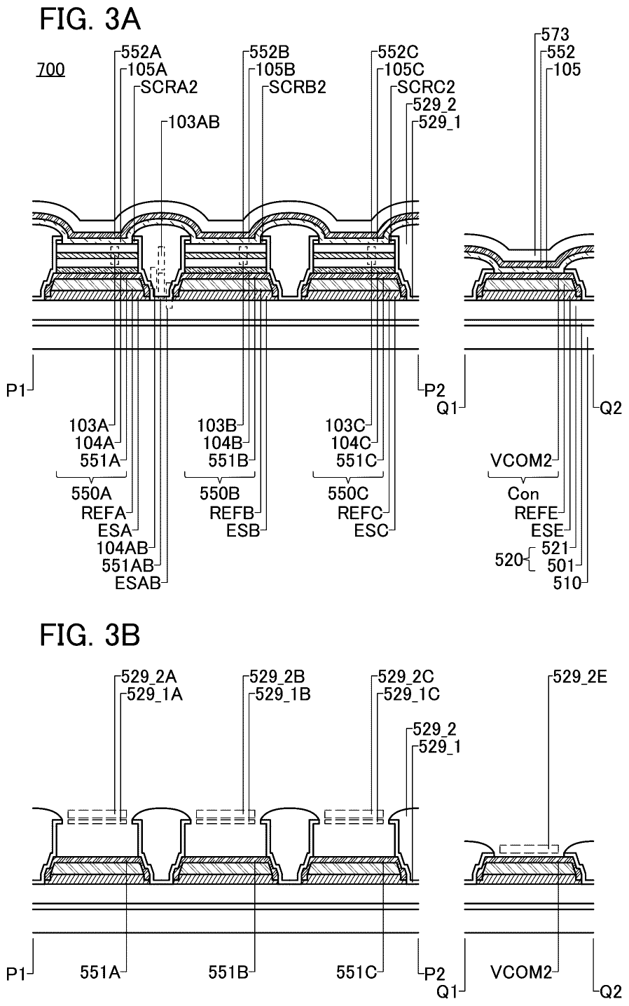

FIG. 3A is a cross-sectional view illustrating a structure of the display device of one embodiment of the present invention along the cutting line P1-P2 in FIG. 1C and a cutting line Q1-Q2 in FIG. 1B, and FIG. 3B is a cross-sectional view illustrating part of FIG. 3A.

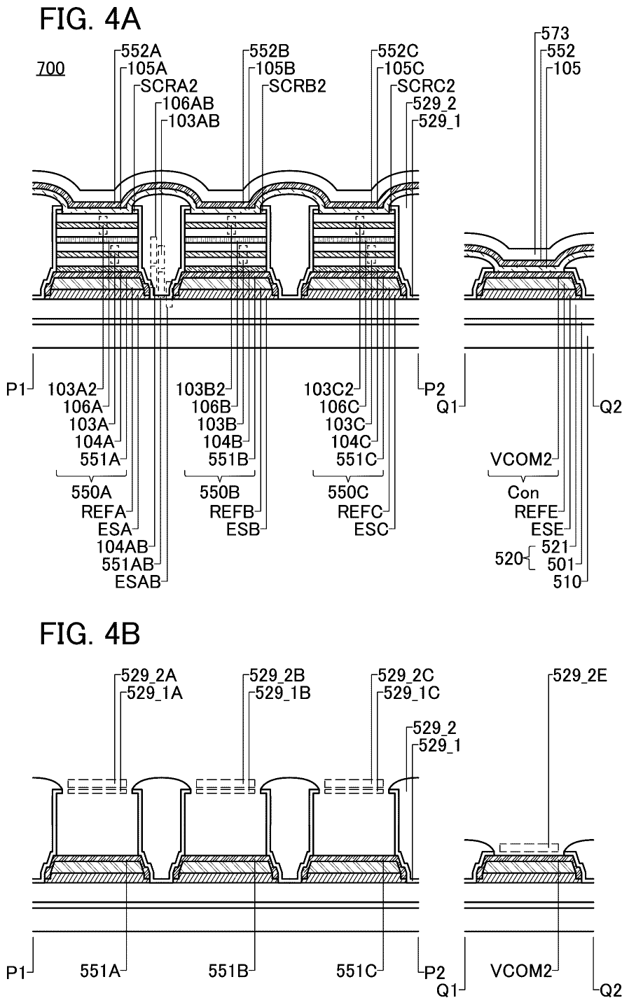

FIG. 4A is a cross-sectional view illustrating a structure different from that in FIG. 3A. FIG. 4B is a cross-sectional view illustrating part of FIG. 4A.

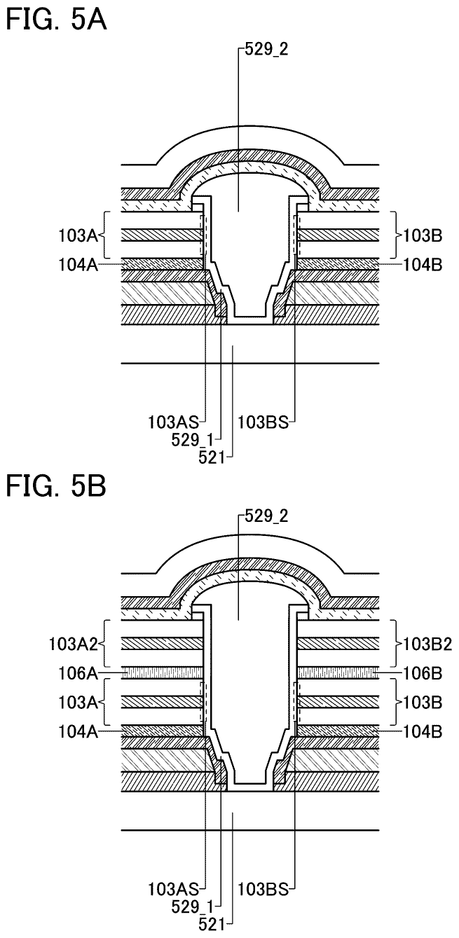

FIG. 5A is a cross-sectional view illustrating part of FIG. 3A, and FIG. 5B is a cross-sectional view illustrating part of FIG. 4A.

### <Structure Example 1 of Display Device>

A display device 700 described in this embodiment includes a display region 731 and a conductive layer VCOM2 (see FIGS. 1A and 1B).

The display region 731 includes a pixel set 703. The pixel set 703 includes pixels 702A, 702B, and 702C (see FIG. 1C).

The pixel 702A includes a light-emitting device 550A and a pixel circuit 530A. The light-emitting device 550A is connected to the pixel circuit 530A (see FIGS. 2A and 2B). Note that in this specification, the term “connection” includes “electrical connection”.

The expression “A and B are electrically connected” means that, in the case where A and B are connected not through an insulator (i.e., connected through a conductor or a semiconductor or in contact with each other), transmission and reception of an electric signal or interaction of a potential occurs between A and B in a certain period in operation of a circuit including A and B. In other words, even when the circuit operation has a period during which neither transmission and reception of an electric signal nor interaction of a potential occurs between A and B, the expression “A and B are electrically connected” can be used as long as transmission and reception of an electric signal or interaction of a potential occurs between A and B in another period.

The pixel 702B includes a light-emitting device 550B and a pixel circuit 530B. The light-emitting device 550B is electrically connected to the pixel circuit 530B.

The pixel 702C includes a light-emitting device 550C and a pixel circuit 530C. The light-emitting device 550C is electrically connected to the pixel circuit 530C.

The conductive layer VCOM2 is electrically connected to the light-emitting devices 550A, 550B, and 550C and supplies a common potential.

The display device 700 includes a functional layer 520, a substrate 510, and a layer 573.

The functional layer 520 includes an insulating layer 521. The insulating layer 521 is sandwiched between the light-emitting device 550A and the pixel circuit 530A and has an insulating property.

The functional layer 520 includes the pixel circuits 530A, 530B, and 530C. The pixel circuit 530A is sandwiched between the light-emitting device 550A and the substrate 510, the pixel circuit 530B is sandwiched between the light-emitting device 550B and the substrate 510, and the pixel circuit 530C is sandwiched between the light-emitting device 550C and the substrate 510.

The layer 573 includes an overlap region overlapping with the insulating layer 521, and the overlap region includes the display region 731 (see FIG. 1A). Note that the light-emitting device 550A is sandwiched between the layer 573 and the insulating layer 521. For example, a material that transmits light emitted from the light-emitting device and has a refractive index higher than or equal to 1.8 can be used for the layer 573. A film through which an impurity such as water or oxygen does not easily pass can be used as the layer 573. Specifically, a film containing nitrogen and silicon can be used as the layer 573.

In the display device 700 of one embodiment of the present invention, for example, the light-emitting device 550A emits light ELA in a direction where the pixel circuit 530A is not provided, the light-emitting device 550B emits light ELB in a direction where the pixel circuit 530B is not provided, and the light-emitting device 550C emits light ELC in a direction where the pixel circuit 530C is not provided (see FIG. 2A). In other words, the display device 700 of one embodiment of the present invention is a top-emission display device.

Alternatively, in the display device 700 of one embodiment of the present invention, for example, the light-emitting device 550A emits the light ELA in a direction where the pixel circuit 530A is provided, the light-emitting device 550B emits the light ELB in a direction where the pixel circuit 530B is provided, and the light-emitting device 550C emits the light ELC in a direction where the pixel circuit 530C is provided (see FIG. 2B). In other words, the display device 700 of one embodiment of the present invention is a bottom-emission display device.

### <Structure Example 2 of Display Device>

The display device 700 described in this embodiment includes the light-emitting devices 550A, 550B, and 550C and the insulating layer 521 (see FIG. 3A).

For example, the light-emitting devices 550A, 550B, and 550C can emit blue light, green light, and red light, respectively. Thus, a side-by-side display device can be provided. A display device with high current efficiency can also be provided.

Alternatively, for example, a structure can be employed where the light-emitting devices 550A, 550B, and 550C emit white light; a coloring layer that transmits blue light is provided to overlap with the light-emitting device 550A; a coloring layer that transmits green light is provided to overlap with the light-emitting device 550B; and a coloring layer that transmits red light is provided to overlap with the light-emitting device 550C.

Alternatively, for example, a structure can be employed where the light-emitting devices 550A, 550B, and 550C emit blue light; a layer that converts blue light into green light is provided to overlap with the light-emitting device 550B; and a layer that converts blue light into red light is provided to overlap with the light-emitting device 550C.

The display device 700 includes the conductive layer VCOM2, a layer ESE, a conductive film 552, a layer 105, and the functional layer 520 (see FIG. 3A).

A layer REFE can be provided between the conductive layer VCOM2 and the insulating layer 521. For example, a material that can be used for a layer REFA described later can be used for the layer REFE. The conductive layer VCOM2 includes a region sandwiched between the conductive film 552 and the layer ESE. For example, a material that can be used for a layer ESA described later can be used for the layer ESE.

The conductive film 552 is electrically connected to the conductive layer VCOM2 in a connection portion Con. Note that the conductive film 552 includes electrodes 552A, 552B, and 552C. The layer 105 includes layers 105A, 105B, and 105C.

The functional layer 520 includes an insulating layer 501, a pixel circuit, and the insulating layer 521. Note that the pixel circuit is sandwiched between the insulating layers 501 and 521.

### <<Structure Example 1 of Light-Emitting Device 550A>>

The light-emitting device 550A includes an electrode 551A, the electrode 552A, a unit 103A, and a layer 104A. The electrode 551A is formed over the insulating layer 521. Note that the layer REFA can be provided between the electrode 551A and the insulating layer 521. For example, a layer containing aluminum or a layer containing silver can be used as the layer REFA. Thus, light emitted from the light-emitting device 550A toward the layer REFA can be efficiently reflected.

### [Structure Example 1 of Unit 103A]

The unit 103A is sandwiched between the electrode 551A and the electrode 552A, and the unit 103A contains a light-emitting material EMA. For example, a fluorescent substance, a phosphorescent substance, or a substance exhibiting thermally activated delayed fluorescence can be used as the light-emitting material EMA. The unit 103A has a side surface 103AS (see FIG. 5A). The unit 103A can have a stacked-layer structure. For example, a layer having a hole-transport property, a layer containing the light-emitting material EMA, and a layer having an electron-transport property can be used as the unit 103A. Note that the layer containing the light-emitting material EMA is preferably provided in a region where holes and electrons are recombined. For example, the layer having a hole-transport property is provided closer to the anode than the layer containing the light-emitting material EMA is, and the layer having an electron-transport property is provided closer to the cathode than the layer containing the light-emitting material EMA is. This allows efficient conversion of energy generated by recombination of carriers into light and emission of the light.

### [Structure Example of Layer 104A]

The layer 104A is sandwiched between the electrode 551A and the unit 103A, and the layer 104A is in contact with the electrode 551A (see FIG. 3A). The layer 104A contains a carrier-injection material CIM, and the layer 104A has a higher concentration of the carrier-injection material CIM than the side surface 103AS (see FIG. 5A).

### [Example 1 of Carrier-Injection Material CIM]

For example, in the case where the electrode 551A functions as an anode, a hole-injection material can be used as the carrier-injection material CIM. Accordingly, the layer 104A can receive holes from the electrode 551A and transfer them to the unit 103A.

For example, a material having a hole mobility lower than or equal to 1×10⁻³ cm²/Vs when the square root of the electric field strength V/cm is 600 can be used for the layer 104A. A film having an electrical resistivity greater than or equal to 1×10⁴ Ω·cm and less than or equal to 1×10⁷ Ω·cm can be used as the layer 104A. The electrical resistivity of the layer 104A is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

Specifically, an electron-accepting substance can be used for the layer 104A. Alternatively, a composite material containing a plurality of kinds of substances can be used for the layer 104A.

An organic compound or an inorganic compound can be used as the electron-accepting substance. The electron-accepting substance can extract electrons from an adjacent hole-transport layer or a hole-transport material by application of an electric field.

For example, a compound having an electron-withdrawing group (a halogen group or a cyano group) can be used as the electron-accepting substance. Note that an organic compound having an electron-accepting property is easily evaporated, which facilitates film formation.

### [Example 2 of Carrier-Injection Material CIM]

In the case where the electrode 551A functions as a cathode, an electron-injection material can be used as the carrier-injection material CIM. Thus, the layer 104A can receive electrons from the electrode 551A and transfer them to the unit 103A.

Specifically, an electron-donating substance can be used for the layer 104A. Alternatively, a material in which an electron-donating substance and an electron-transport material are combined can be used for the layer 104A. Alternatively, electride can be used for the layer 104A.

For example, an alkali metal, an alkaline earth metal, a rare earth metal, or a compound thereof (an oxide, a halide, a carbonate, or the like) can be used as the electron-donating substance. Alternatively, an organic compound such as tetrathianaphthacene (abbreviation: TTN), nickelocene, or decamethylnickelocene can be used as the electron-donating substance.

### [Structure Example of Layer 105A]

The layer 105A is sandwiched between the electrode 552A and the unit 103A, and the layer 105A is in contact with the electrode 552A (see FIG. 3A). The layer 105A contains a carrier-injection material.

For example, in the case where the electrode 552A functions as a cathode, an electron-injection material can be used for the layer 105A. Thus, the layer 105A can receive electrons from the electrode 552A and transfer them to the unit 103A.

For example, in the case where the electrode 552A functions as an anode, a hole-injection material can be used for the layer 105A. Accordingly, the layer 105A can receive holes from the electrode 552A and transfer them to the unit 103A.

### <<Structure Example 1 of Light-Emitting Device 550B>>

The light-emitting device 550B includes an electrode 551B, the electrode 552B, a unit 103B, and a layer 104B (see FIG. 3A).

The electrode 551B is formed over the insulating layer 521. The electrode 551B is adjacent to the electrode 551A, and a gap 551AB is provided between the electrodes 551B and 551A. Note that a layer REFB can be provided between the electrode 551B and the insulating layer 521. For example, the material that can be used for the layer REFA can be used for the layer REFB.

### [Structure Example 1 of Unit 103B]

The unit 103B is sandwiched between the layer 104B and the electrode 552B, and the unit 103B contains a light-emitting material EMB. Note that the material that can be used as the light-emitting material EMA can be used as the light-emitting material EMB. For example, a material that emits light with a hue different from that of light emitted from the light-emitting material EMA can be used as the light-emitting material EMB.

A gap 103AB is provided between the units 103B and 103A. The gap 103AB overlaps with the gap 551AB. The unit 103B has a side surface 103BS (see FIG. 5A). The side surface 103BS faces the side surface 103AS.

### [Structure Example of Layer 104B]

The layer 104B is sandwiched between the electrode 551B and the unit 103B, and the layer 104B is in contact with the electrode 551B (see FIG. 3A). A gap 104AB is provided between the layers 104B and 104A, and the gap 104AB overlaps with the gap 551AB. The layer 104B contains the carrier-injection material CIM, and the layer 104B has a higher concentration of the carrier-injection material CIM than the side surface 103BS (see FIG. 5A). Note that a carrier-injection material that can be used for the layer 104A can be used for the layer 104B. For example, the concentration of the carrier-injection material CIM contained in the layer 104B is preferably higher than or equal to 10 times, further preferably higher than or equal to 100 times, still further preferably higher than or equal to 1000 times the concentration of the carrier-injection material CIM observed on the side surface 103BS.

### [Structure Example of Layer 105B]

The layer 105B is sandwiched between the electrode 552B and the unit 103B, and the layer 105B is in contact with the electrode 552B (see FIG. 3A). The layer 105B contains a carrier-injection material and a material that can be used for the layer 105A.

Accordingly, current flowing between the electrodes 551A and 552A through the side surface 103AS can be reduced. Furthermore, current flowing between the electrodes 551B and 552B through the side surface 103BS can be reduced. Furthermore, current that does not contribute to light emission of the light-emitting device 550A or 550B can be reduced. In addition, the current efficiency of light emission of the display device can be increased. As a result, a novel display device that is highly convenient, useful, or reliable can be provided.

### <<Structure Example 1 of Light-Emitting Device 550C>>

The light-emitting device 550C includes an electrode 551C, the electrode 552C, a unit 103C, and a layer 104C (see FIG. 3A). The electrode 551B is formed over the insulating layer 521. Note that a layer REFC can be provided between the electrode 551C and the insulating layer 521. For example, the material that can be used for the layer REFA can be used for the layer REFC.

### [Structure Example 1 of Unit 103C]

The unit 103C is sandwiched between the layer 104C and the electrode 552C, and the unit 103C contains a light-emitting material. Note that the material that can be used as the light-emitting material EMA can be used for the unit 103C. For example, a material that emits light with a hue different from that of light emitted from the light-emitting material EMA can be used for the unit 103C.

### [Structure Example of Layer 104C]

The layer 104C is sandwiched between the electrode 551C and the unit 103C, and the layer 104C is in contact with the electrode 551C (see FIG. 3A). Note that the carrier-injection material that can be used for the layer 104A can be used for the layer 104C.

### [Structure Example of Layer 105C]

The layer 105C is sandwiched between the electrode 552C and the unit 103C, and the layer 105C is in contact with the electrode 552C (see FIG. 3A). The layer 105C contains a carrier-injection material and a material that can be used for the layer 105A.

### [Structure Example of Insulating Layer 521]

The etching rate of the insulating layer 521 is lower than that of the unit 103A in etching treatment using an oxygen-containing gas. For example, silicon oxide, silicon nitride, aluminum oxide, or zirconium oxide can be used for the insulating layer 521.

Thus, the outer shapes of the units 103A and 103B can be adjusted by the etching treatment using an oxygen-containing gas. The carrier-injection material CIM attached to the side surface 103AS or 103BS can be removed, so that the side surface 103AS or 103BS can be brought into a clean state. The insulating layer 521 can be protected from the etching treatment using an oxygen-containing gas. As a result, a novel display device that is highly convenient, useful, or reliable can be provided.

### <Structure Example 3 of Display Device>

The display device 700 described in this embodiment includes the layer ESA, a layer ESB, and a layer ESC (see FIG. 3A). Note that the electrode 551A includes a region sandwiched between the layers 104A and ESA, and the electrode 551B includes a region sandwiched between the layers 104B and ESB. The electrode 551C includes a region sandwiched between the layers 104C and ESC.

The layer ESA includes a region sandwiched between the electrode 551A and the insulating layer 521, and an etching rate of the layer ESA is lower than that of the unit 103A in the etching treatment using an oxygen-containing gas. The layer ESA has conductivity.

The layer ESB includes a region sandwiched between the electrode 551B and the insulating layer 521, the layer ESB is adjacent to the layer ESA, and a gap ESAB is provided between the layers ESB and ESA. The layer ESB contains the same material as the layer ESA.

For example, tungsten, molybdenum, aluminum, titanium, or tantalum can be used for the layers ESA, ESB, and ESC. For example, indium oxide-tin oxide (abbreviation: ITO), indium oxide-tin oxide containing silicon or silicon oxide (abbreviation: ITSO), indium oxide-zinc oxide (registered trademark: IZO), indium oxide-gallium oxide-zinc oxide (abbreviation: IGZO), and aluminum oxide-zinc oxide (abbreviation: AZO) can be used for the layers ESA, ESB, and ESC.

Thus, the outer shapes of the units 103A and 103B can be adjusted by the etching treatment using an oxygen-containing gas. The carrier-injection material CIM attached to the side surface 103AS or 103BS can be removed, so that the side surface 103AS or 103BS can be brought into a clean state. The insulating layer 521 can be protected from the etching treatment using an oxygen-containing gas. Furthermore, electrical continuity between the electrodes 551A and 551B can be prevented using the gap ESAB. As a result, a novel display device that is highly convenient, useful, or reliable can be provided.

### <Structure Example 4 of Display Device>

The display device 700 described in this embodiment includes layers 529_1 and 529_2 and the conductive film 552 (see FIG. 3A). The layer 529_1 overlaps with the gap 551AB, and the layer 529_1 is in contact with the insulating layer 521.

The layer 529_1 includes opening portions 529_1A and 529_1B (see FIG. 3B). The opening portions 529_1A and 529_1B overlap with the electrodes 551A and 551B, respectively.

The layer 5292 fills the gaps 551AB and 103AB (see FIG. 3A). The layer 5292 is sandwiched between the conductive film 552 and the layer 529_1 (see FIG. 5A).

The layer 5292 includes opening portions 529_2A and 529_2B (see FIG. 3B). The opening portions 529_2A and 529_2B overlap with the electrodes 551A and 551B, respectively. Note that the conductive film 552 includes the electrodes 552A and 552B (see FIG. 3A).

The display device 700 includes layers SCRA2, SCRB2, and SCRC2. The layer SCRA2 is sandwiched between the layer 529_1 and the unit 103A, the layer SCRB2 is sandwiched between the layer 529_1 and the unit 103B, and the layer SCRC2 is sandwiched between the layer 529_1 and the unit 103C.

### <Structure Example 5 of Display Device>

The display device 700 of this embodiment described with reference to FIGS. 4A, 4B, and 5B is different from the display device described with reference to FIGS. 3A, 3B, and 5A in structures of the light-emitting devices 550A and 550B. Here, different parts will be described in detail, and the above description is referred to for similar parts.

### <<Structure Example 2 of Light-Emitting Device 550A>>

The light-emitting device 550A includes the electrodes 551A and 552A, the unit 103A, an intermediate layer 106A, a unit 103A2, and the layer 104A (see FIG. 4A). Note that the electrode 551A is formed over the insulating layer 521.

In other words, the light-emitting device 550A includes the stacked units between the electrodes 551A and 552A. The number of stacked units is not limited to two and may be three or more. A structure including the stacked units sandwiched between the electrodes 551A and 552A and the intermediate layer 106A sandwiched between the units is referred to as a stacked light-emitting device or a tandem light-emitting device in some cases.

This structure can provide light emission at high luminance while the current density is kept low. Alternatively, the reliability can be improved. Alternatively, the driving voltage can be reduced in comparison with that of the light-emitting device with the same luminance. Alternatively, the power consumption can be reduced.

### [Structure Example 2 of Unit 103A]

The unit 103A is sandwiched between the electrodes 551A and 552A, and the unit 103A contains the light-emitting material EMA. For example, a fluorescent substance, a phosphorescent substance, or a substance exhibiting thermally activated delayed fluorescence can be used as the light-emitting material EMA. The unit 103A has the side surface 103AS (see FIG. 5B).

### [Structure Example of Unit 103A2]

The unit 103A2 is sandwiched between the unit 103A and the electrode 552A, and the unit 103A2 contains a light-emitting material (see FIG. 4A). Note that the material that can be used as the light-emitting material EMA can be used for the unit 103A2. For example, the same material can be used for the units 103A and 103A2. A material that emits light with a hue which is the same as that of light emitted from the light-emitting material EMA can be used for the unit 103A2. A material that emits light with a hue different from that of light emitted from the light-emitting material EMA can also be used for the unit 103A2.

### [Example of Intermediate Layer 106A]

The intermediate layer 106A has a function of supplying electrons to the anode side and supplying holes to the cathode side when voltage is applied. The intermediate layer 106A can be referred to as a charge-generation layer.

The intermediate layer 106A is sandwiched between the units 103A2 and 103A. The intermediate layer 106A has a function of injecting holes to one of the units 103A2 and 103A and injecting electrons to the other. For example, in the case where the electrode 552A functions as a cathode, the intermediate layer 106A supplies holes to the unit 103A2 and supplies electrons to the unit 103A. For example, in the case where the electrode 552A functions as an anode, the intermediate layer 106A supplies electrons to the unit 103A2 and supplies holes to the unit 103A.

For example, a stacked-layer film can be used as the intermediate layer 106A. Specifically, a stacked-layer film of a film containing a hole-injection material and a film containing an electron-injection material can be used as the intermediate layer 106A. A stacked-layer film in which a film containing a material having a LUMO level in the range of higher than or equal to −5.0 eV, preferably higher than or equal to −5.0 eV and lower than or equal to −3.0 eV is positioned between the film containing a hole-injection material and the film containing an electron-injection material can be used as the intermediate layer 106A.

### <<Structure Example 2 of Light-Emitting Device 550B>>

The light-emitting device 550B includes the electrodes 551B and 552B, the unit 103B, an intermediate layer 106B, a unit 103B2, and the layer 104B (see FIG. 4A).

### [Structure Example 2 of Unit 103B]

The unit 103B is sandwiched between the layer 104B and the electrode 552B, and the unit 103B contains the light-emitting material EMB. Note that the material that can be used as the light-emitting material EMA can be used as the light-emitting material EMB. For example, a material that emits light with a hue different from that of light emitted from the light-emitting material EMA can be used as the light-emitting material EMB.

The gap 103AB is provided between the units 103B and 103A. The gap 103AB overlaps with the gap 551AB. The unit 103B has the side surface 103BS (see FIG. 5B). The side surface 103BS faces the side surface 103AS.

### [Structure Example of Unit 103B2]

The unit 103B2 is sandwiched between the unit 103B and the electrode 552B, and the unit 103B2 contains a light-emitting material (see FIG. 4A). Note that a material that can be used as the light-emitting material EMB can be used for the unit 103B2. For example, the same material can be used for the units 103B and 103B2. A material that emits light with a hue which is the same as that of light emitted from the light-emitting material EMB can be used for the unit 103B2. A material that emits light with a hue different from that of light emitted from the light-emitting material EMB can be used for the unit 103B2.

### [Structure Example of Intermediate Layer 106B]

The intermediate layer 106B is sandwiched between the units 103B2 and 103B. The intermediate layer 106B has a function of injecting holes to one of the units 103B2 and 103B and injecting electrons to the other. For example, in the case where the electrode 552B functions as a cathode, the intermediate layer 106B supplies holes to the unit 103B2 and supplies electrons to the unit 103B. For example, in the case where the electrode 552B functions as an anode, the intermediate layer 106B supplies electrons to the unit 103B2 and supplies holes to the unit 103B.

For example, a material that can be used for the intermediate layer 106A can be used for the intermediate layer 106B.

A gap 106AB is provided between the intermediate layers 106B and 106A (see FIG. 4A). Accordingly, current flowing between the intermediate layers 106B and 106A is reduced, and when one of the adjacent light-emitting devices emits light, occurrence of a phenomenon where the other light-emitting device emits light with unintended luminance can be inhibited. The light-emitting devices adjacent to each other can be individually driven. Occurrence of a crosstalk phenomenon between the light-emitting devices can be inhibited. A display device capable of expressing a wide color gamut can be provided.

### <<Structure Example 2 of Light-Emitting Device 550C>>

The light-emitting device 550C includes the electrodes 551C and 552C, the unit 103C, an intermediate layer 106C, a unit 103C2, and the layer 104C (see FIG. 4A).

### [Structure Example 2 of Unit 103C]

The unit 103C is sandwiched between the layer 104C and the electrode 552C, and the unit 103C contains a light-emitting material. Note that the material that can be used as the light-emitting material EMA can be used for the unit 103C. For example, a material that emits light with a hue different from those of light emitted from the light-emitting materials EMA and EMB can be used for the unit 103C.

### [Structure Example of Unit 103C2]

The unit 103C2 is sandwiched between the unit 103C and the electrode 552C, and the unit 103C2 contains a light-emitting material (see FIG. 4A). Note that a light-emitting material that can be used for the unit 103C can be used for the unit 103C2. For example, the same material can be used for the units 103C and 103C2. A material that emits light with a hue which is the same as that of light emitted from the light-emitting material and can be used for the unit 103C can be used for the unit 103C2. A material that emits light with a hue different from that of light emitted from the light-emitting material and can be used for the unit 103C can be used for the unit 103C2.

### [Structure Example of Intermediate Layer 106C]

The intermediate layer 106C is sandwiched between the units 103C2 and 103C. The intermediate layer 106C has a function of injecting holes to one of the units 103C2 and 103C and injecting electrons to the other. For example, in the case where the electrode 552C functions as a cathode, the intermediate layer 106C supplies holes to the unit 103C2 and supplies electrons to the unit 103C. For example, in the case where the electrode 552C functions as an anode, the intermediate layer 106C supplies electrons to the unit 103C2 and supplies holes to the unit 103C.

For example, the material that can be used for the intermediate layer 106A can be used for the intermediate layer 106C.

Note that this embodiment can be combined with any of the other embodiments described in this specification as appropriate.

### Embodiment 2

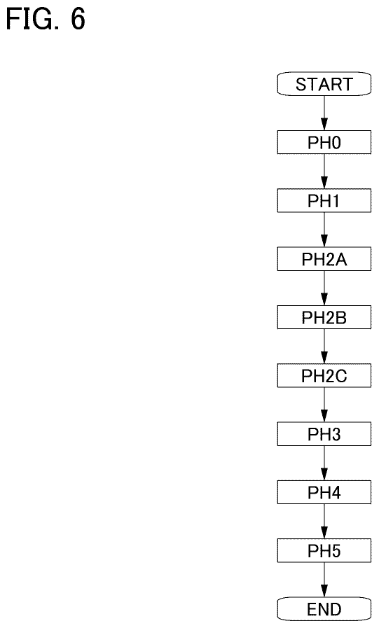

In this embodiment, a method for manufacturing the display device of one embodiment of the present invention will be described with reference to FIGS. 6 to 24.

### <Manufacturing Method Example of Display Device 700>

The method for manufacturing the display device described in this embodiment includes the following phases between the start (START) and the end (END) (see FIG. 6).

### <<Phase PH0>>

In Phase PH0, a circuit board of a display device is formed.

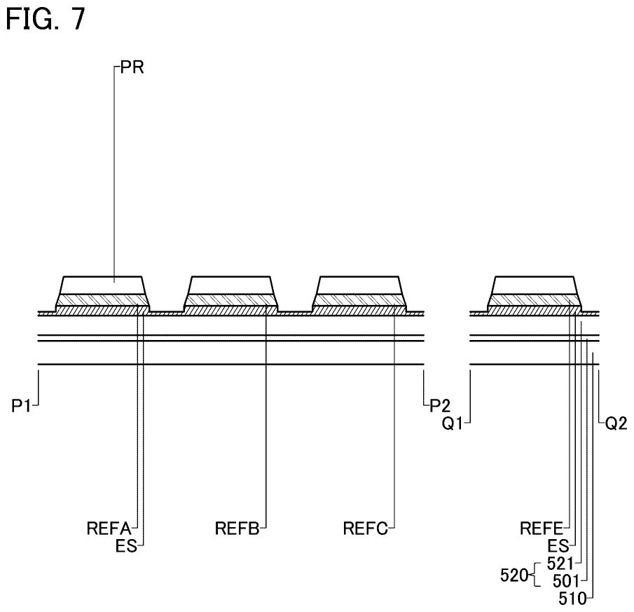

In Phase PH0, the functional layer 520 is formed over the substrate 510 (see FIG. 7). Note that the functional layer 520 includes the insulating layers 501 and 521. The functional layer 520 includes, for example, a pixel circuit or a driver circuit, between the insulating layers 501 and 521.

### <<Phase PH1>>

In Phase PH1, the electrodes 551A, 551B, and 551C and the conductive layer VCOM2 are formed (see FIGS. 7 to 9).

### [Step 1]

In Step 1 of Phase PH1, a film ES is formed over the insulating layer 521 (see FIG. 7). For example, a film containing silicon nitride is formed over the insulating layer 521 by a CVD method and can be used as the film ES. Moreover, tungsten is formed over the insulating layer 521 by a sputtering method and can be used as the film ES, for example.

The layers REFA, REFB, REFC, and REFE are formed over the insulating layer 521. For example, a film to be the layers ESA, ESB, ESC, and ESE later is formed over the film ES by a sputtering method. A photoresist PR is formed, and the layers REFA, REFB, REFC, and REFE are formed by a photolithography method. Specifically, a stacked-layer film in which a film containing titanium, a film containing aluminum, and a film containing titanium are stacked can be used as the layers REFA, REFB, REFC, and REFE.

Note that the layers REFA, REFB, REFC, and REFE may be formed over the insulating layer 521 without formation of the film ES. In this case, the layers REFA, REFB, and REFC connects the light-emitting devices 550A, 550B, and 550C to the pixel circuit, respectively.

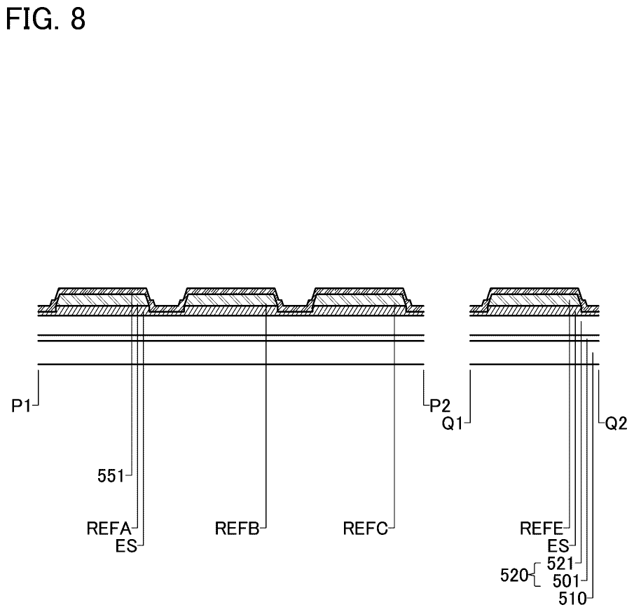

A conductive film 551 is formed over the layers REFA, REFB, REFC, and REFE (see FIG. 8). For example, the conductive film 551 is formed by a sputtering method. Specifically, indium oxide-tin oxide containing silicon or silicon oxide (abbreviation: ITSO) can be used for the conductive film 551.

Note that the conductive film 551 may be formed over the insulating layer 521 without formation of the film ES and the layers REFA, REFB, REFC, and REFE.

### [Step 2]

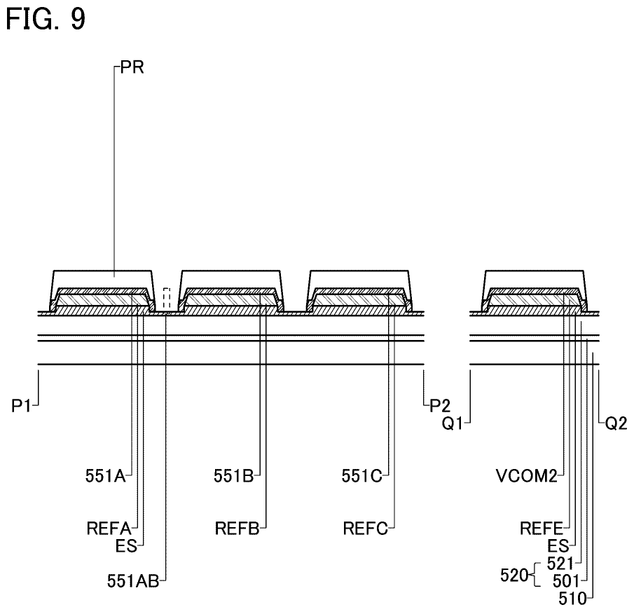

In Step 2 of Phase PH1, the photoresist PR is formed over the conductive film 551, and the electrodes 551A and 551B and the gap 551AB are formed over the insulating layer 521 by a photolithography method (see FIG. 9). Note that the gap 551AB is sandwiched between the electrodes 551A and 551B. In addition, the electrode 551C and the conductive layer VCOM2 are formed.

Note that after the film to be the layers REFA, REFB, REFC, and REFE later is formed over the insulating layer 521 and the conductive film 551 is formed thereover, the layers REFA, REFB, REFC, and REFE, the electrodes 551A, 551B, and 551C, the gap 551AB, and the conductive layer VCOM2 may be formed by a photolithography method.

### <<Phase PH2A>>

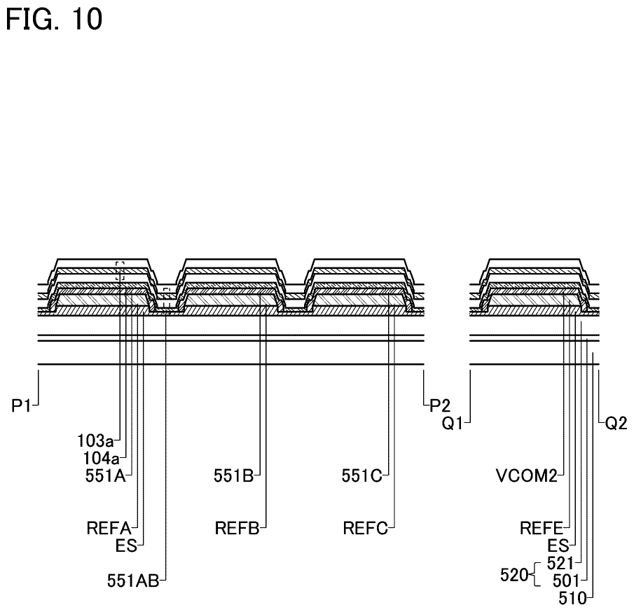

In Phase PH2A, part of the light-emitting device 550A is formed. Specifically, the layer 104A, the unit 103A, the intermediate layer 106A, and the unit 103A2 are formed (see FIGS. 10 to 13).

### [Step 1]

In Step 1 of Phase PH2A, a film 104a is formed over the electrodes 551A, 551B, and 551C and the conductive layer VCOM2 (see FIG. 10). For example, the film 104a can be formed by a resistance-heating method. Specifically, an organic compound(s) can be deposited or co-deposited.

### [Step 2]

In Step 2 of Phase PH2A, a film 103a is formed over the film 104a. In the case where the light-emitting device has a tandem structure, a film 106a is formed over the film 103a and a film 103a2 is formed over the film 106a. For example, the films 106a and 103a2 can be formed by a resistance-heating method. Specifically, an organic compound(s) can be deposited or co-deposited.

### [Step 3]

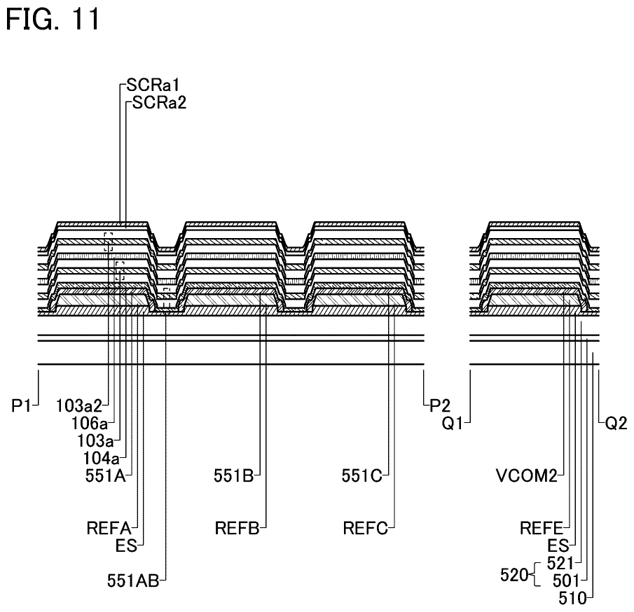

In Step 3 of Phase PH2A, a film SCRa2 is formed over the film 103a (see FIG. 11). In the case where the light-emitting device has a tandem structure, the films 106a and 103a2 are sandwiched between the films 103a and SCRa2. Note that the films 104a, 103a, 106a, and 103a2 can be prevented from being formed over the conductive layer VCOM2 by using a shadow mask.

For example, in the case where a 30-nm-thick film containing aluminum oxide is used as the film SCRa2, the film SCRa2 can be formed by an atomic layer deposition (ALD) method.

### [Step 4]

In Step 4 of Phase PH2A, a film SCRa1 is formed over the film SCRa2. For example, in the case where a 50-nm-thick film containing tungsten is used as the film SCRa1, the film SCRa1 can be formed by a sputtering method.

### [Step 5]

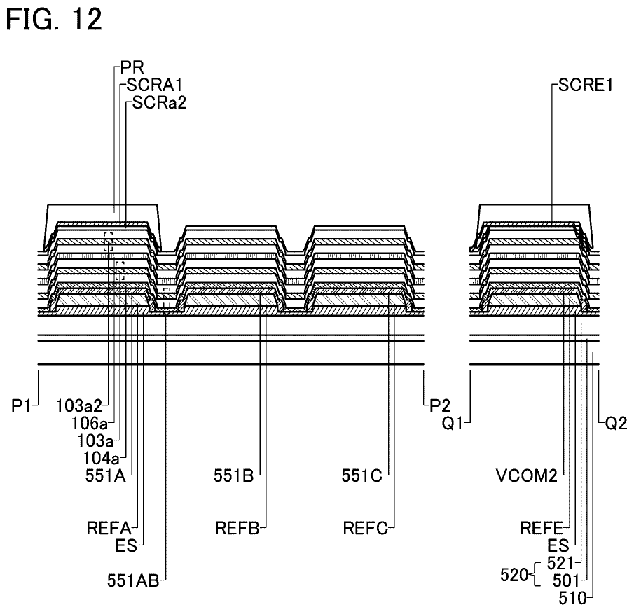

In Step 5 of Phase PH2A, the photoresist PR is formed over the film SCRa1, the film SCRa1 is removed from above the electrodes 551B and 551C by a photolithography method, so that a layer SCRA1 overlapping with the electrode 551A is formed (see FIG. 12). For example, in the case where a film containing tungsten is used as the film SCRa1, a gas containing sulfur hexafluoride (SF₆) can be used for etching of the film SCRa1.

### [Step 6]

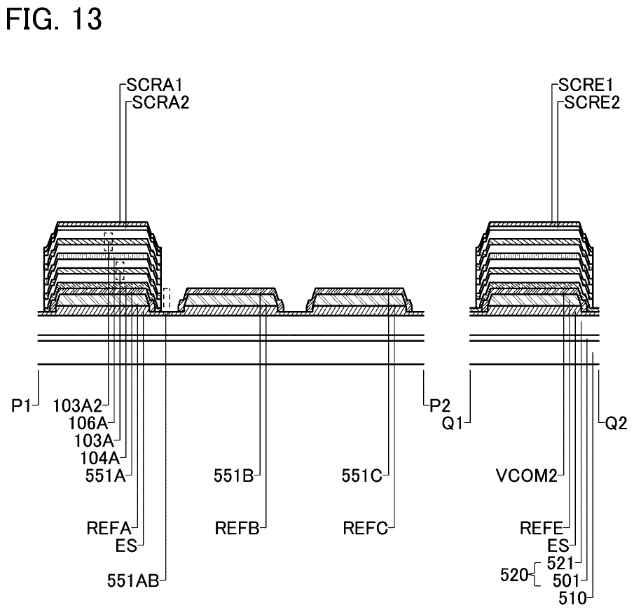

In Step 6 of Phase PH2A, the films SCRa2 and 103a are removed from above the electrodes 551B and 551C by an etching method using the layer SCRA1, so that the layer SCRA2, the unit 103A, and the layer 104A are formed over the electrode 551A (see FIG. 13). The layer SCRA2 is sandwiched between the layer SCRA1 and the electrode 551A. The unit 103A is sandwiched between the layer SCRA2 and the electrode 551A. In the case where the light-emitting device has a tandem structure, the intermediate layer 106A and the unit 103A2 are sandwiched between the unit 103A and the layer SCRA2.

For example, in the case where a film containing aluminum oxide is used as the film SCRa2, a gas containing trifluoromethane (CHF₃), helium (He), and methane (CH₄) can be used for etching of the film SCRa2. For example, in the case where an organic compound is used for the film 103a or the like, an oxygen-containing gas can be used for etching of the film 103a. The layer SCRA1 functions as a hard mask.

A layer SCRE1 is formed in the step of forming the layer SCRA1, and a layer SCRE2 is formed in the step of forming the layer SCRA2. The layer SCRE1 overlaps with the conductive layer VCOM2, and the layer SCRE2 is sandwiched between the layer SCRE1 and the conductive layer VCOM2.

Note that the layer SCRE1 can be formed in the step of forming a layer SCRB1 described later, and the layer SCRE2 can be formed in the step of forming the layer SCRB2. The layer SCRE1 can be formed in the step of forming a layer SCRC1 described later, and the layer SCRE2 can be formed in the step of forming the layer SCRC2.

### <<Phase PH2B>>

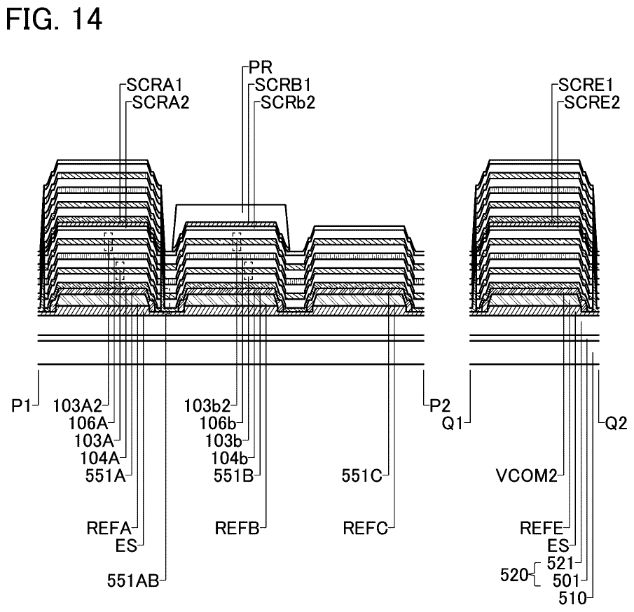

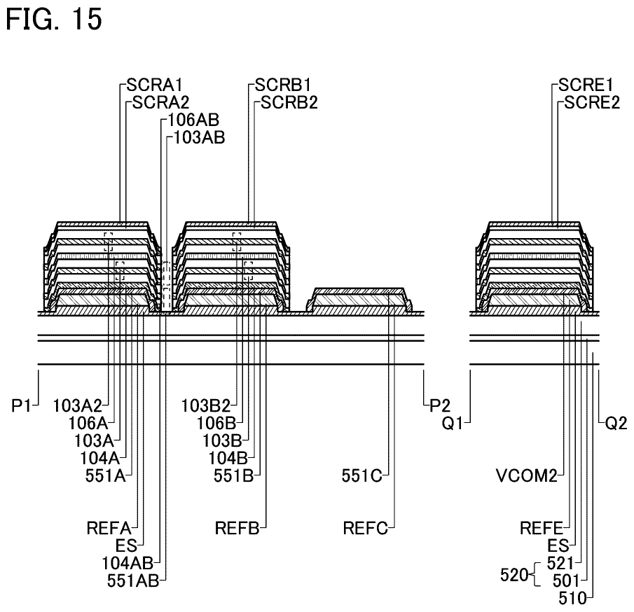

In Phase PH2B, part of the light-emitting device 550B is formed. Specifically, the layer 104B, the unit 103B, the intermediate layer 106B, and the unit 103B2 are formed (see FIGS. 14 and 15). Portions where different methods are employed are described in detail below. Refer to the above description for portions where the same methods as the above-described portions can be employed.

### [Step 1]

In Step 1 of Phase PH2B, a film 104b is formed over the layer SCRA1, the electrodes 551B and 551C, and the conductive layer VCOM2 (see FIG. 14). Note that when the film 104b is formed, a material used for the film 104b is attached to part of the light-emitting device 550A formed in Phase PH2A. For example, when the film 104b is formed by a resistance-heating method, the material used for the film 104b is also attached to side surfaces of the unit 103A.

### [Step 2]

In Step 2 of Phase PH2B, the film 103b is formed over the film 104b. In the case where the light-emitting device has a tandem structure, a film 106b is formed over the film 103b and a film 103b2 is formed over the film 106b.

### [Step 3]

In Step 3 of Phase PH2B, a film SCRb2 is formed over the film 103b. In the case where the light-emitting device has a tandem structure, the films 106b and 103b2 are sandwiched between the films 103b and SCRb2. A material that can be used for the film SCRa2 can be used for the film SCRb2.

### [Step 4]

In Step 4 of Phase PH2B, a film to be the layer SCRB1 later is formed over the film SCRb2. Note that a material that can be used for the film SCRa1 can be used for the film to be the layer SCRB1 later.

### [Step 5]

In Step 5 of Phase PH2B, the photoresist PR is formed over the film to be the layer SCRB1 later, unnecessary portions are removed from above the layer SCRA1 and the electrode 551C by a photolithography method, so that the layer SCRB1 overlapping with the electrode 551B is formed. For example, in the case where tungsten is used for the layer SCRB1, a gas containing SF₆ can be used for etching.

### [Step 6]

In Step 6 of Phase PH2B, the films SCRb2 and 103b are removed from the layer SCRA1 and the gap 551AB by an etching method using the layer SCRB1, so that the layer SCRB2, the unit 103B, and the layer 104B are formed over the electrode 551B (see FIG. 15). The gap 103AB is formed over the gap 551AB. The layer SCRB2 is sandwiched between the layer SCRB1 and the electrode 551B. The unit 103B is sandwiched between the layer SCRB2 and the electrode 551B, and the gap 103AB overlaps with the gap 551AB. In the case where the light-emitting device has a tandem structure, the intermediate layer 106B and the unit 103B2 are sandwiched between the unit 103B and the layer SCRB2.

For example, in the case where a film containing aluminum oxide is used as the film SCRb2, a gas containing CHF₃, He, and CH₄ can be used for etching of the film SCRb2. For example, in the case where an organic compound is used for the film 103b or the like, an oxygen-containing gas can be used for the etching of the film 103b. The layer SCRB1 functions as a hard mask.

### <<Phase PH2C>>

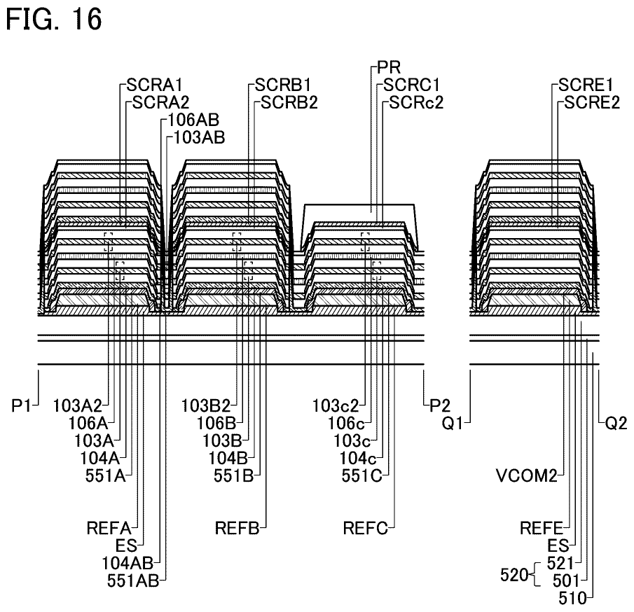

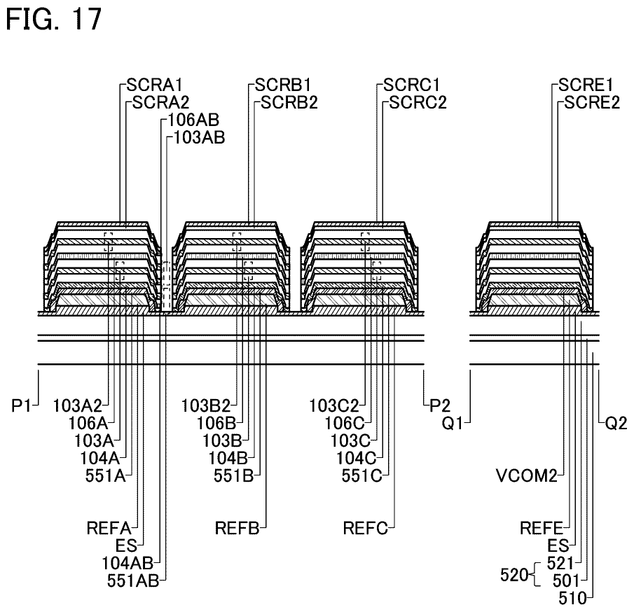

In Phase PH2C, part of the light-emitting device 550C is formed. Specifically, the layer 104C, the unit 103C, the intermediate layer 106C, and the unit 103C2 are formed (see FIGS. 16 and 17). Portions where different methods are employed are described in detail below. Refer to the above description for portions where the same methods as the above-described portions can be employed.

### [Step 1]

In Step 1 of Phase PH2C, a film 104c is formed over the layers SCRA1 and SCRB1, the electrode 551C, and the conductive layer VCOM2 (see FIG. 16). Note that when the film 104c is formed, a material used for the film 104c is attached to part of the light-emitting device 550B formed in Phase PH2B. For example, when the film 104c is formed by a resistance-heating method, the material used for the film 104c is also attached to side surfaces of the unit 103B.

### [Step 2]

In Step 2 of Phase PH2C, a film 103c is formed over the film 104c. In the case where the light-emitting device has a tandem structure, a film 106c is formed over the film 103c and a film 103c2 is formed over the film 106c.

### [Step 3]

In Step 3 of Phase PH2C, a film SCRc2 is formed over the film 103c. In the case where the light-emitting device has a tandem structure, the films 106c and 103c2 are sandwiched between the films 103c and SCRc2. For example, the material that can be used for the film SCRa2 can be used for the film SCRc2.

### [Step 4]

In Step 4 of Phase PH2C, a film to be the layer SCRC1 later is formed over the film SCRc2. Note that the material that can be used for the film SCRa1 can be used for the film to be the layer SCRC1 later.

### [Step 5]

In Step 5 of Phase PH2C, the photoresist PR is formed over the film to be the layer SCRC1 later, unnecessary portions are removed from above the layers SCRA1 and SCRB1 by a photolithography method, so that the layer SCRC1 overlapping with the electrode 551C is formed. For example, in the case where tungsten is used for the layer SCRC1, a gas containing SF₆ can be used for etching.

### [Step 6]

In Step 6 of Phase PH2C, the films SCRc2 and 103c are removed from the layers SCRA1 and SCRB1 and the gap 551AB by an etching method using the layer SCRC1, so that the layer SCRC2, the unit 103C, and the layer 104C are formed over the electrode 551C (see FIG. 17). The layer SCRC2 is sandwiched between the layer SCRC1 and the electrode 551C. The unit 103C is sandwiched between the layer SCRC2 and the electrode 551C. In the case where the light-emitting device has a tandem structure, the intermediate layer 106C and the unit 103C2 are sandwiched between the unit 103C and the layer SCRC2.

For example, in the case where a film containing aluminum oxide is used as the film SCRc2, a gas containing CHF₃, He, and CH₄ can be used for etching of the film SCRc2. In the case where an organic compound is used for the film 103c or the like, for example, an oxygen-containing gas can be used for etching of the film 103c. The layer SCRC1 functions as a hard mask.

### <<Phase PH3>>

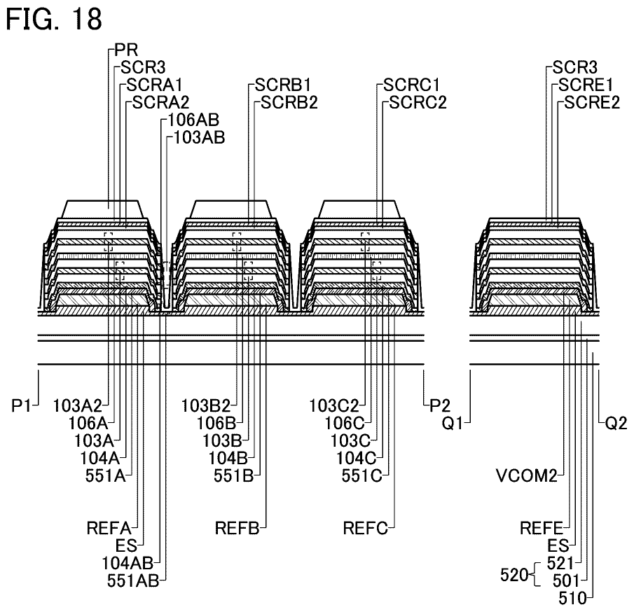

In Phase PH3, the outer shapes of the unit 103A of the light-emitting device 550A, the unit 103B of the light-emitting device 550B, and the unit 103C of the light-emitting device 550C are adjusted to form side surfaces thereof (see FIGS. 18 to 21).

### [Step 1]

In Step 1 of Phase PH3, after a film SCR3 is formed over the layers SCRA1, SCRB1, and SCRC1, the photoresist PR is formed (see FIG. 18). The film SCR3 covers part of the light-emitting device 550A formed in Phase PH2A, part of the light-emitting device 550B formed in Phase PH2B, and part of the light-emitting device 550C formed in Phase PH2C. For example, the film SCR3 covers the side surfaces of the units 103A, 103B, and 103C. This can prevent a phenomenon in which a solution containing a photosensitive polymer is in contact with the unit 103A, 103B, or 103C at the time of forming the photoresist PR. Moreover, a phenomenon in which the solution containing a photosensitive polymer dissolves part of the unit 103A, part of the unit 103B, or part of the unit 103C can be prevented.

For example, in the case where a 30-nm-thick film containing aluminum oxide is used as the film SCR3, the film SCR3 can be formed by an ALD method.

### [Step 2]

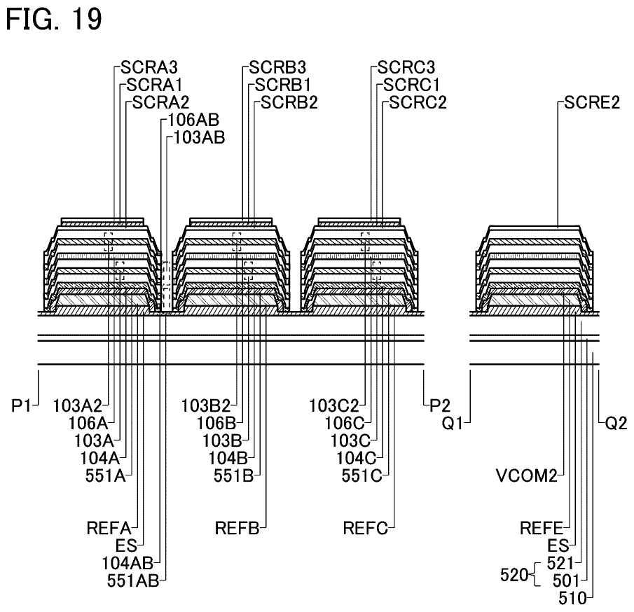

In Step 2 of Phase PH3, unnecessary portions are removed from the film SCR3 by an etching method using the photoresist PR, so that layers SCRA3, SCRB3, and SCRC3 are formed (see FIG. 19). Note that the layer SCRA3 overlaps with the electrode 551A and has an outer shape smaller than that of the layer SCRA1. The layer SCRB3 overlaps with the electrode 551B and has an outer shape smaller than that of the layer SCRB1. The layer SCRC3 overlaps with the electrode 551C and has an outer shape smaller than that of the layer SCRC1. For example, in the case where a film containing aluminum oxide is used as the film SCR3, a gas containing CHF₃, He, and CH₄ can be used for etching of the film SCR3.

### [Step 3]

In Step 3 of Phase PH3, the outer shape of each of the layers SCRA1, SCRB1, and SCRC1 is made smaller by an etching method using the photoresist PR or an etching method using the layers SCRA3, SCRB3, and SCRC3 (see FIG. 19). For example, in the case where a film containing tungsten is used as the layers SCRA1, SCRB1, and SCRC1, a gas containing SF₆ can be used for etching of the layers SCRA1, SCRB1, and SCRC1.

### [Step 4]

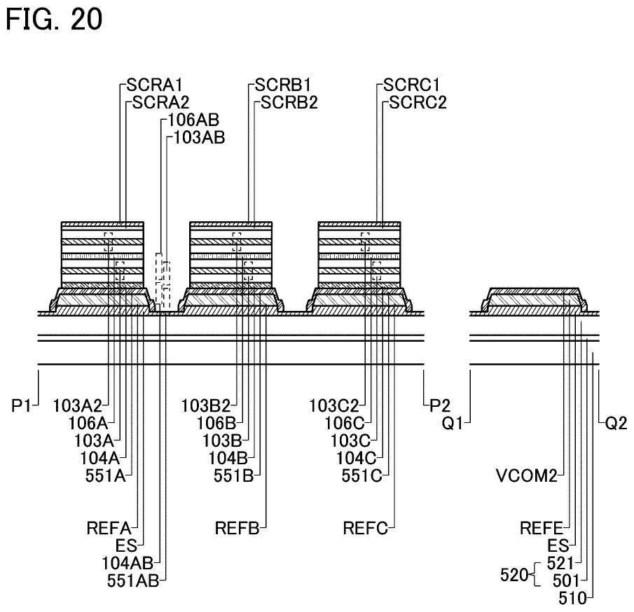

In Step 4 of Phase PH3, the outer shape of each of the layers SCRA2, SCRB2, and SCRC2, the units 103A,103B, and 103C, and the layers 104A, 104B, and 104C is made smaller by an etching method using the layers SCRA1, SCRB1, and SCRC1 (see FIG. 20). In the case where the light-emitting device has a tandem structure, the outer shape of each of the intermediate layers 106A, 106B, and 106C and the units 103A2, 103B2, and 103C2 is made smaller. In addition, an unnecessary portion is removed from above the conductive layer VCOM2. Accordingly, portions of the material used for the film 104b attached to the unit 103A can be removed. Portions of the material used for the film 104c attached to the unit 103B can also be removed. In the case where the light-emitting device has a tandem structure, portions of the material used for the film 104b attached to the intermediate layer 106A and the unit 103A2 can be removed. Portions of the material used for the film 104c attached to the intermediate layer 106B and the unit 103B2 can also be removed.

Note that when the same material is used for the layers SCRA3, SCRB3, SCRC3, SCRA2, SCRB2, and SCRC2, unnecessary portions can be removed by the etching method in this step. For example, in the case where aluminum oxide is used for the layers SCRA3, SCRB3, SCRC3, SCRA2, SCRB2, and SCRC2, a gas containing CHF₃, He, and CH₄ can be used for etching of the layers SCRA3, SCRB3, SCRC3, SCRA2, SCRB2, and SCRC2. For example, in the case where an organic compound is used for the units 103A, 103B, 103C, and the like, an oxygen-containing gas can be used for etching of the units 103A, 103B, and 103C. The layers SCRA1, SCRB1, and SCRC1 function as hard masks. When the film ES is formed over the functional layer 520, the film ES can protect the functional layer 520 from the etching treatment in this step.

### [Step 5]

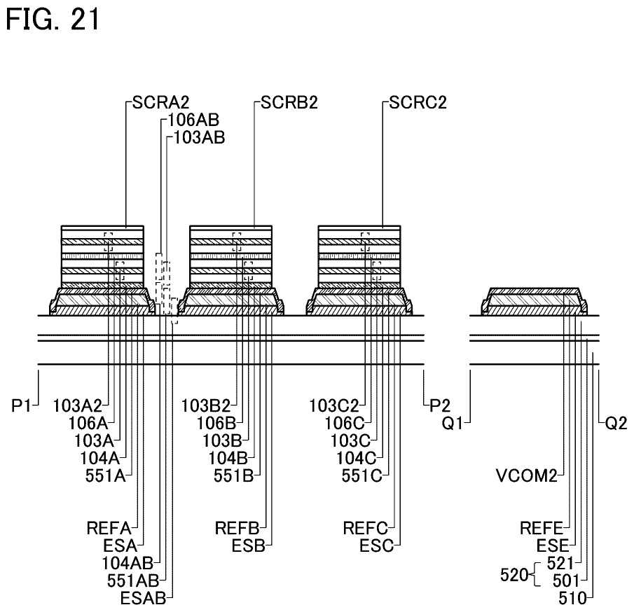

In Step 5 of Phase PH3, the layers SCRA1, SCRB1, and SCRC1 are removed by an etching method (see FIG. 21). For example, in the case where a film containing tungsten is used as the layers SCRA1, SCRB1, and SCRC1, a gas containing SF₆ can be used for etching of the layers SCRA1, SCRB1, and SCRC1.

An unnecessary portion is removed from the film ES, so that the layers ESA and ESB and the gap ESAB are formed. In addition, the layers ESC and ESE are formed. Note that the layer ESA is sandwiched between the electrode 551A and the insulating layer 521, and the layer ESB is sandwiched between the electrode 551B and the insulating layer 521. The gap ESAB overlaps with the gap 551AB. For example, in the case where a film containing tungsten is used as the film ES, a gas containing SF₆ can be used for etching of the film ES.

### <<Phase PH4>>

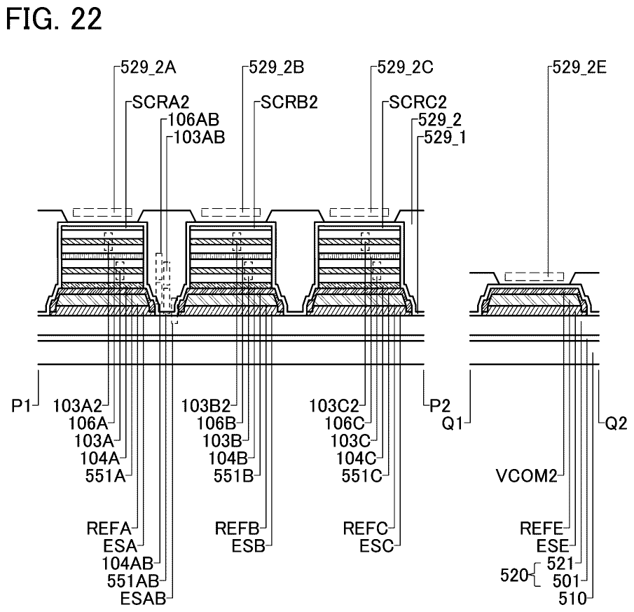

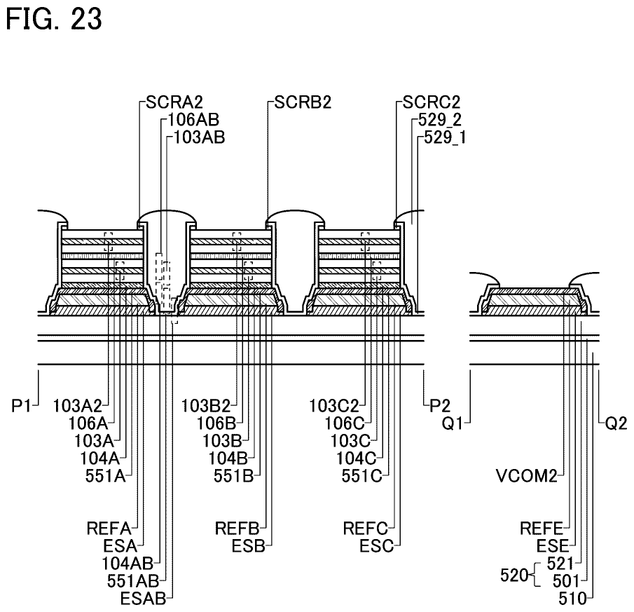

In Phase PH4, the layers 529_1 and 529_2 are formed (see FIGS. 22 and 23).

### [Step 1]

In Step 1 of Phase PH4, the layer 529_1 is formed (see FIG. 22). The layer 529_1 is in contact with the insulating layer 521 in the gap 551AB and covers the units 103A, 103B, and 103C. In the case where the light-emitting device has a tandem structure, the layer 529_1 covers the intermediate layers 106A, 106B, and 106C and the units 103B2 and 103C2.

For example, in the case where a film containing aluminum oxide is used as the layer 529_1, the layer 529_1 can be formed by an ALD method.

### [Step 2]

In Step 2 of Phase PH4, the layer 5292 is formed. The layer 5292 fills the gaps 551AB and 103AB. The layer 529_2 includes the opening portion 529_2A and the opening portion 529_2B, which overlap with the electrode 551A and the electrode 551B, respectively. The layer 529_2 includes an opening portion 529_2C and an opening portion 529_2E, which overlap with the electrode 551C and the conductive layer VCOM2, respectively.

For example, a photosensitive polymer can be used for the layer 5292. Specifically, a film containing a photosensitive polymer is formed by a spin coating method, and the opening portions 529_2A, 529_2B, 529_2C, and 529_2E are formed by a photolithography method.

### [Step 3]

In Step 3 of Phase PH4, the layer 529_1 and the layer SCRA2 each in a portion overlapping with the opening portion 529_2A are removed, and the layer 529_1 and the layer SCRB2 each in a portion overlapping with the opening portion 529_2B are removed, by a wet etching method using the layer 529_2 (see FIG. 23). The layer 529_1 and the layer SCRC2 each in a portion overlapping with the opening portion 529_2C are removed, and the layer 529_1 in a portion overlapping with the opening portion 529_2E is removed. For example, in the case where aluminum oxide is used for the layers 529_1, SCRA2, SCRB2, and SCRC2, an aqueous solution containing hydrofluoric acid (HF) can be used for etching.

Note that the layer 529_2 can be softened to have fluidity. For example, a workpiece WP where the layer 529_2 is formed is heated.

### <<Phase PH5>>

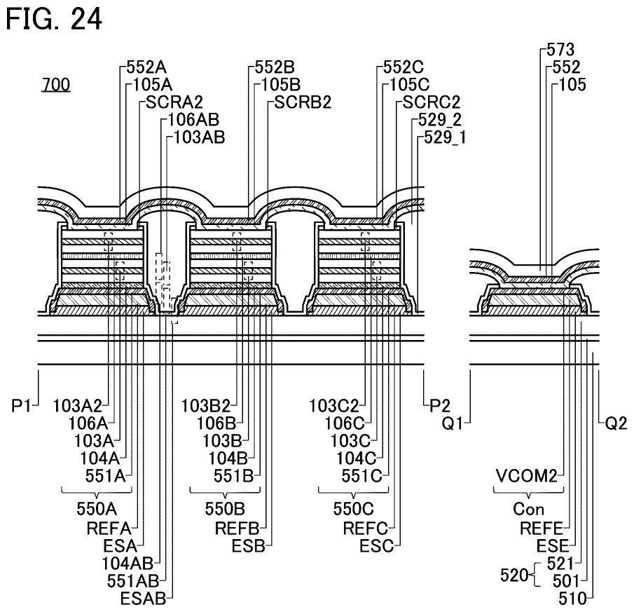

In Phase PH5, the layer 105 and the conductive film 552 are formed (see FIG. 24).

### [Step 1]

In Step 1 of Phase PH5, the layer 105 is formed over the units 103A, 103B, and 103C and the conductive layer VCOM2 (see FIG. 24). In the case where the light-emitting device has a tandem structure, the layer 105 is formed over the units 103A2, 103B2, and 103C2.

### [Step 2]

In Step 2 of Phase PH5, the conductive film 552 is formed over the layer 105. For example, the conductive film 552 can be formed by a resistance-heating method. Specifically, a film containing silver and magnesium can be co-deposited. A film containing indium oxide-tin oxide (abbreviation: ITO) can be stacked over the film containing silver and magnesium by a sputtering method.

### [Step 3]

In Step 3 of Phase PH5, the layer 573 is formed over the conductive film 552. For example, a film containing ITO is formed by a sputtering method and can be used as the layer 573. A film that transmits light emitted from the light-emitting device and contains an organic compound with a refractive index higher than or equal to 1.8 is formed by a resistance-heating method and can be used as the layer 573. A film through which impurities such as water or oxygen do not easily pass is formed by a CVD method or an ALD method and can be used as the layer 573.

Thus, the carrier-injection material CIM attached to the side surface 103AS in Step 1 of Phase PH2B can be removed in Step 4 of Phase PH3, for example. Current flowing between the electrodes 551A and 552A through the side surface 103AS can be reduced. Furthermore, Current flowing between the electrodes 551B and 552B through the side surface 103BS can be reduced. Furthermore, current that does not contribute to light emission of the light-emitting device 550A or 550B can be reduced. In addition, the current efficiency of light emission of the display device can be increased.

In Step 4 of Phase PH3, the outer shape of each of the units 103A and 103B can be adjusted by etching treatment using an oxygen-containing gas. With the use of the film ES, the insulating layer 521 can be protected from the etching treatment using an oxygen-containing gas. Furthermore, even in the case where the film ES has conductivity, the formation of the gap ESAB can prevent electrical continuity between the electrodes 551A and 551B. As a result, a manufacturing method of a novel display device that is highly convenient, useful, or reliable can be provided.

### Embodiment 3

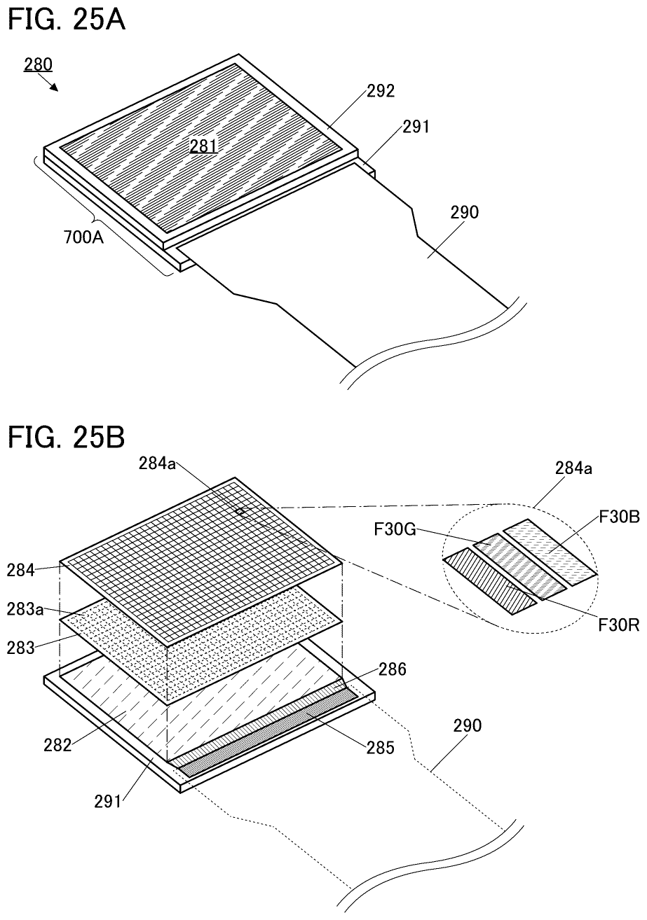

In this embodiment, structure examples of a display module that can be used for the display device of one embodiment of the present invention and a display device will be described with reference to FIGS. 25A and 25B, FIGS. 26A to 26E, FIG. 27, FIGS. 28A and 28B, FIG. 29, FIG. 30, FIG. 31, FIG. 32, FIG. 33, FIGS. 34A to 34C, FIG. 35, FIGS. 36A to 36D, FIGS. 37A to 37E, and FIG. 38.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

### [Display Module]

FIG. 25A is a perspective view of a display module 280. The display module 280 includes a display device 700A and an FPC 290. Note that instead of the display device 700A, any of display devices 700B to 700F described later can be used for the display module 280, for example.

### [Example 1 of Display Device 700]

The display device 700A includes a substrate 291 and a substrate 292. The display device 700A includes a display portion 281. The display portion 281 is a region where an image is displayed. The display portion 281 includes a pixel portion 284.

FIG. 25B is a perspective view illustrating part of the structure of the display device 700A. Over the substrate 291, a circuit portion 282, a pixel circuit portion 283 over the circuit portion 282, and the pixel portion 284 over the pixel circuit portion 283 are stacked. A terminal portion 285 is provided outside the pixel portion 284 over the substrate 291. A wiring portion 286 is provided between the circuit portion 282 and the terminal portion 285. The wiring portion 286 includes a plurality of wirings and connects the terminal portion 285 and the circuit portion 282. Note that the display device 700A is connected to the FPC 290 in the terminal portion 285.

The pixel portion 284 includes a plurality of pixels 284a arranged periodically. An enlarged view of one pixel 284a is illustrated on the right side in FIG. 25B. The pixel 284a includes a plurality of subpixels in a stripe pattern.

The pixel circuit portion 283 includes a plurality of pixel circuits 283a arranged periodically.

For example, the pixel circuit 283a can include at least one selection transistor, one current control transistor (driving transistor), and a capacitor. In that case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like can be included.

The FPC 290 functions as a wiring for supplying a video signal, a power supply potential, or the like to the circuit portion 282 from the outside. An integrated circuit (IC) can be mounted on the FPC 290.

The display device 700 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have greatly high resolution. For example, the pixels 284a are preferably arranged in the display portion 281 with a resolution greater than or equal to 2000 ppi, preferably greater than or equal to 3000 ppi, further preferably greater than or equal to 5000 ppi, and still further preferably greater than or equal to 6000 ppi, and less than or equal to 20000 ppi or less than or equal to 30000 ppi.

Such a display device 700 has the display portion 281 with extremely high resolution, and thus can be suitably used for a VR device such as an HMD or a glasses-type AR device. For example, even in the case of a structure in which the display portion is magnified through a lens for viewing, an individual pixel cannot be recognized, so that display providing a high sense of immersion can be performed. For example, the display device 700 can be suitably used for an electronic device including a relatively small display portion, such as a wearable electronic device like a wrist watch.

### [Example 2 of Display Device 700]

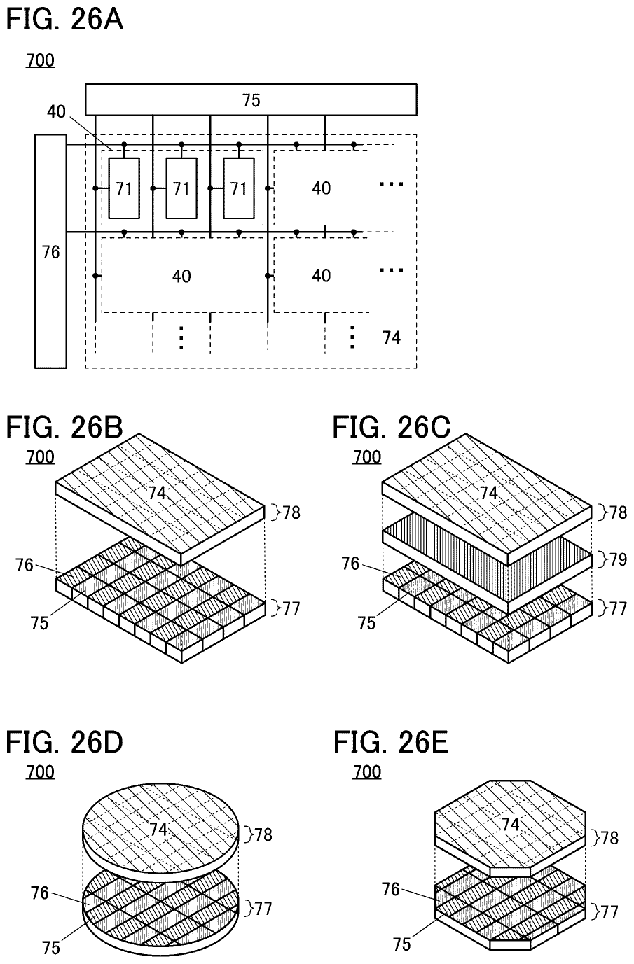

FIG. 26A is a block diagram illustrating a display device of one embodiment of the present invention. The display device 700 includes a pixel array 74, a circuit 75, and a circuit 76. The pixel array 74 includes pixels 40 arranged in a column direction and a row direction.

The pixel 40 can include a plurality of subpixels 71. The subpixel 71 has a function of emitting light for display. When colors of R (red), G (green), B (blue), and the like are assigned to light emitted from the subpixels 71, full-color display can be performed.

The subpixel 71 includes a light-emitting device that emits unpolarized visible light. An EL element such as an OLED (Organic Light Emitting Diode) or a QLED (Quantum-dot Light Emitting Diode) is preferably used as the light-emitting device. Examples of a light-emitting substance contained in the EL element include a substance exhibiting fluorescence (a fluorescent material), a substance exhibiting phosphorescence (a phosphorescent material), a substance that exhibits thermally activated delayed fluorescence (a thermally activated delayed fluorescent (TADF) material), and an inorganic compound (e.g., a quantum dot material). In addition, an LED such as a micro LED can be also used as the light-emitting device.

The circuits 75 and 76 are driver circuits for driving the subpixel 71. The circuit 75 can have a function of a source driver circuit, and the circuit 76 can have a function of a gate driver circuit. A shift register circuit or the like can be used as each of the circuits 75 and 76, for example.

Note that the display device 700 may be divided into a plurality of regions horizontally and vertically, and pixel driving may be performed on the divided region basis.

For example, as illustrated in FIG. 26B, the circuits 75 and 76 can be separately arranged under the pixel array 74. In this case, the display device 700 has a stacked-layer structure of layers 77 and 78, a plurality of circuits 75 and a plurality of circuits 76 are provided in the layer 77, and the pixel array 74 is provided in the layer 78 so as to overlap with the circuits 75 and 76.

In addition, when the circuits 75 and 76 are separately arranged, the pixel array 74 can be driven on the divided region basis. For example, the pixel array 74 can be operated at different frame rates from region to region. The pixel array 74 can be displayed with different resolutions from region to region, and can also be compatible with foveated rendering.

In addition, when the driver circuits are provided below the pixel array 74, wiring length can be shortened and wiring capacitance can be reduced. Accordingly, a display device capable of high-speed operation with low power consumption can be provided. In addition, the display device 700 can have a narrow bezel.

The layout and area of the circuits 75 and 76 illustrated in FIG. 26B are examples and can be changed as appropriate. In addition, part of each of the circuits 75 and 76 can be formed in the same layer as the pixel array 74. Furthermore, a circuit such as a memory circuit, an arithmetic circuit, or a communication circuit may be provided in the layer 77.

In this structure, for example, a single crystal silicon substrate can be provided for the layer 77, the circuits 75 and 76 can be formed with transistors containing silicon in channel formation regions (hereinafter Si transistors), and pixel circuits included in the pixel array 74 provided in the layer 78 can be formed with transistors containing an oxide semiconductor in channel formation regions (hereinafter OS transistors). An OS transistor can be formed with a thin film and can be formed to be stacked over a Si transistor.

Note that a structure illustrated in FIG. 26C, in which a layer 79 including OS transistors is provided between the layer 77 and the layer 78, may be employed. In the layer 79, OS transistors which form some of the pixel circuits included in the pixel array 74 can be provided. Alternatively, OS transistors which form some of the circuit 75 and the circuit 76 can be provided in the layer 79. Alternatively, OS transistors which form some of the circuits that can be provided in the layer 77, such as a memory circuit, an arithmetic circuit, and a communication circuit, can be provided in the layer 79.

The shape of the display device 700 in the top view is not limited to a rectangle and may be a circle as illustrated in FIG. 26D. Alternatively, a polygon such as an octagon may be employed as illustrated in FIG. 26E.

Display devices in this embodiment are high-resolution display devices, and particularly suitably used for display portions of wearable devices capable of being worn on a head, such as VR devices like head-mounted displays and glasses-type AR devices.

### [Display Device 700A]

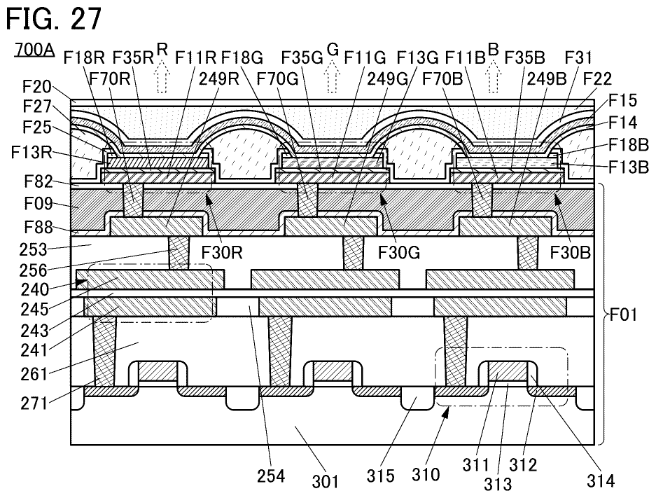

The display device 700A illustrated in FIG. 27 includes a substrate 301, light-emitting devices F30R, F30G, and F30B, a capacitor 240, and a transistor 310.

The substrate 301 corresponds to the substrate 291 in FIGS. 25A and 25B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, insulating layers 313 and 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 so as to be embedded in the substrate 301.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

When a material with a low light transmittance is used for the conductive layers 241 and 245, light incident on the transistor 310 can be inhibited. When each of the conductive layers 241 and 245 functions as a light-blocking layer in addition to a light-blocking layer F09, a change in the electrical characteristics of the transistor 310 is inhibited, whereby the display device can have high reliability. It is preferable that one or both of the conductive layers 241 and 245 include a region overlapping with the transistor 310 (in particular, the channel formation region). In particular, the light-blocking layer F09 preferably has a low transmittance of light of energy higher than or equal to the band gap of a semiconductor material included in a semiconductor layer of a transistor provided in a layer F01, that is, a low transmittance of light with a short wavelength. Accordingly, a change in electrical characteristics of the transistor can be more effectively inhibited and a display device with higher reliability can be obtained. For example, in the case where the band gap of a semiconductor material included in the semiconductor layer is 3.1 eV, the light-blocking layer F09 preferably has a low transmittance of light with an energy higher than or equal to 3.1 eV (with a wavelength of approximately lower than or equal to 400 nm). For example, red, green, brown, and black resins each have a low transmittance of light with a short wavelength and thus can be particularly suitably used for the light-blocking layer F09.

The conductive layer 241 is provided over the insulating layer 261 and is embedded in an insulating layer 254. The conductive layer 241 is connected to one of the source and the drain of the transistor 310 through a conductive layer 271 embedded in the insulating layer 261. The conductive layer 271 functions as a plug. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer F01. The conductive layer can be referred to as a guard ring. By providing the conductive layer, elements such as a transistor and a light-emitting device can be inhibited from being broken by high voltage application due to electrostatic discharge (ESD) or charging caused by a step using plasma.

An insulating layer 253 is provided to cover the capacitor 240, and conductive layers 249R, 249G, and 249B are provided over the insulating layer 253. The conductive layers 249R, 249G, and 249B each function as a wiring, for example. The conductive layer 249R is connected to the conductive layer 241 through a conductive layer 256 embedded in the insulating layer 253. The conductive layer 256 functions as a plug. The same applies to the conductive layers 249G and 249B.

As the insulating layer 253, inorganic insulating films such as an oxide insulating film, a nitride insulating film, an oxynitride insulating film, and a nitride oxide insulating film can be suitably used. For example, one or more of a silicon oxide film, a silicon oxynitride film, an aluminum oxide film, a silicon nitride film, and a silicon nitride oxide film can be suitably used as the insulating layer 253.

An insulating layer F88 is provided over the insulating layer 253 and the conductive layers 249R, 249G, and 249B, the light-blocking layer F09 is provided over the insulating layer F88, and an insulating layer F82 is provided over the light-blocking layer F09. The light-emitting devices F30R, F30G, and F30B are provided over the insulating layer F82.

In FIG. 27, the light-blocking layer F09 is provided between the conductive layers 249R, 249G, and 249B and the light-emitting devices F30R, F30G, and F30B; however, one embodiment of the present invention is not limited thereto.

In FIG. 27, an insulator is provided in a region between adjacent light-emitting devices. In FIG. 27 and the like, an insulating layer F25 and an insulating layer F27 over the insulating layer F25 are provided in this region. A mask layer F18R is positioned over a layer F13R included in the light-emitting device F30R, a mask layer F18G is positioned over a layer F13G included in the light-emitting device F30G, and a mask layer F18B is positioned over a layer F13B included in the light-emitting device F30B.

Pixel electrodes F11R, F11G, and F11B are connected to the conductive layers 249R, 249G, and 249B through conductive layers F70R, F70G, and F70B, respectively, each of the conductive layers is embedded in the light-blocking layer F09 and the insulating layers F82 and F88. The top surface of the insulating layer F82 and the top surface of each of the conductive layers F70R, F70G, and F70B are level or substantially level with each other.

A protective layer F31 is provided over the light-emitting devices F30R, F30G, and F30B. A substrate F20 is attached onto the protective layer F31 with a resin layer F22. The substrate F20 corresponds to the substrate 292 in FIG. 25A.

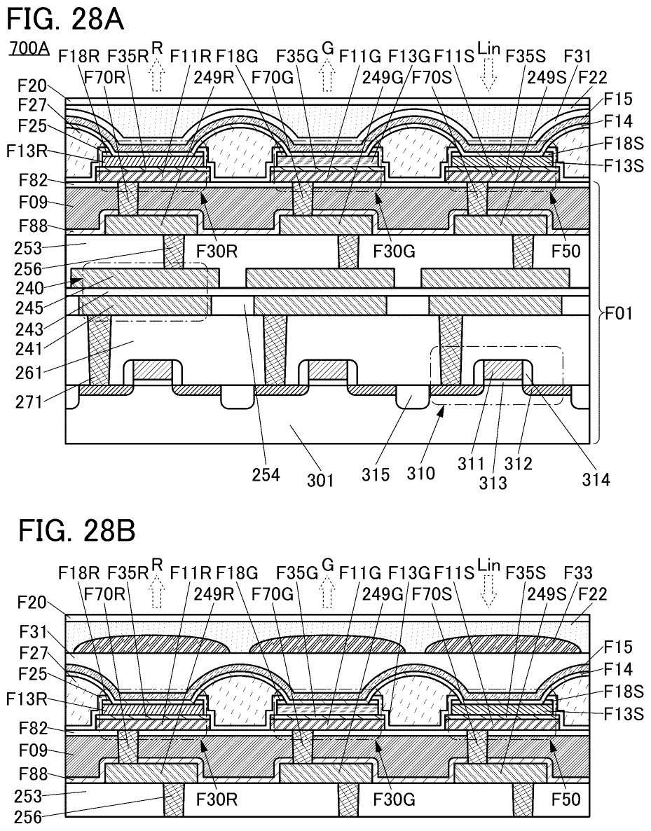

FIGS. 28A and 28B illustrate an example in which the display device includes the light-emitting devices F30R and F30G and a light-receiving device F50. Although not illustrated, the display device also includes the light-emitting device F30B. In FIG. 28B, the layers below the insulating layer 253 are omitted. The display device 700A illustrated in FIGS. 28A and 28B can employ any of the structures of the layer F01 illustrated in FIG. 27 and FIGS. 29 to 34A, for example.

The light-receiving device F50 includes a pixel electrode F11S, a conductive layer F35S over the pixel electrode F11S, a layer F13S over the conductive layer F35S, a common layer F14 over the layer F13S, and a common electrode F15 over the common layer F14. The conductive layer F35S can be formed in the same step as conductive layers F35R, F35G, and F35B.

A conductive layer F70S is in contact with and is connected to a conductive layer 249S. The conductive layer 249S functions as a wiring, for example. The conductive layer 249S can be formed in the same step as the conductive layers 249R, 249G, and 249B, for example.

The pixel electrode F11S is provided over the insulating layer F82. The pixel electrode F11S includes a region in contact with the conductive layer F70S embedded in the light-blocking layer F09 and the insulating layers F82 and F88 and is connected to the conductive layer F70S. The conductive layer F70S is in contact with the conductive layer 249S included in the layer F01 and is connected to the conductive layer 249S. That is, the conductive layer 249S is connected to the pixel electrode F11S through the conductive layer F70S. The conductive layer 249S corresponds to an electrode of the transistor, an electrode of the capacitor, or a wiring.

As illustrated in FIG. 28B, a lens array F33 can be provided in the display device. The lens array F33 can be provided to overlap with one or both of the light-emitting device and the light-receiving device.

FIG. 28B illustrates an example in which the lens array F33 is provided over the light-emitting devices F30R and F30G and the light-receiving device F50 with the protective layer F31 therebetween. The lens array F33 is directly formed over the substrate provided with the light-emitting device (and the light-receiving device), whereby the accuracy of positional alignment of the light-emitting device or the light-receiving device and the lens array can be enhanced.

In FIG. 28B, light emitted from the light-emitting device passes through the lens array F33 and is extracted to the outside of the display device.

The substrate F20 provided with the lens array F33 can be bonded onto the protective layer F31 with the resin layer F22. By providing the lens array F33 for the substrate F20, the heat treatment temperature in the formation step of the lens array F33 can be increased.

### [Display Device 700B]

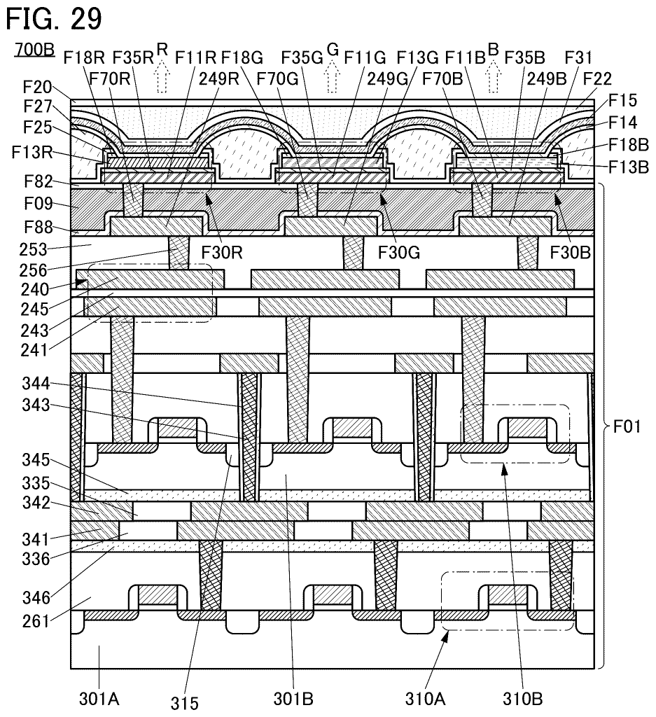

The display device 700B illustrated in FIG. 29 has a structure where a transistor 310A and a transistor 310B in each of which a channel is formed in a semiconductor substrate are stacked. Note that in the following description of display devices, the description of portions similar to those of the above-described display devices may be omitted.

In the display device 700B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrates 301B and 301A. As the insulating layers 345 and 346, an inorganic insulating film that can be used as the protective layer F31 can be used.

The substrate 301B is provided with a plug 343 that penetrates the substrate 301B and the insulating layer 345. An insulating layer 344 is preferably provided to cover a side surface of the plug 343. The insulating layer 344 functions as a protective layer and can inhibit diffusion of impurities into the substrate 301B. As the insulating layer 344, an inorganic insulating film that can be used as the protective layer F31 can be used.

A conductive layer 342 is provided under the insulating layer 345 on the rear surface of the substrate 301B (the surface opposite to the substrate F20). The conductive layer 342 is preferably provided to be embedded in an insulating layer 335. The bottom surfaces of the conductive layer 342 and the insulating layer 335 are preferably planarized. The conductive layer 342 is in contact with and is electrically connected to the plug 343.

A conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layers 341 and 342 are bonded to each other, whereby the substrates 301A and 301B are connected to each other. Here, improving the flatness of a plane formed by the conductive layer 342 and the insulating layer 335 and a plane formed by the conductive layer 341 and the insulating layer 336 allows the conductive layers 341 and 342 to be bonded to each other favorably.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layers 341 and 342. In this case, it is possible to employ Cu-to-Cu direct bonding (a technique for achieving electrical continuity by connecting copper (Cu) pads).

### [Display Device 700C]

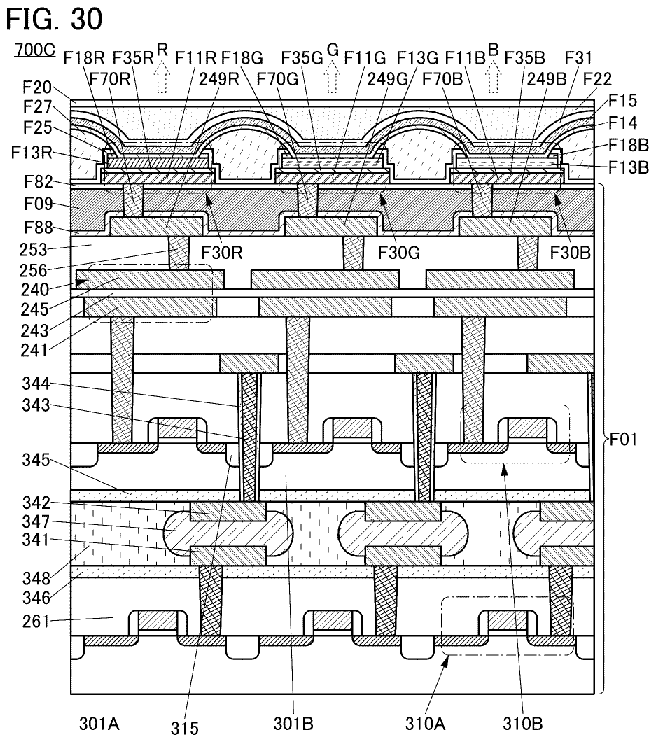

In the display device 700C illustrated in FIG. 30, the conductive layers 341 and 342 are bonded to each other with a bump 347.

As illustrated in FIG. 30, providing the bump 347 between the conductive layers 341 and 342 enables the conductive layers 341 and 342 to be connected to each other. The bump 347 can be formed using a conductive material containing gold (Au), nickel (Ni), indium (In), or tin (Sn), for example. As another example, solder may be used for the bump 347. An adhesive layer 348 can be provided between the insulating layers 345 and 346. In the case where the bump 347 is provided, the insulating layers 335 and 336 can be omitted.

### [Display Device 700D]

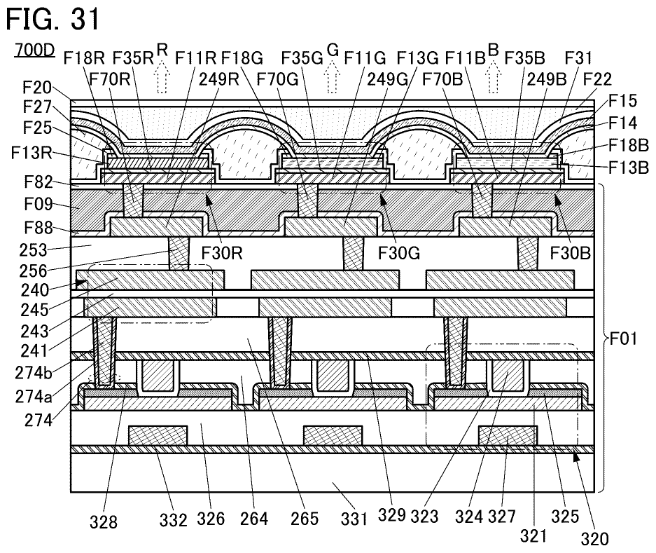

The display device 700D illustrated in FIG. 31 differs from the display device 700A mainly in a structure of a transistor.

A transistor 320 is an OS transistor that contains an oxide semiconductor in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIGS. 25A and 25B. As the substrate 331, an insulating substrate or a semiconductor substrate can be used.

An insulating layer 332 is provided over the substrate 331. The insulating layer 332 functions as a barrier layer that prevents diffusion of impurities (e.g., water and hydrogen) from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. The semiconductor layer 321 preferably includes an oxide semiconductor film. The pair of conductive layers 325 is provided over and in contact with the semiconductor layer 321, and functions as a source electrode and a drain electrode.

An insulating layer 328 is provided to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities (e.g., water and hydrogen) from the insulating layer 264 and the like into the semiconductor layer 321 and release of oxygen from the semiconductor layer 321. As the insulating layer 328, an insulating film similar to the insulating layer 332 can be used.

An opening portion reaching the semiconductor layer 321 is provided in the insulating layers 328 and 264. The insulating layer 323 that is in contact with side surfaces of the insulating layers 264 and 328 and the side surface of the conductive layer 325 and the top surface of the semiconductor layer 321, and the conductive layer 324 are embedded in the opening portion. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and insulating layers 329 and 265 are provided to cover these layers.

The insulating layers 264 and 265 each function as an interlayer insulating layer. The insulating layer 329 functions as a barrier layer that prevents diffusion of impurities (e.g., water and hydrogen) from the insulating layer 265 or the like into the transistor 320. As the insulating layer 329, an insulating film similar to the insulating layers 328 and 332 can be used.

A plug 274 connected to one of the pair of conductive layers 325 is provided to be embedded in the insulating layers 265, 329, and 264. Here, the plug 274 preferably includes a conductive layer 274a that covers a side surface of an opening portion formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

### [Display Device 700E]

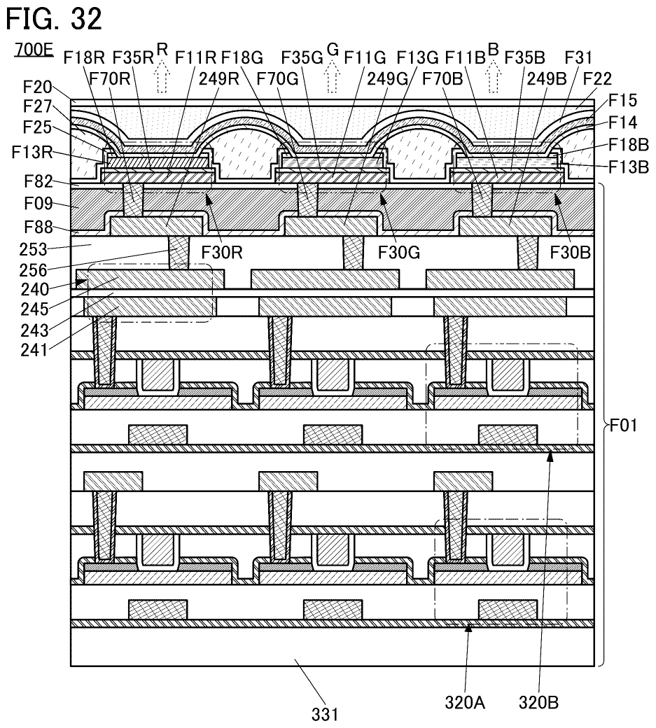

The display device 700E illustrated in FIG. 32 has a structure in which a transistor 320A and a transistor 320B each including an oxide semiconductor in a semiconductor where a channel is formed are stacked.

The description of the display device 700D can be referred to for the transistor 320A, the transistor 320B, and the components around them.

Although the structure in which two transistors each including an oxide semiconductor are stacked is described, one embodiment of the present invention is not limited thereto. For example, three or more transistors can be stacked.

### [Display Device 700F]

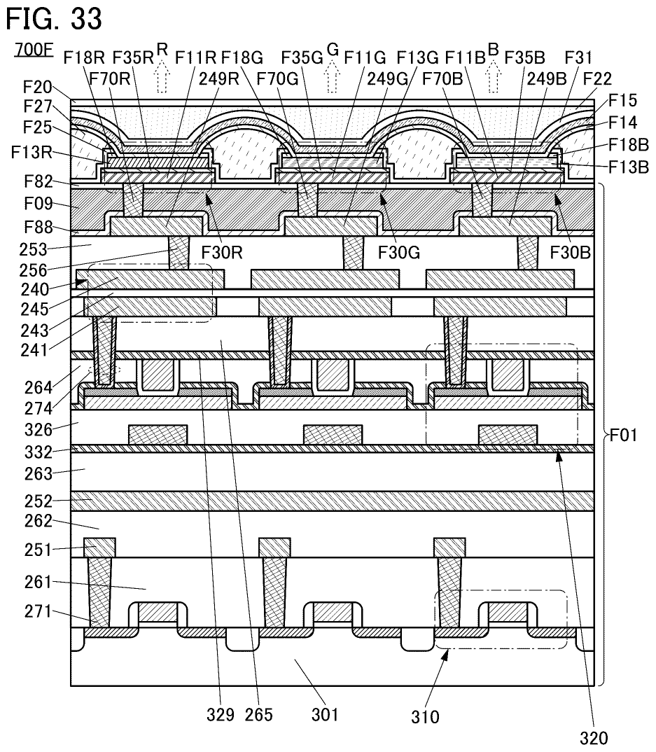

In the display device 700F illustrated in FIG. 33, the transistor 310 whose channel is formed in the substrate 301 and the transistor 320 including an oxide semiconductor in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layers 251 and 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistors 310 and 320 can also be used as transistors included in a variety of circuits such as an arithmetic circuit and a memory circuit.

With such a structure, not only the pixel circuit but also the driver circuit or the like can be formed directly under the light-emitting device; thus, the display device can be downsized as compared with the case where the driver circuit is provided around a display region.

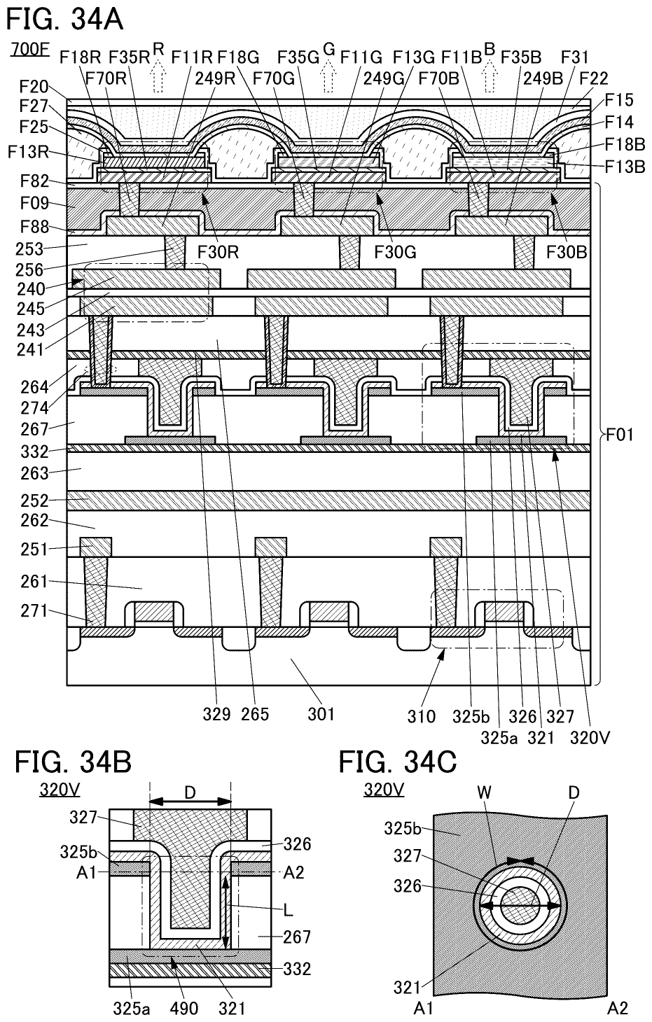

FIG. 34A illustrates a structure example different from that in FIG. 33. The display device 700F illustrated in FIG. 34A has a structure where the transistor 310 whose channel is formed in the substrate 301 and a transistor 320V are stacked.

An enlarged view of the transistor 320V is illustrated in FIG. 34B. FIG. 34C illustrates a cross-sectional view along dashed-dotted line A1-A2 in FIG. 34B.

The transistor 320V includes the conductive layer 327 functioning as a first gate electrode, the insulating layer 326 functioning as a first gate insulating layer, the semiconductor layer 321, and conductive layers 325a and 325b. The conductive layer 325a functions as one of a source and a drain, and the conductive layer 325b functions as the other of the source and the drain. An oxide semiconductor can be suitably used for the semiconductor layer 321, for example.

The conductive layer 325a is provided over the insulating layer 332, an insulating layer 267 is provided over the conductive layer 325a, and the conductive layer 325b is provided over the insulating layer 267. The conductive layer 325b and the insulating layer 267 include an opening portion 490 reaching the conductive layer 325a. The semiconductor layer 321 is provided to cover the opening portion 490 and is in contact with the conductive layer 325a in the opening portion 490. The semiconductor layer 321 is in contact with a side surface of the insulating layer 267 and a side surface of the conductive layer 325b. The semiconductor layer 321 is preferably in contact with not only the side surface of the conductive layer 325b but also the top surface of the conductive layer 325b. In the semiconductor layer 321, the region in contact with the conductive layer 325a functions as one of a source region and a drain region, and the region in contact with the conductive layer 325b functions as the other of the source region and the drain region. In the semiconductor layer 321, the channel formation region is positioned between the source region and the drain region. The insulating layer 326 is provided over the semiconductor layer 321, and the conductive layer 327 is provided over the insulating layer 326. The conductive layer 327 includes a region overlapping with the semiconductor layer 321 with the insulating layer 326 therebetween in the opening portion.

As the insulating layer 267, inorganic insulating films such as an oxide insulating film, a nitride insulating film, an oxynitride insulating film, and a nitride oxide insulating film can be suitably used. For example, one or more of a silicon oxide film, a silicon oxynitride film, an aluminum oxide film, a silicon nitride film, and a silicon nitride oxide film can be suitably used as the insulating layer 267.

In the transistor 320V, a source electrode and a drain electrode are positioned at different levels from the formation surface (here, the top surface of the insulating layer 332) and a drain current flows in a direction perpendicular or substantially perpendicular to the top surface of the insulating layer 332. In other words, the channel length direction includes a height (vertical) component; therefore, the transistor 320V can also be referred to as a vertical field effect transistor (VFET), a vertical transistor, a vertical-channel transistor, or a vertical-channel-type transistor.

The channel length L of the transistor 320V can be controlled by the thickness of an insulating layer (here, the insulating layer 267) sandwiched between the source electrode and the drain electrode. Thus, the transistor 320V having a channel length L (e.g., less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm) that is shorter than the minimum exposure size of a light-exposure apparatus used for manufacturing the transistor can be fabricated with high accuracy. When the channel length L of the transistor 320V is shortened, the on-state current thereof can be increased. Accordingly, the display device with high-speed operation can be provided.

In the transistor 320V, the source electrode, the semiconductor layer, and the drain electrode are provided to overlap with each other. Thus, the area occupied by the transistor 320V can be significantly reduced as compared with a so-called planar transistor in which the source electrode, the semiconductor layer, and the drain electrode are arranged in a planar shape. When a VFET is used for a pixel circuit of the display device, the area occupied by the pixel circuit can be reduced, so that a high-resolution display device can be obtained.

As illustrated in FIG. 34C, the opening portion 490 is formed to be circular or substantially circular in the top view, whereby the semiconductor layer 321, the insulating layer 326, and the conductive layer 327 are concentrically provided. This makes the distance between the conductive layer 327 and the semiconductor layer 321 substantially uniform, so that a gate electric field can be substantially uniformly applied to the semiconductor layer 321.

A side surface of the conductive layer 327 faces the side surface of the semiconductor layer 321 with the insulating layer 326 therebetween. That is, in the top view, all the circumference of the semiconductor layer 321 serves as the channel formation region. In this case, for example, the channel width W of the transistor 320V is determined by the length of the outer circumference of the semiconductor layer 321. In other words, the channel width W of the transistor 320V is determined by the maximum width of the opening portion 490 (the maximum diameter in the case where the opening portion 490 is circular in the top view). In FIGS. 34B and 34C, the maximum width D of the opening portion 490 is indicated by a solid double-headed arrow. In FIG. 34C, the channel width W of the transistor 320V is indicated by a dashed-dotted double-headed arrow. By increasing the maximum width D of the opening portion 490, the channel width per unit area can be increased and the on-state current can be increased.

In the case where the opening portion 490 is formed by a photolithography method, the maximum width D of the opening portion 490 is greater than or equal to the minimum exposure size of a light-exposure apparatus. In addition, the maximum width D of the opening portion 490 is determined by the thicknesses of the semiconductor layer 321, the insulating layer 326, and the conductive layer 327 provided in the opening portion 490. The maximum width D of the opening portion 490 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 490 is circular in the top view, the maximum width D of the opening portion 490 corresponds to the diameter of the opening portion 490, and the channel width W can be “D×π”.

Note that the structure of the transistor 320V described here can also be applied to other structure examples.

### [Display Device 700G]

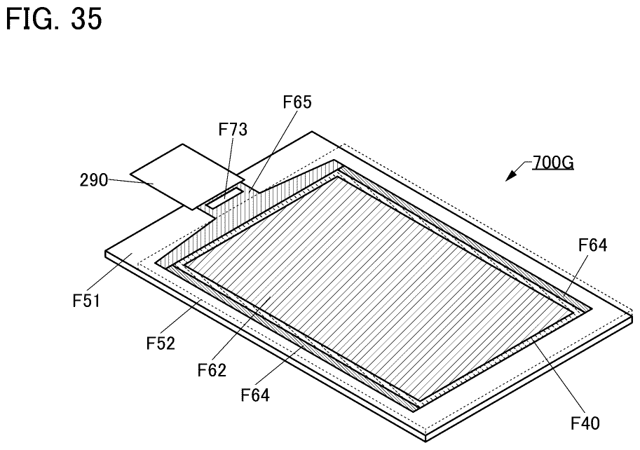

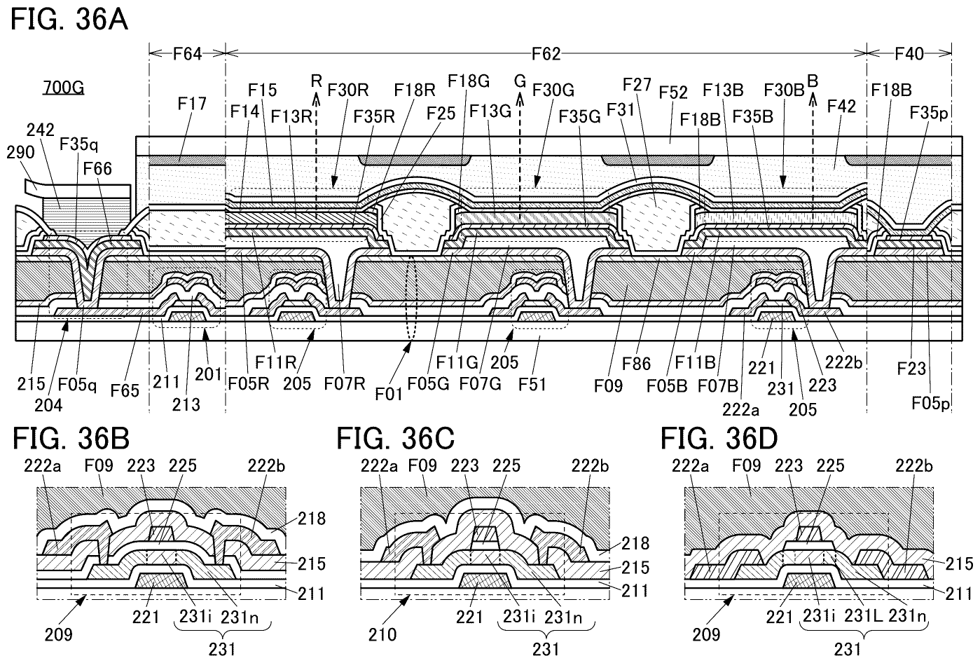

FIG. 35 is a perspective view of a display device 700G, and FIG. 36A is a cross-sectional view of the display device 700G.

In the display device 700G, a substrate F52 and a substrate F51 are bonded to each other. In FIG. 35, the substrate F52 is indicated by a dashed line.

The display device 700G includes a display portion F62, a connection portion F40, circuits F64, a wiring F65, and the like. FIG. 35 illustrates an example where an integrated circuit F73 and the FPC 290 are mounted on the display device 700G. Thus, the structure illustrated in FIG. 35 can be regarded as a display module including the display device 700G, the integrated circuit (IC), and the FPC.

The connection portion F40 is provided outside the display portion F62. The connection portion F40 can be provided along one or more sides of the display portion F62. The number of the connection portions F40 can be one or more. FIG. 35 illustrates an example where the connection portion F40 is provided to surround the four sides of the display portion. The common electrode of the light-emitting device is connected to a conductive layer in the connection portion F40, and thus a potential can be supplied to the common electrode.

As the circuit F64, a scan line driver circuit can be used, for example.

The wiring F65 has a function of supplying a signal and electric power to the display portion F62 and the circuits F64. The signal and electric power are input to the wiring F65 from the outside through the FPC 290 or from the integrated circuit F73.

FIG. 35 illustrates an example where the integrated circuit F73 is provided over the substrate F51 by a chip on glass (COG) method, a chip on film (COF) method, or the like. An IC including a scan line driver circuit, a signal line driver circuit, or the like can be used as the integrated circuit F73, for example. Note that the display device 700G and the display module are not necessarily provided with an IC. The IC can be mounted on the FPC by a COF method or the like.

FIG. 36A illustrates an example of cross sections of part of a region including the FPC 290, part of the circuit F64, part of the display portion F62, part of the connection portion F40, and part of a region including an end portion of the display device 700G.

The display device 700G illustrated in FIG. 36A includes a transistor 201, a transistor 205, the light-emitting devices F30R, F30G, and F30B, and the like between the substrates F51 and F52. The transistors 201 and 205 are provided over the substrate F51, an insulating layer 215 is provided over the transistors 201 and 205, the light-blocking layer F09 is provided over the insulating layer 215, and an insulating layer F86 is provided over the light-blocking layer F09. The light-emitting devices F30R, F30G, and F30B are provided over the insulating layer F86.

In FIG. 36A, conductive layers F05R, F05G, F05B, and F05p are provided over the insulating layer F86. Layers F07R, F07G, and F07B are provided over the conductive layers F05R, F05G, and F05B. The pixel electrodes F11R, F11G, and F11B are provided to cover the conductive layers F05R, F05G, and F05B and the layers F07R, F07G, and F07B. An electrode F23 is provided over the conductive layer F05p, and a conductive layer F35p is provided over the electrode F23.

The conductive layer F05B is in contact with a conductive layer 222b included in the transistor 205 in an opening portion provided in the insulating layer F86, the light-blocking layer F09, the insulating layer 215, and an insulating layer 213 and is connected to the conductive layer 222b. The pixel electrode F11B is connected to the conductive layer 222b through the conductive layer F05B. The same applies to the pixel electrode F11R and the conductive layer F05R and the pixel electrode F11G and the conductive layer F05G; thus, the detailed description thereof is omitted.

In the display portion F62, the light-blocking layer F09 is provided over the transistor 205. In the circuit F64, the light-blocking layer F09 is provided over the transistor 201. Providing the light-blocking layer F09 in the display portion F62 and the circuit F64 can inhibit entry of external light and light emitted from the light-emitting devices into the transistors included in the display device; accordingly, variation of the electrical characteristics of the transistors due to light can be inhibited. Thus, a highly reliable pixel circuit and a highly reliable driver circuit can be obtained, so that a highly reliable display device can be provided.

A side surface and part of the top surface of each of the layers F13B, F13G, and F13R are covered with the insulating layers F25 and F27. The mask layer F18B is positioned between the layer F13B and the insulating layer F25. The mask layer F18G is positioned between the layer F13G and the insulating layer F25, and the mask layer F18R is positioned between the layer F13R and the insulating layer F25. The common layer F14 is provided over the layers F13B, F13G, and F13R and the insulating layers F25 and F27, and the common electrode F15 is provided over the common layer F14. The common layer F14 and the common electrode F15 are each a continuous film provided to be shared by a plurality of light-emitting devices.

The protective layer F31 is provided over the light-emitting devices F30R, F30G, and F30B. The protective layer F31 and the substrate F52 are bonded to each other with an adhesive layer F42. The substrate F52 is provided with a light-blocking layer F17. A solid sealing structure, a hollow sealing structure, or the like can be employed to seal the light-emitting devices. In FIG. 36A, a solid sealing structure is employed, in which a space between the substrate F52 and the substrate F51 is filled with the adhesive layer F42. Alternatively, a hollow sealing structure can be employed, in which the space is filled with an inert gas (e.g., nitrogen or argon). Here, the adhesive layer F42 may be provided not to overlap with the light-emitting device. The space may be filled with a resin different from that of the frame-like adhesive layer F42.

The protective layer F31 is provided at least in the display portion F62, and preferably provided to cover the entire display portion F62. The protective layer F31 is preferably provided to cover not only the display portion F62 but also the connection portion F40 and the circuit F64. It is also preferable that the protective layer F31 be provided to extend to the end portion of the display device 700G. Meanwhile, a connection portion 204 has a portion not provided with the protective layer F31 so that the FPC 290 and a conductive layer F66 are connected to each other.

The connection portion 204 is provided in a region of the substrate F51 where the substrate F52 does not overlap. In the connection portion 204, the wiring F65 is connected to the FPC 290 through a conductive layer F05q, the conductive layer F66, a conductive layer F35q, and a connection layer 242. The conductive layer F05q can be formed in the same step as the conductive layers F05R, F05G, and F05B, for example. The conductive layer F66 can be formed in the same step as the pixel electrodes F11R, F11G, and F11B, for example. The conductive layer F35q can be formed in the same step as the conductive layers F35R, F35G, and F35B, for example. On the top surface of the connection portion 204, the conductive layer F35q is exposed. Thus, the connection portion 204 and the FPC 290 can be connected to each other through the connection layer 242.

For example, the protective layer F31 is formed over the entire surface of the display device 700G and then a region of the protective layer F31 overlapping with the conductive layer F35q is removed using a mask, so that the conductive layer F35q can be exposed.

Here, another layer (e.g., a layer corresponding to the layer F07R) is not provided between the conductive layers F05q and F66. Accordingly, the contact area between the conductive layers F05q and F66 is increased, so that the contact resistance can be reduced. Note that another layer (e.g., a layer corresponding to the layer F07R) can be provided between the conductive layers F05q and F66.

Furthermore, a stacked-layer structure of at least one organic layer and a conductive layer can be provided over the conductive layer F35q, and the protective layer F31 can be provided over the stacked-layer structure. Then, a peeling trigger (a portion that can be a trigger of peeling) can be formed in the stacked-layer structure using laser or a sharp cutter (e.g., a needle or a utility knife) to selectively remove the stacked-layer structure and the protective layer F31 thereover, so that the conductive layer F35q can be exposed. For example, the protective layer F31 can be selectively removed when an adhesive roller is pressed to the substrate F51 and then moved relatively while being rolled. Alternatively, an adhesive tape can be attached to the substrate F51 and then the protective layer F31 is peeled. Since adhesion between the organic layer and the conductive layer or between the organic layers is low, separation occurs at the interface between the organic layer and the conductive layer or in the organic layer. Thus, a region of the protective layer F31 overlapping with the conductive layer F35q can be selectively removed. Note that when the organic layer and the like remain over the conductive layer F35q, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layers F13B, F13G, and F13R, for example. The organic layer may be formed concurrently with or provided separately from the layer F13B, F13G, and F13R. The conductive layer can be formed using the same process and the same material as the common electrode F15. An ITO film is preferably formed as the common electrode F15 and the conductive layer, for example. Note that in the case where a stacked-layer structure is used for the common electrode F15, at least one of the layers included in the common electrode F15 is provided as the conductive layer.

The top surface of the conductive layer F35q may be covered with a mask so that the protective layer F31 is not provided over the conductive layer F35q. As the mask, a metal mask (area metal mask) or a tape or a film having adhesiveness or attachability may be used. The protective layer F31 is formed while the mask is placed and then the mask is removed, so that the conductive layer F35q can be kept exposed even after the protective layer F31 is formed.

With such a method, a region not provided with the protective layer F31 can be formed in the connection portion 204, and the conductive layer F35q and the FPC 290 can be connected to each other through the connection layer 242 in the region.

Although the structure where the conductive layers F66 and F35q are provided in the connection portion 204 is described here, one embodiment of the present invention is not limited thereto. The conductive layer F35q is not necessarily provided in the connection portion 204. In the case where the conductive layer F35q is not provided in the connection portion 204, the conductive layer F66 can be exposed on the top surface of the connection portion 204 and the conductive layer F66 can be in contact with the connection layer 242.

The display device 700G has a top-emission structure. Light from the light-emitting device is emitted toward the substrate F52. For the substrate F52, a material having a high visible-light-transmitting property is preferably used. The pixel electrode contains a material that reflects visible light, and the counter electrode (the common electrode F15) contains a material that transmits visible light.

The transistors 201 and 205 can be formed in the same step.

An insulating layer 211, the insulating layer 213, the insulating layer 215, the light-blocking layer F09, and the insulating layer F86 are provided in this order over the substrate F51. Part of the insulating layer 211 functions as a gate insulating layer of each transistor. Part of the insulating layer 213 functions as a gate insulating layer of each transistor. The insulating layer 215 is provided to cover the transistors. The light-blocking layer F09 is provided to cover the transistors and inhibits light incidence on the transistors. Note that the number of gate insulating layers and the number of insulating layers covering the transistors are not limited and can each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and improve the reliability of a display device.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like can be used. A stack including two or more of the above insulating films can also be used.

Each of the transistors 201 and 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates can be provided above and below a semiconductor layer where a channel is formed.

The structure in which the semiconductor layer where a channel is formed is provided between two gates is employed for the transistors 201 and 205. The two gates can be connected to each other and supplied with the same signal to operate the transistor. Alternatively, the threshold voltage of the transistor can be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) can be used. It is preferable to use a single crystal semiconductor or a semiconductor having crystallinity, in which case deterioration of the transistor characteristics can be inhibited.

It is preferable that a semiconductor layer of a transistor contain an oxide semiconductor. That is, an OS transistor including an oxide semiconductor in its channel formation region is preferably used in the display device of this embodiment.

As the oxide semiconductor having crystallinity, a c-axis aligned crystalline oxide semiconductor (CAAC-OS), a nanocrystalline oxide semiconductor (nc-OS), and the like are given.

Alternatively, a transistor containing silicon in its channel formation region (a Si transistor) can be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows simplification of an external circuit mounted on the display device and a reduction in costs of parts and mounting costs.

The OS transistor has much higher field-effect mobility than a transistor containing amorphous silicon. In addition, the OS transistor has an extremely low leakage current between a source and a drain in an off state (hereinafter also referred to as off-state current), and electric charge accumulated in a capacitor that is connected in series to the transistor can be held for a long period. Furthermore, the power consumption of the display device can be reduced with the OS transistor.

To increase the emission luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor in the pixel circuit, current flowing between the source and the drain can be set minutely in accordance with a change in gate-source voltage; hence, the amount of current flowing through the light-emitting device can be controlled. Accordingly, the gray level in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

Examples of the oxide semiconductor that can be used for the semiconductor layer include indium oxide, gallium oxide, and zinc oxide. The oxide semiconductor preferably contains at least indium or zinc. The oxide semiconductor preferably contains one or two or more selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the oxide semiconductor is preferably one or more kinds of the above elements, further preferably one or more kinds selected from gallium, aluminum, tin, and yttrium, still further preferably one or more kinds selected from gallium, aluminum, and tin. These elements are further preferable because they have high bonding energy with oxygen and have substantially the same ion radius as indium or zinc. In addition, tin is tetravalent and is preferable because the carrier mobility of the semiconductor layer can be increased. In this specification and the like, a metal element and a metalloid element may be collectively referred to as a “metal element”, and a “metal element” in this specification and the like may refer to a metalloid element.

For example, the semiconductor layer can be formed using indium zinc oxide (also referred to as In—Zn oxide or IZO (registered trademark)), indium tin oxide (also referred to as In—Sn oxide or ITO), indium titanium oxide (In—Ti oxide), indium gallium oxide (In—Ga oxide), indium tungsten oxide (also referred to as In—W oxide or IWO), indium gallium aluminum oxide (In—Ga—Al oxide), indium gallium oxide (In—Ga oxide), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon (also referred to as ITSO), gallium tin oxide (Ga—Sn oxide), aluminum tin oxide (Al—Sn oxide), or the like can be used.

Instead of indium or in addition to indium, the oxide semiconductor can contain one or more kinds of metal elements with large period numbers in the periodic table. The larger the overlap between orbits of metal elements is, the more likely it is that the oxide semiconductor will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

By increasing the proportion of the number of indium atoms in the total number of atoms of all the metal elements included in the oxide semiconductor, the field-effect mobility of the transistor can be increased. In addition, the transistor can have a high on-state current.

In this specification and the like, the proportion of the number of indium atoms in the total number of atoms of all the metal elements contained is sometimes referred to as indium content percentage. The same applies to other metal elements. In the case where a plurality of elements are contained as the element M, the sum of the proportion of the number of the element M atoms in the total number of atoms of all the metal elements contained can be referred to as element M content percentage.

Furthermore, an oxide semiconductor having a high zinc content percentage has high crystallinity, whereby diffusion of impurities in the oxide semiconductor can be inhibited. Consequently, a change in electrical characteristics of the transistor is suppressed, and the reliability of the transistor can be increased.

By increasing the element M content percentage in the oxide semiconductor, the oxide semiconductor can have a large band gap. In addition, formation of oxygen vacancies (V_{O}) in the oxide semiconductor is inhibited; accordingly, generation of carriers due to oxygen vacancies (V_{O}) and a shift in the threshold voltage of the transistor can be inhibited. Thus, the cutoff current can be reduced, so that a normally-off transistor can be obtained. Alternatively, a transistor with a low off-state current can be provided. Furthermore, changes in the electrical characteristics of the transistor can be reduced to improve the reliability of the transistor.

The composition of the oxide semiconductor used for the semiconductor layer affects the electrical characteristics and reliability of the transistor. Therefore, by determining the composition of the oxide semiconductor in accordance with the electrical characteristics and reliability required for the transistor, the semiconductor device can have both excellent electrical characteristics and high reliability.

When the oxide semiconductor is In-M-Zn oxide, the proportion of the number of In atoms is preferably higher than or equal to that of the number of element M atoms in the In-M-Zn oxide. For example, In-M-Zn oxide with metal elements in any of the following atomic ratios can be used: In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=5:1:9, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the vicinity thereof. Note that the vicinity of the atomic ratio includes ±30% of an intended atomic ratio. By increasing the proportion of the number of indium atoms in the oxide semiconductor, the on-state current or field-effect mobility of the transistor can be increased.

The proportion of the number of In atoms can also be lower than that of the number of element M atoms in the In-M-Zn oxide. Examples of the atomic ratio of the metal elements of such an In-M-Zn oxide include In:M:Zn=1:3:2, In:M:Zn=1:3:3, In:M:Zn=1:3:4, In:M:Zn=1:3:6 and a composition in the vicinity of any of the above atomic ratios. By increasing the proportion of the number of M atoms in the oxide semiconductor, generation of oxygen vacancies (V_{O}) can be inhibited.

In the case where a plurality of elements are contained as the element M, the sum of the atomic ratios of these elements can be the atomic ratio of the element M.

The use of a material with a high indium content for the semiconductor layer enables an increase in the on-state current or field-effect mobility of the transistor. Furthermore, the element M included in the semiconductor layer can inhibit generation of oxygen vacancies (V_{O}). The element M content percentage in the oxide semiconductor contained in the semiconductor layer is preferably higher than or equal to 0.1% and lower than or equal to 25%, further preferably higher than or equal to 0.1% and lower than or equal to 20%, still further preferably higher than or equal to 0.1% and lower than or equal to 10%, yet further preferably higher than or equal to 0.1% and lower than or equal to 8%, yet still further preferably higher than or equal to 0.1% and lower than or equal to 6%, yet still further preferably higher than or equal to 0.1% and lower than or equal to 4%. Accordingly, a transistor with favorable electrical characteristics can be provided. For example, an oxide semiconductor with In:M:Zn of 40:1:10 or the vicinity thereof is preferably used. The element M is preferably one or more kinds of the above elements, further preferably one or more kinds selected from aluminum, gallium, tin, and yttrium. Specifically, an oxide semiconductor with In:Sn:Zn of 40:1:10 or the vicinity thereof can be suitably used. Alternatively, an oxide semiconductor with In:Al:Zn of 40:1:10 or the vicinity thereof can be suitably used.

In the case where an oxide semiconductor having a polycrystalline structure is used for the semiconductor layer, the grain boundary becomes a recombination center and captures carriers and thus decreases the on-state current of the transistor, in some cases. When an oxide semiconductor having a polycrystalline structure is used for the semiconductor layer, unevenness of the surface of the semiconductor layer is increased in some cases. This increases a step in the formation surface of a layer formed over the semiconductor layer, so that generation of defects such as step disconnection or voids in the layer sometimes occurs. In the case where an oxide semiconductor with a composition that tends to form a polycrystalline structure is used for the semiconductor layer, an element that hinders crystallization is preferably contained. This inhibits the semiconductor layer from having a polycrystalline structure, so that a transistor with a high on-state current can be obtained. In addition, coverage with the layer formed over the semiconductor layer can be improved, so that generation of defects such as step disconnection or voids in the layer can be inhibited.

For example, indium tin oxide containing silicon (ITSO) is less likely to form a polycrystalline structure than indium tin oxide (ITO) and can be suitably used for the semiconductor layer. In the case where ITSO is used, silicon content percentage is preferably higher than or equal to 1% and lower than or equal to 20%, further preferably higher than or equal to 3% and lower than or equal to 20%, still further preferably higher than or equal to 3% and lower than or equal to 15%, yet further preferably higher than or equal to 5% and lower than or equal to 15%. Specifically, an oxide semiconductor with In:Sn:Si of 45:5:4 or 95:5:8 or the vicinity thereof can be suitably used. In the case where indium tin oxide containing silicon (ITSO) is used for the semiconductor layer, the semiconductor layer preferably has crystallinity. Note that the semiconductor layer can include an amorphous region. The semiconductor layer can be made amorphous.

An oxide semiconductor that does not contain the element M can be used for the semiconductor layer. In the case where the oxide semiconductor is In—Zn oxide, examples of the atomic ratio of metal elements include In:Zn=1:1, In:Zn=2:1, In:Zn=1:2, In:Zn=3:1, In:Zn=3:2, In:Zn=2:3, In:Zn=4:1, In:Zn=4:3, In:Zn=5:1, In:Zn=5:2, In:Zn=5:3, In:Zn=5:4, In:Zn=5:6, In:Zn=5:7, In:Zn=5:8, In:Zn=5:9, In:Zn=7:1, In:Zn=10:1, In:Zn=10:3, In:Zn=10:7, or the vicinity thereof. Furthermore, the proportion of the number of In atoms is preferably higher than or equal to that of the number of Zn atoms. By increasing the proportion of the number of In atoms in the oxide semiconductor, the on-state current or field-effect mobility of the transistor can be increased.

Analysis of the composition of the semiconductor layer can be performed by energy dispersive X-ray spectrometry (EDX), X-ray photoelectron spectroscopy (XPS), inductively coupled plasma-mass spectrometry (ICP-MS), or inductively coupled plasma-atomic emission spectrometry (ICP-AES) can be used, for example. Alternatively, these methods can be combined as appropriate to be employed for analysis. It is preferable that peak separation of a spectrum obtained by the analysis be performed to identify and quantify an element. Note that as for an element whose content percentage is low, the actual content percentage may be different from the content percentage obtained by analysis because of the influence of the analysis accuracy. In the case where the element M content percentage is low, for example, the element M content percentage obtained by analysis is lower than the actual content percentage, the element M content percentage may be difficult to quantify, or the element M is below the lower detection limit in some cases.

A sputtering method or an ALD method can be suitably used for forming the oxide semiconductor. As an ALD method, a thermal ALD method or a plasma-enhanced ALD (PEALD) method can be used. Note that in the case where the oxide semiconductor is deposited by a sputtering method, the composition of the deposited oxide semiconductor may be different from the composition of a sputtering target. In particular, the content percentage of the deposited oxide semiconductor may be reduced to approximately 50% of that of the sputtering target. The oxide semiconductor can also be deposited by a PECVD method.

It is preferable to use an oxide semiconductor having crystallinity for the semiconductor layer. Examples of the structure of an oxide semiconductor having crystallinity include a c-axis aligned crystal (CAAC) structure, a polycrystalline structure, and a nano-crystal (nc) structure. With use of an oxide semiconductor having crystallinity, the density of defect states in the semiconductor layer can be reduced, which enables the semiconductor device to have high reliability.

The semiconductor layer is preferably formed using a CAAC-OS or an nc-OS.

The CAAC-OS includes a plurality of layered crystals. The c-axis of the crystal is aligned in the normal direction of the formation surface. The semiconductor layer preferably includes a layered crystal parallel or substantially parallel to the formation surface. Accordingly, the layered crystal of the semiconductor layer is formed parallel or substantially parallel to the channel length direction of the transistor, whereby the transistor can have a high on-state current.

The use of an oxide semiconductor having high crystallinity in a channel formation region can reduce the density of defect states in the channel formation region. By contrast, the use of an oxide semiconductor having low crystallinity enables a transistor to flow a large amount of current.

The transistors included in the circuit F64 and the transistors included in the display portion F62 may have the same structure or different structures. One structure or two or more kinds of structures may be employed for a plurality of transistors included in the circuit F64. Similarly, one structure or two or more kinds of structures may be employed for a plurality of transistors included in the display portion F62.

All of the transistors included in the display portion F62 may be OS transistors or Si transistors. Alternatively, some of the transistors included in the display portion F62 may be OS transistors and the others may be Si transistors.

For example, when both an LTPS transistor and an OS transistor are used in the display portion F62, the display device can have low power consumption and high drive capability. Note that a structure in which the LTPS transistor and the OS transistor are combined is referred to as LTPO in some cases. As a favorable example, it is preferable that the OS transistor be used as a transistor functioning as a switch for controlling electrical continuity and discontinuity between wirings and the LTPS transistor be used as a transistor for controlling current.

For example, one transistor included in the display portion F62 may function as a transistor for controlling current flowing through the light-emitting device and be referred to as a driving transistor. One of a source and a drain of the driving transistor is connected to the pixel electrode of the light-emitting device. An LTPS transistor is preferably used as the driving transistor. Accordingly, the amount of current flowing through the light-emitting device can be increased in the pixel circuit.

By contrast, another transistor included in the display portion F62 may function as a switch for controlling selection or non-selection of a pixel and be referred to as a selection transistor. A gate of the selection transistor is connected to a gate line, and one of a source and a drain thereof is connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having a metal maskless (MML) structure. With this structure, the leakage current that might flow through the transistor and the leakage current that might flow between adjacent light-emitting devices (also referred to as a lateral leakage current, a side leakage current, or the like) can become extremely low. With the structure, a viewer can observe any one or more of the image clearness, the image sharpness, a high chroma, and a high contrast ratio in an image displayed on the display device. When the leakage current that might flow through the transistor and the lateral leakage current that might flow between light-emitting devices are extremely low, display with little leakage of light at the time of black display (what is called black floating) can be achieved.

In particular, in the case where a light-emitting device having the MML structure employs the above-described side-by-side (SBS) structure, a layer provided between light-emitting devices (for example, an organic layer shared by the light-emitting devices, also referred to as a common layer) is disconnected; accordingly, side leakage can be prevented or be made extremely low.

The light-blocking layer F17 is preferably provided on the surface of the substrate F52 on the substrate F51 side. The light-blocking layer F17 can be provided over a region between adjacent light-emitting devices, in the connection portion F40, in the circuit F64, and the like. A variety of optical members can be arranged on the outer surface of the substrate F52.

A material that can be used for the substrate F20 can be used for each of the substrates F51 and F52.

A material that can be used for the resin layer F22 can be used for the adhesive layer F42.

As the connection layer 242, an anisotropic conductive film (ACF), an anisotropic conductive paste (ACP), or the like can be used.

FIGS. 36B to 36D illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor can be provided.

FIG. 36B illustrates an example of the transistor 209 in which the insulating layer 225 covers the top and side surfaces of the semiconductor layer 231. The conductive layers 222a and 222b are in contact with and are connected to the low-resistance regions 231n through opening portions provided in the insulating layers 225 and 215. One of the conductive layers 222a and 222b functions as a source, and the other functions as a drain.

In the transistor 210 illustrated in FIG. 36C, the insulating layer 225 overlaps with the channel formation region 231i of the semiconductor layer 231 and does not overlap with the low-resistance regions 231n. The structure illustrated in FIG. 36C is obtained by processing the insulating layer 225 with the conductive layer 223 as a mask, for example. The insulating layer 215 is provided to cover the insulating layer 225 and the conductive layer 223. The conductive layers 222a and 222b are in contact with and are connected to the low-resistance regions 231n in the opening portions provided in the insulating layer 215.

The insulating layer 225 of the transistor 209 illustrated in FIG. 36D includes a region projecting from the conductive layer 223. The semiconductor layer 231 includes a pair of regions 231L between the channel formation region 231i and the pair of low-resistance regions 231n. The region 231L overlaps with the insulating layer 225 and does not overlap with the conductive layer 223. The electric resistance of the region 231L is substantially equal to or lower than that of the channel formation region 231i. Furthermore, the electric resistance of the region 231L is substantially equal to or higher than that of the low-resistance regions 231n.

The region 231L functions as a buffer region for relieving a drain electric field. The region 231L does not overlap with the conductive layer 223 and thus a channel is hardly formed by application of gate voltage to the conductive layer 223. The region 231L preferably has a higher carrier concentration than the channel formation region. Thus, the region 231L can function as a lightly doped drain (LDD) region. Providing the LDD region achieves a transistor with high drain withstand voltage.

FIG. 36D illustrates a structure where the conductive layers 222a and 222b functioning as the source and the drain are formed in the same step as the conductive layer 223 functioning as the gate. For example, the insulating layer 225 is formed over the semiconductor layer 231, and a conductive film is formed over the semiconductor layer 231 and the insulating layer 225. Then, the conductive film is processed, whereby the conductive layers 222a, 222b, and 223 can be formed. Forming the conductive layers 222a, 222b, and 223 in the same step can simplify the process. Note that in FIG. 36D, the conductive layers 222a and 222b are shown with the same hatching pattern as the conductive layer 223. The insulating layer 215 is provided over the conductive layers 222a, 222b, and 223.

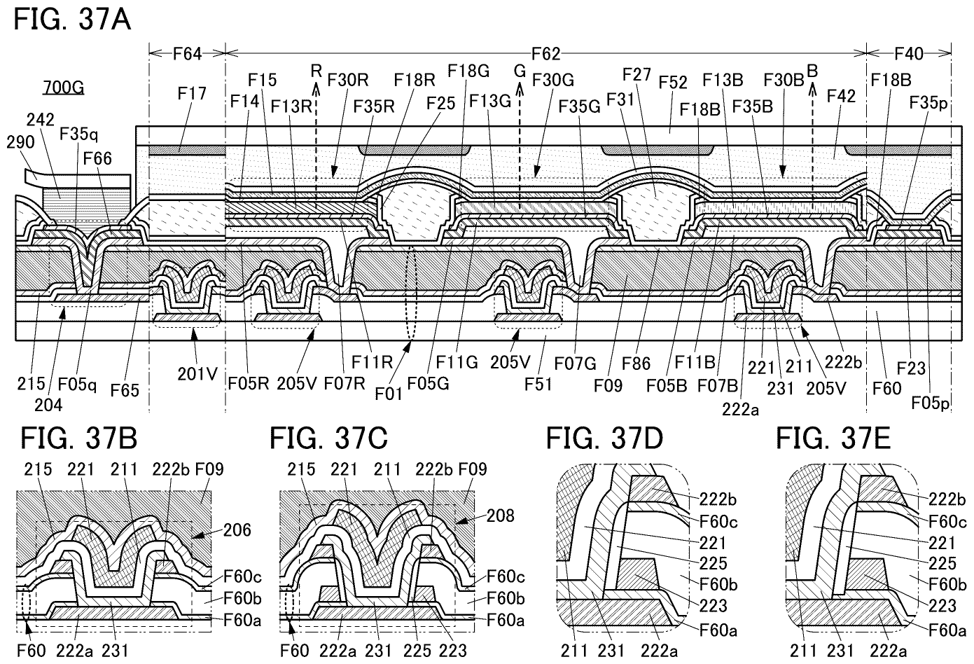

FIGS. 37A to 37C illustrate structure examples different from those of the transistors illustrated in FIGS. 36A to 36D.

FIG. 37A illustrates a structure example where transistors 201V and 205V that are VFETs are used. Each of the transistors 201V and 205V includes the conductive layer 221 functioning as a gate, the insulating layer 211 functioning as a gate insulating layer, the semiconductor layer 231, and the conductive layers 222a and 222b. The conductive layer 222a functions as the one of the source and the drain and the conductive layer 222b functions as the other of the source and the drain.

An insulating layer F60 is provided over the conductive layer 222a, and the conductive layer 222b is provided over the insulating layer F60. The conductive layer 222b and the insulating layer F60 include an opening portion reaching the conductive layer 222a. The semiconductor layer 231 is provided to cover the opening portion and is in contact with the conductive layer 222a in the opening portion. The semiconductor layer 231 is in contact with a side surface of the insulating layer F60 and a side surface of the conductive layer 222b. The semiconductor layer 231 is preferably in contact with not only the side surface of the conductive layer 222b but also the top surface of the conductive layer 222b. In the semiconductor layer 231, a region in contact with the conductive layer 222a functions as one of a source region and a drain region, and a region in contact with the conductive layer 222b functions as the other of the source region and the drain region. In the semiconductor layer 231, a channel formation region is positioned between the source region and the drain region. The insulating layer 211 is provided over the semiconductor layer 231 and the conductive layer 221 is provided over the insulating layer 211. The conductive layer 221 includes a region overlapping with the semiconductor layer 231 with the insulating layer 211 therebetween in the opening portion.

Each of the channel lengths of the transistors 201V and 205V can be controlled by the thickness of an insulating layer (here, the insulating layer F60) sandwiched between its source electrode and its drain electrode. Thus, the transistors 201V and 205V each having a channel length shorter than the minimum exposure size of a light-exposure apparatus used for manufacturing the transistors can be manufactured with high accuracy. When the channel lengths of the transistors 201V and 205V are shortened, the on-state current of the transistors can be increased. Accordingly, the display device with high-speed operation can be provided.

When the VFET is used for a pixel circuit of a display device, the area occupied by the pixel circuit can be reduced, so that the display device can have high resolution. When the VFET is used for a driver circuit (e.g., one or both of a gate line driver circuit and a source line driver circuit) of a display device, the area occupied by the driver circuit can be reduced and the display device can have a narrow bezel.

The insulating layer F60 can have a stacked-layer structure. FIG. 37B illustrates a structure example where the insulating layer F60 includes an insulating layer F60a, an insulating layer F60b over the insulating layer F60a, and an insulating layer F60c over the insulating layer F60b.

A region of the semiconductor layer 231 in contact with at least the insulating layer F60b functions as a channel formation region of a transistor 206. The insulating layer F60b preferably releases oxygen by application of heat. Thus, an oxygen vacancy (V_{O}) and a defect that is an oxygen vacancy (V_{O}) into which hydrogen enters (hereinafter also referred to as V_{O}H) in the channel formation region can be reduced. An oxide insulating film is preferably used as the insulating layer F60b. For example, a silicon oxide film or a silicon oxynitride film can be suitably used as the insulating layer F60b.

Each of the insulating layers F60a and F60c functions as a barrier layer that prevents release of oxygen from the insulating layer F60b to the insulating layer F60a side and the insulating layer F60c side. When the insulating layer F60b is sandwiched between the insulating layers F60a and F60c, the amount of oxygen supplied from the insulating layer F60b to the channel formation region can be increased and oxygen vacancies (V_{O}) and V_{O}H in the channel formation region can be efficiently reduced. Accordingly, a transistor having favorable electrical characteristics and high reliability can be provided. For each of the insulating layers F60a and F60c, any of the above-described materials for the insulating layer 332 can be used.

A transistor 208 illustrated in FIG. 37C includes the insulating layer 225 functioning as a gate insulating layer and the conductive layer 223 functioning as a gate. FIG. 37C illustrates a structure example in which the conductive layer 223 is positioned between the insulating layers F60a and F60b. The insulating layer F60 and the conductive layers 223 and 222b include an opening portion reaching the conductive layer 222a. The insulating layer 225 is provided along a sidewall of the opening portion. The semiconductor layer 231 is provided in contact with the top and side surfaces of the insulating layer 225. The semiconductor layer 231 includes a region sandwiched between the conductive layer 221 and the conductive layer 223 with the insulating layer 211 positioned between the region and the conductive layer 221 and with the insulating layer 225 positioned between the region and the conductive layer 223. FIGS. 37D and 37E are enlarged views of the insulating layer 225, the conductive layer 223, and the vicinity thereof. As illustrated in FIGS. 37D and 37E, the insulating layer F60a includes a region sandwiched between the insulating layer 225 and the conductive layer 222a. When the insulating layer F60a is provided between the insulating layer 225 and the conductive layer 222a, supply of oxygen from the insulating layer 225 to the conductive layer 222a can be reduced. This can inhibit the conductive layer 222a from being oxidized and having high electric resistance. As illustrated in FIG. 37E, the thickness of a region of the insulating layer F60a in contact with the bottom surface of the insulating layer 225 is smaller than the thickness of a region of the insulating layer F60a in contact with the bottom surface of the conductive layer 223 in some cases. At this time, the insulating layer 225 includes a region in contact with the top surface and a side surface of the insulating layer F60a.

### [Display Device 700H]

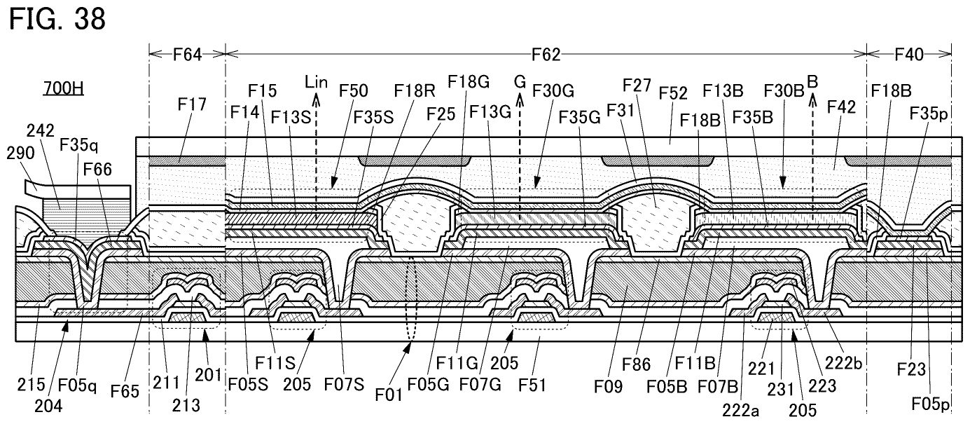

A display device 700H illustrated in FIG. 38 is different from the display device 700G mainly in including the light-receiving device F50.

The light-receiving device F50 includes the pixel electrode F11S, the conductive layer F35S over the pixel electrode F11S, the layer F13S over the conductive layer F35S, the common layer F14 over the layer F13S, and the common electrode F15 over the common layer F14. The layer F13S includes at least an active layer.

A conductive layer F05S is in contact with and is connected to the conductive layer 222b included in the transistor 205 in an opening portion provided in the insulating layer F86, the light-blocking layer F09, and the insulating layers 215 and 213. The pixel electrode F11S is connected to the conductive layer 222b through the conductive layer F05S. A layer F07S is provided over the conductive layer F05S, and the pixel electrode F11S is provided to cover the conductive layer F05S and the layer F07S. The conductive layer F05S includes a depressed portion overlapping with the opening portion provided in the insulating layer F86, the light-blocking layer F09, and the insulating layers 215 and 213. The depressed portion is filled with the layer F07S.

The side surface and part of the top surface of the layer F13S is covered with the insulating layers F25 and F27. A mask layer F18S is positioned between the layer F13S and the insulating layer F25. The common layer F14 is provided over the layer F13S and the insulating layers F25 and F27, and the common electrode F15 is provided over the common layer F14. The common layer F14 is a continuous film shared by the light-receiving device and the light-emitting devices.

This embodiment can be combined with the other embodiments as appropriate.

### Embodiment 4

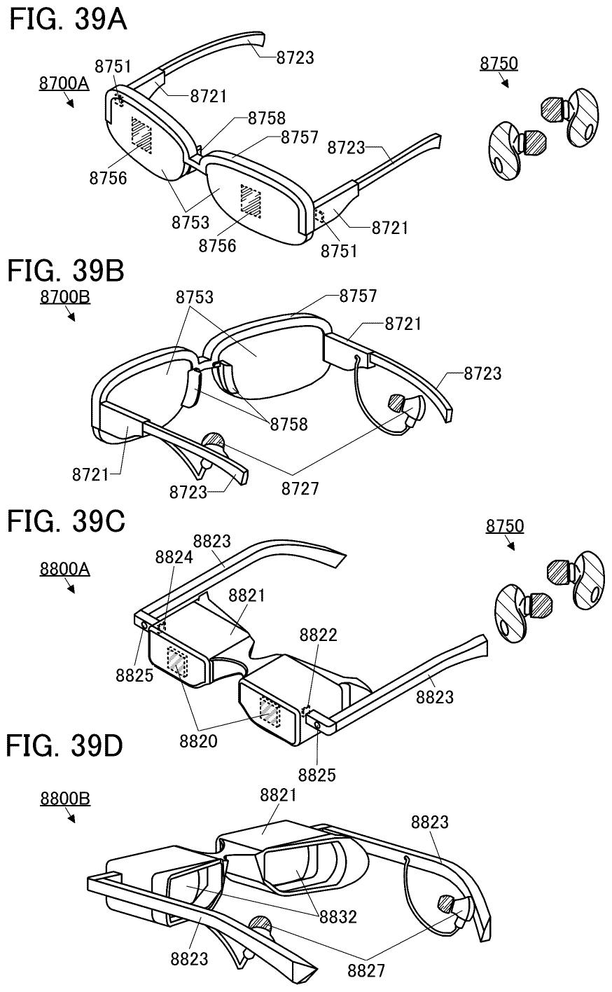

In this embodiment, electronic devices of embodiments of the present invention will be described with reference to FIGS. 39A to 39D, FIGS. 40A to 40F, and FIGS. 41A to 41G.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop computers, a monitor of a computer and the like, digital signage, and a large game machine such as a pachinko machine.

In particular, the display device of one embodiment of the present invention can have high resolution, and thus can be favorably used for an electronic device having a relatively small display portion. Examples of such an electronic device include watch-type and bracelet-type information terminal devices (wearable devices) and wearable devices capable of being worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment can include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 39A to 39D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 8700A illustrated in FIG. 39A and an electronic device 8700B illustrated in FIG. 39B each include a pair of display panels 8751, a pair of housings 8721, a communication portion (not illustrated), a pair of wearing portions 8723, a control portion (not illustrated), an image capturing portion (not illustrated), a pair of optical members 8753, a frame 8757, and a pair of nose pads 8758. Note that the display panels 8751 are omitted in FIG. 39B.

The display device of one embodiment of the present invention can be used for the display panels 8751. Thus, the electronic devices are capable of performing ultrahigh-resolution display.

The electronic devices 8700A and 8700B can each project images displayed on the display panels 8751 onto display regions 8756 of the optical members 8753. Since the optical members 8753 have a light-transmitting property, the user can see images displayed on the display regions, which are superimposed on transmission images seen through the optical members 8753. Accordingly, the electronic devices 8700A and 8700B are electronic devices capable of AR display.

In the electronic devices 8700A and 8700B, a camera capable of capturing images of the front side can be provided as the image capturing portion. Furthermore, when the electronic devices 8700A and 8700B are provided with an acceleration sensor such as a gyroscope sensor, the orientation of the user's head can be sensed and an image corresponding to the orientation can be displayed on the display regions 8756.

The communication portion includes a wireless communication device, and a video signal and the like can be supplied by the wireless communication device. Instead of or in addition to the wireless communication device, a connector that can be connected to a cable for supplying a video signal and a power supply potential can be provided.

The electronic devices 8700A and 8700B are provided with a battery (not illustrated) so that they can be charged wirelessly and/or by wire.

A touch sensor module can be provided in the housing 8721. The touch sensor module has a function of detecting a touch on the outer surface of the housing 8721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 8721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 8800A illustrated in FIG. 39C and an electronic device 8800B illustrated in FIG. 39D each include a pair of display portions 8820, a housing 8821, a communication portion 8822, a pair of wearing portions 8823, a control portion 8824, a pair of image capturing portions 8825, and a pair of lenses 8832. Note that the display portions 8820, the communication portion 8822, and the image capturing portions 8825 are omitted in FIG. 39D.

The display device of one embodiment of the present invention can be used in the display portions 8820. Thus, the electronic devices are capable of performing ultrahigh-resolution display. Such electronic devices provide a high sense of immersion to the user.

The display portions 8820 are positioned inside the housing 8821 so as to be seen through the lenses 8832. When the pair of display portions 8820 display different images, three-dimensional display using parallax can be performed.

The electronic devices 8800A and 8800B can be regarded as electronic devices for VR. The user who wears the electronic device 8800A or the electronic device 8800B can see images displayed on the display portions 8820 through the lenses 8832.

The electronic devices 8800A and 8800B preferably include a mechanism for adjusting the lateral positions of the lenses 8832 and the display portions 8820 so that the lenses 8832 and the display portions 8820 are positioned optimally in accordance with the positions of the user's eyes. Moreover, the electronic devices 8800A and 8800B preferably include a mechanism for adjusting focus by changing the distance between the lenses 8832 and the display portions 8820.

The electronic device 8800A or the electronic device 8800B can be mounted on the user's head with the wearing portions 8823. FIG. 39C and the like illustrate examples where the wearing portion 8823 has a shape like a temple of glasses; however, one embodiment of the present invention is not limited thereto. The wearing portion 8823 can have any shape with which the user can wear the electronic device, for example, a shape of a helmet or a band.

The image capturing portion 8825 has a function of obtaining information on the external environment. Data obtained by the image capturing portion 8825 can be output to the display portion 8820. An image sensor can be used for the image capturing portion 8825. Moreover, a plurality of cameras can be provided so as to support a plurality of fields of view, such as a telescope field of view and a wide field of view.

Although an example where the image capturing portion 8825 is provided is shown here, a range sensor (hereinafter also referred to as a sensing portion) capable of measuring a distance between the user and an object just needs to be provided. In other words, the image capturing portion 8825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 8800A can include a vibration mechanism that functions as bone-conduction earphones. For example, at least one of the display portion 8820, the housing 8821, and the wearing portion 8823 can include the vibration mechanism. Thus, without additionally requiring an audio device such as headphones, earphones, or a speaker, the user can enjoy video and sound only by wearing the electronic device 8800A.

The electronic devices 8800A and 8800B can each include an input terminal. To the input terminal, a cable for supplying a video signal from a video output device or the like, electric power for charging the battery provided in the electronic device, and the like can be connected.

The electronic device of one embodiment of the present invention can have a function of performing wireless communication with earphones 8750. The earphones 8750 include a communication portion (not illustrated) and have a wireless communication function. The earphones 8750 can receive information (e.g., audio data) from the electronic device with the wireless communication function. For example, the electronic device 8700A in FIG. 39A has a function of transmitting information to the earphones 8750 with the wireless communication function. As another example, the electronic device 8800A in FIG. 39C has a function of transmitting information to the earphones 8750 with the wireless communication function.

The electronic device can include an earphone portion. The electronic device 8700B in FIG. 39B includes earphone portions 8727. For example, the earphone portion 8727 can be connected to the control portion by wire. Part of a wiring that connects the earphone portion 8727 and the control portion may be positioned inside the housing 8721 or the wearing portion 8723.

Similarly, the electronic device 8800B in FIG. 39D includes earphone portions 8827. For example, the earphone portion 8827 can be connected to the control portion 8824 by wire. Part of a wiring that connects the earphone portion 8827 and the control portion 8824 may be positioned inside the housing 8821 or the wearing portion 8823. Alternatively, the earphone portions 8827 and the wearing portions 8823 may include magnets. This is preferable because the earphone portions 8827 can be fixed to the wearing portions 8823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 8700A and 8700B) and the goggles-type device (e.g., the electronic devices 8800A and 8800B) are preferable as the electronic device of one embodiment of the present invention.

The electronic device of one embodiment of the present invention can transmit information to earphones by wire or wirelessly.

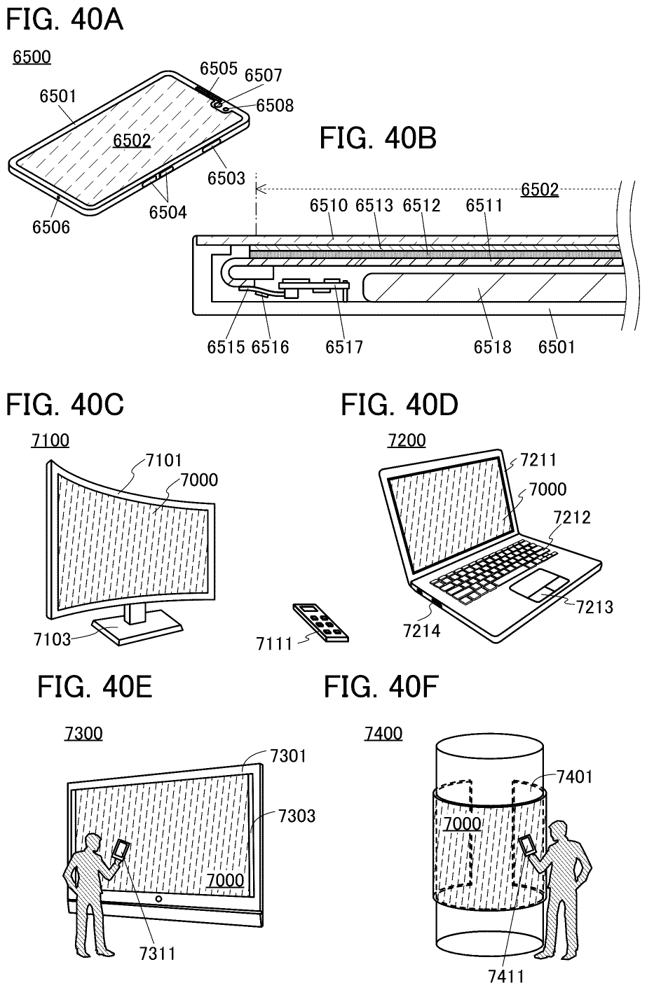

An electronic device 6500 illustrated in FIG. 40A is a portable information terminal that can be used as a smartphone.

The electronic device 6500 includes a housing 6501, a display portion 6502, a power button 6503, buttons 6504, a speaker 6505, a microphone 6506, a camera 6507, and a light source 6508. The display portion 6502 has a touch panel function.

The display device of one embodiment of the present invention can be used in the display portion 6502.

FIG. 40B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 40C illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 40C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 40D illustrates an example of a laptop computer. A computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 40E and 40F illustrate examples of digital signage.

Digital signage 7300 illustrated in FIG. 40E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 40F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 40E and 40F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIGS. 40E and 40F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

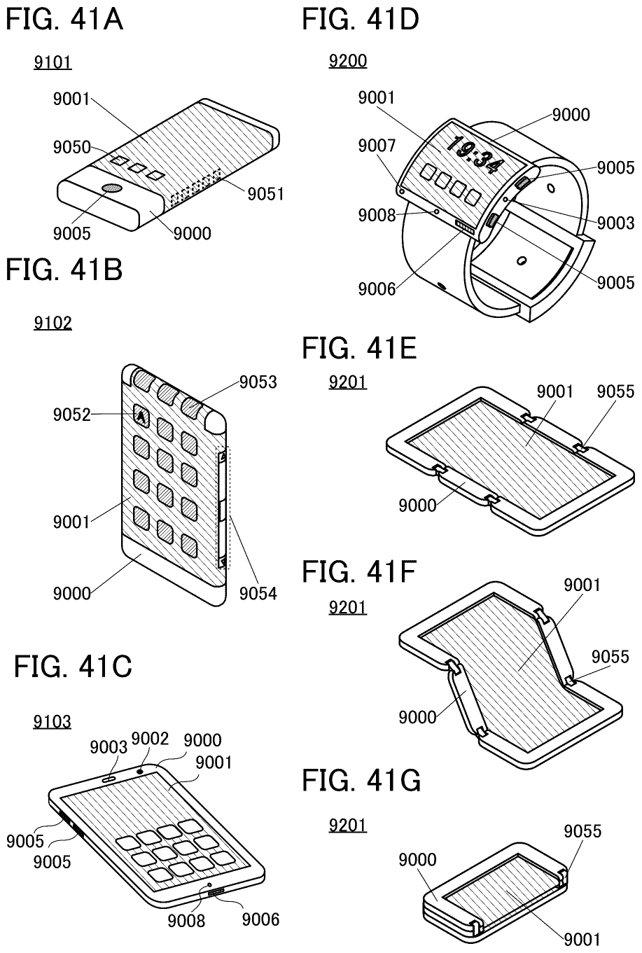

Electronic devices illustrated in FIGS. 41A to 41G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 41A to 41G, the display device of one embodiment of the present invention can be used in the display portion 9001.

The electronic devices illustrated in FIGS. 41A to 41G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 41A to 41G will be described in detail below.

FIG. 41A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 41A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 41B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 41C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 41D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation can be performed by wireless power feeding.

FIGS. 41E to 41G are perspective views of a foldable portable information terminal 9201. FIG. 41E is a perspective view illustrating the portable information terminal 9201 that is opened. FIG. 41G is a perspective view illustrating the portable information terminal 9201 that is folded. FIG. 41F is a perspective view illustrating the portable information terminal 9201 that is shifted from one of the states in FIGS. 41E and 41G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

### Example 1

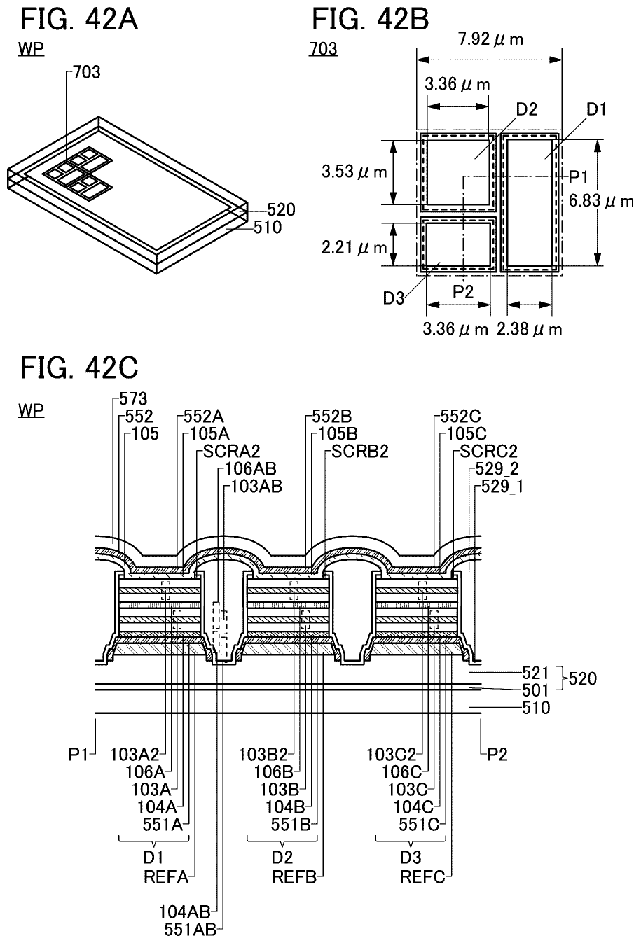

In this example, a workpiece WP fabricated by the method for manufacturing the display device of one embodiment of the present invention will be described with reference to FIGS. 42A to 42C, FIG. 43, FIG. 44, FIG. 45, FIG. 46, and FIG. 47.

FIG. 42A is a perspective view illustrating a structure of the workpiece WP fabricated in this example, and FIG. 42B is a top view illustrating part of FIG. 42A. FIG. 42C is a cross-sectional view taken along a cutting line P1-P2 in FIG. 42B.

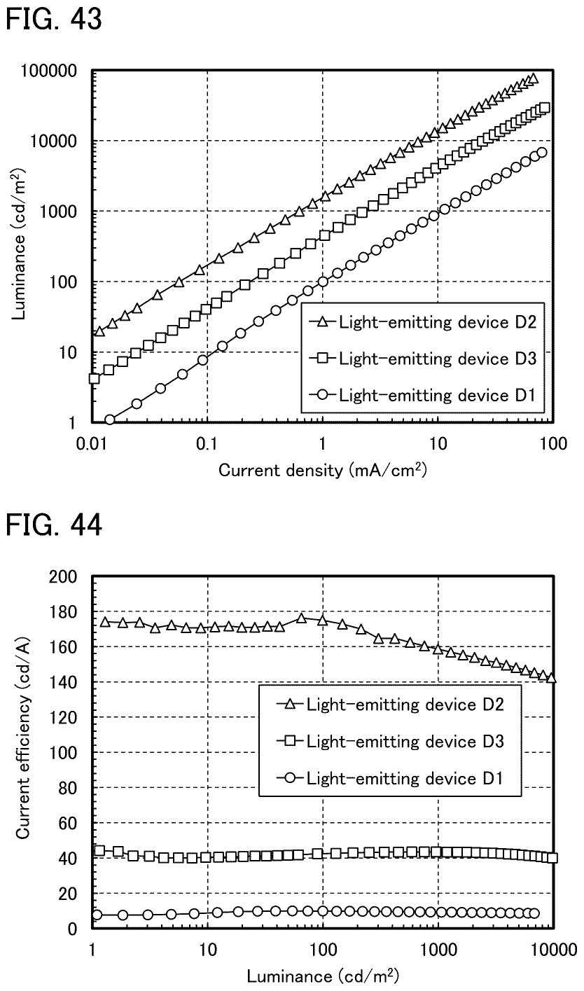

FIG. 43 shows current density-luminance characteristics of light-emitting devices fabricated in this example.

FIG. 44 shows luminance-current efficiency characteristics of the light-emitting devices fabricated in this example.

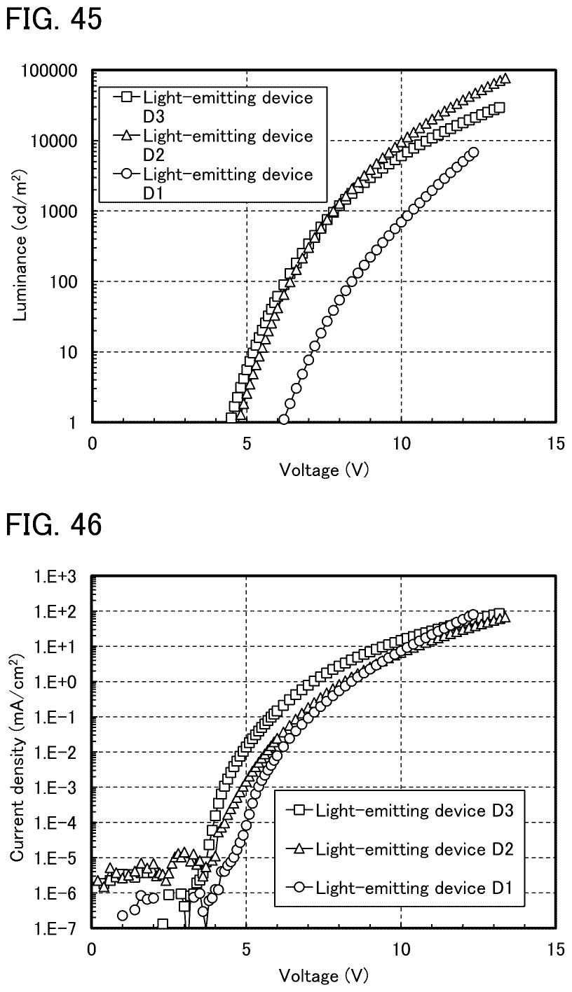

FIG. 45 shows voltage-luminance characteristics of the light-emitting devices fabricated in this example.

FIG. 46 shows voltage-current density characteristics of the light-emitting devices fabricated in this example.

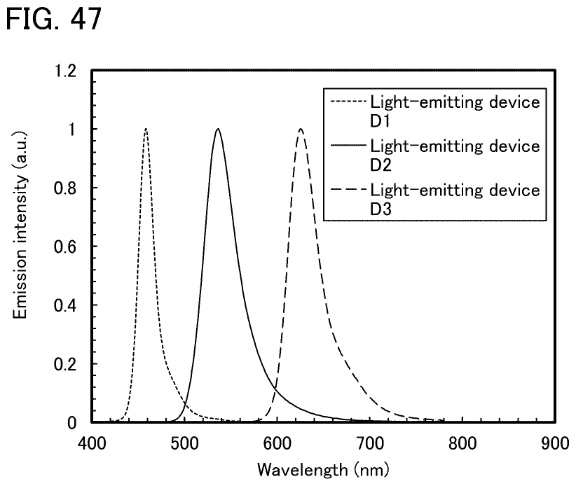

FIG. 47 shows emission spectra of the light-emitting devices fabricated in this example emitting light at a luminance of 1000 cd/m².

### <Example 1 of Workpiece WP>

The fabricated workpiece WP that is described in this example includes the pixel set 703 (see FIG. 42A). The pixel set 703 includes light-emitting devices D1, D2, and D3 (see FIG. 42B). The workpiece WP includes the substrate 510 and the functional layer 520, and the functional layer 520 includes the insulating layer 521 (see FIG. 42C). A silicon substrate was used as the substrate 510, and silicon oxide was used for the insulating layer 521. Note that the workpiece WP does not include a pixel circuit and a driver circuit.

### <<Structure of Light-Emitting Device D1>>

The light-emitting device D1 has a rectangular front surface with a size of 6.83 μm long and 2.38 μm width (see FIG. 42B). The area of the light-emitting device D1 is approximately 16.26 μm² and the perimeter is approximately 18.42 μm.

The light-emitting device D1 includes the electrode 551A, the layer 104A, the unit 103A, the intermediate layer 106A, the unit 103A2, the layer 105A, and the electrode 552A (see FIG. 42C). Note that the electrode 551A is formed over the layer REFA, and the layer 573 is formed over the electrode 552A.

The layer REFA includes a 50-nm-thick layer containing titanium, a 70-nm-thick layer containing aluminum, and a 2-nm-thick layer containing titanium. The electrode 551A contains ITSO.

The layer 104A contains a hole-injection material. Specifically, the layer 104A contains N-(biphenyl-4-yl)-N-[4-(9-phenyl-9H-carbazol-3-yl)phenyl]-9,9-dimethyl-9H-fluoren-2-amine (abbreviation: PCBBiF) and an electron-accepting material (abbreviation: OCHD-003) at PCBBiF:OCHD-003=1:0.03 (weight ratio) and has a thickness of 10 nm. Note that OCHD-003 contains fluorine and has a molecular weight of 672.

The units 103A and 103A2 each include a layer having a hole-transport property, a layer containing a light-emitting material, and a layer having an electron-transport property. The units 103A and 103A2 emit blue light. The intermediate layer 106A supplies electrons to the unit 103A and supplies holes to the unit 103A2. The layer 105A contains an electron-injection material.

### <<Structure of Light-Emitting Device D2>>

The light-emitting device D2 has a rectangular front surface with a size of 3.53 μm long and 3.36 μm width (see FIG. 42B). The area of the light-emitting device D2 is approximately 11.86 μm² and the perimeter is approximately 13.78 μm.

The light-emitting device D2 includes the electrode 551B, the layer 104B, the unit 103B, the intermediate layer 106B, the unit 103B2, the layer 105B, and the electrode 552B (see FIG. 42C). Note that the electrode 551B is formed over the layer REFB and the gap 551AB is provided between the electrodes 551B and 551A. The layer 573 is formed over the electrode 552B.

The layer REFB has the same structure as the layer REFA, and the electrode 551B contains ITSO. The gap 104AB is provided between the layers 104B and 104A. The layer 104B contains the same material as the layer 104A.

Each of the units 103B and 103B2 includes a layer having a hole-transport property, a layer containing a light-emitting material, and a layer having an electron-transport property. The units 103B and 103B2 emit green light. The intermediate layer 106B supplies electrons to the unit 103B and supplies holes to the unit 103B2. The layer 105B contains an electron-injection material. Note that the gap 103AB is provided between the units 103B and 103A. The gap 106AB is provided between the intermediate layers 106B and 106A.

### <<Structure of Light-Emitting Device D3>>

The light-emitting device D3 has a rectangular front surface with a size of 2.21 μm long and 3.36 μm width (see FIG. 42B). The area of the light-emitting device D3 is approximately 7.43 μm² and the perimeter is approximately 11.14 μm.

The light-emitting device D3 includes the electrode 551C, the layer 104C, the unit 103C, the intermediate layer 106C, the unit 103C2, the layer 105C, and the electrode 552C (see FIG. 42C). Note that the electrode 551C is formed over the layer REFC and a gap is provided between the electrodes 551C and 551B. The layer 573 is formed over the electrode 552C.

The layer REFC has the same structure as the layer REFA, and the electrode 551C contains ITSO. A gap is provided between the layers 104C and 104B. The layer 104C contains the same material as the layer 104A.

The units 103C and 103C2 each include a layer having a hole-transport property, a layer containing a light-emitting material, and a layer having an electron-transport property. The units 103C and 103C2 emit red light. The intermediate layer 106C supplies electrons to the unit 103C and supplies holes to the unit 103C2. The layer 105C contains an electron-injection material.

### <<Operation Characteristics of Light-Emitting Devices D1, D2, and D3>>

On the supply of electric power, the light-emitting devices D1, D2, and D3 emitted light. The operation characteristics of the light-emitting devices D1, D2, and D3 were measured at room temperature (see FIGS. 43 to 47). Note that luminance and emission spectra were measured with a spectroradiometer (SR-UL1R, produced by TOPCON TECHNOHOUSE CORPORATION).

The light-emitting devices D1, D2, and D3 exhibited favorable characteristics. For example, a wasted current flowing through the light-emitting devices D1, D2, and D3 at a voltage lower than the voltage at which light emission starts was able to be reduced. Furthermore, current that does not contribute to light emission was able to be reduced. Current flowing through side surfaces of the light-emitting devices at a voltage lower than the voltage at which light emission starts was able to be reduced. A current component that flows depending on the perimeters of the light-emitting devices at a voltage lower than the voltage at which light emission starts was able to be reduced. In addition, high current efficiency was exhibited in the range of 1 cd/m² to 10000 cd/m². In addition, favorable current density-voltage characteristics were exhibited with a voltage at which current starts to flow of 3 V to 5 V. Furthermore, an emission spectrum with no color mixture was obtained.

### <Fabrication Method of Workpiece WP>

The workpiece WP was fabricated using the method described in Embodiment 2. A supplementary explanation of the workpiece WP is provided below.

In Phase PH0, the insulating layer 521 was formed over the substrate 510 by a CVD method. Specifically, a film containing silicon oxide was formed over a silicon substrate.

Step 1 was skipped in Phase PH1, and a film to be the layers REFA, REFB, REFC, and REFE later was formed over the insulating layer 521 in Step 2 of Phase PH1, and the conductive film 551 was formed. Specifically, a 50-nm-thick film containing titanium, a 70-nm-thick film containing aluminum, a 2-nm-thick film containing titanium, and a 10-nm-thick film containing ITSO were stacked in this order by a sputtering method. After that, the layers REFA, REFB, REFC, and REFE, the electrodes 551A and 551B, the gap 551AB, the electrode 551C, and the conductive layer VCOM2 were formed. Specifically, a photolithography method was used.

The layer SCRE1 was not formed in Step 6 of Phase PH2A, and the layer SCRE1 was formed at the time of forming the layer SCRC1 in Step 6 of Phase PH2C.

In Step 3 of Phase PH3, the outer shape of each of the layers SCRA1, SCRB1, and SCRC1 was made smaller by an etching method using the photoresist PR. Specifically, a film containing tungsten was used as the layers SCRA1, SCRB1, SCRC1, and SCRE1, and a gas containing SF₆ was used for etching of the layers SCRA1, SCRB1, SCRC1, and SCRE1. A film containing aluminum oxide was used as the layers SCRA2, SCRB2, SCRC2, and SCRE2, and a gas containing CHF₃, He, and CH₄ was used for etching of the layers SCRA2, SCRB2, SCRC2, and SCRE2.

In Step 2 of Phase PH5, the conductive film 552 was formed by a resistance-heating method. Specifically, a 15-nm-thick film containing silver (Ag) and magnesium (Mg) at a volume ratio of Ag:Mg=1:0.1 was deposited by co-evaporation. In Step 3 of Phase PH5, the layer 573 was formed by a sputtering method. Specifically, a 70-nm-thick film containing ITO was formed.

### Example 2

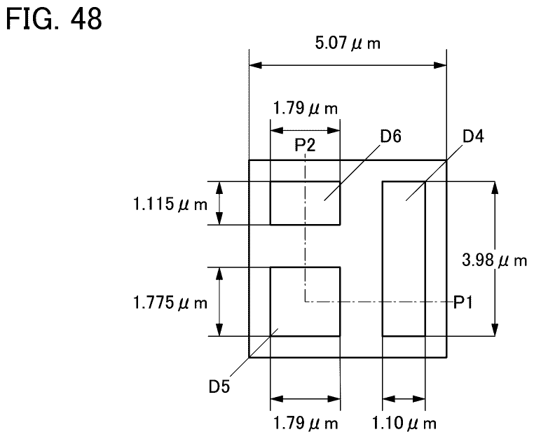

FIG. 48 is a top view illustrating a structure of a workpiece different from that of the workpiece illustrated in FIG. 42A.

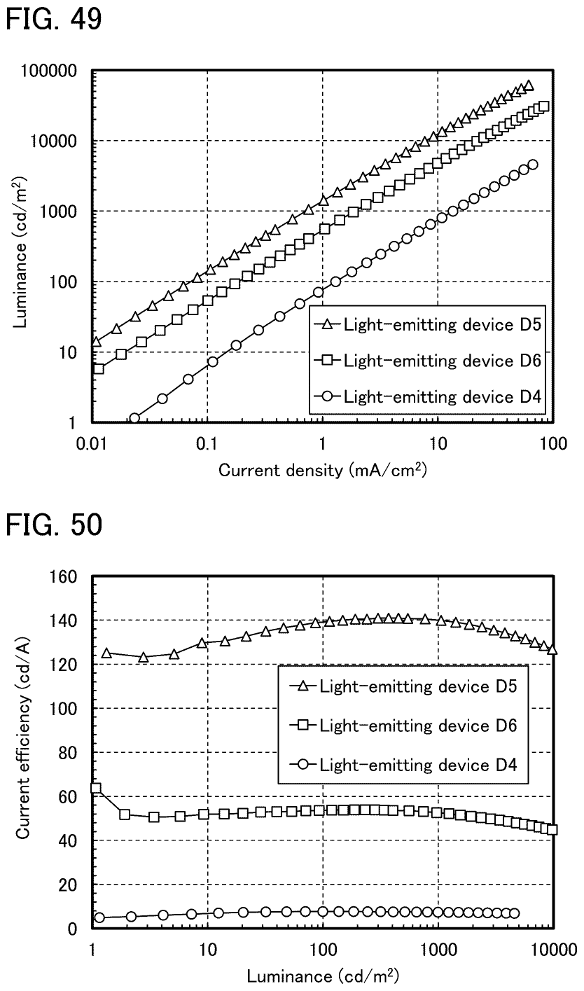

FIG. 49 shows current density-luminance characteristics of light-emitting devices fabricated in this example.

FIG. 50 shows luminance-current efficiency characteristics of the light-emitting devices fabricated in this example.

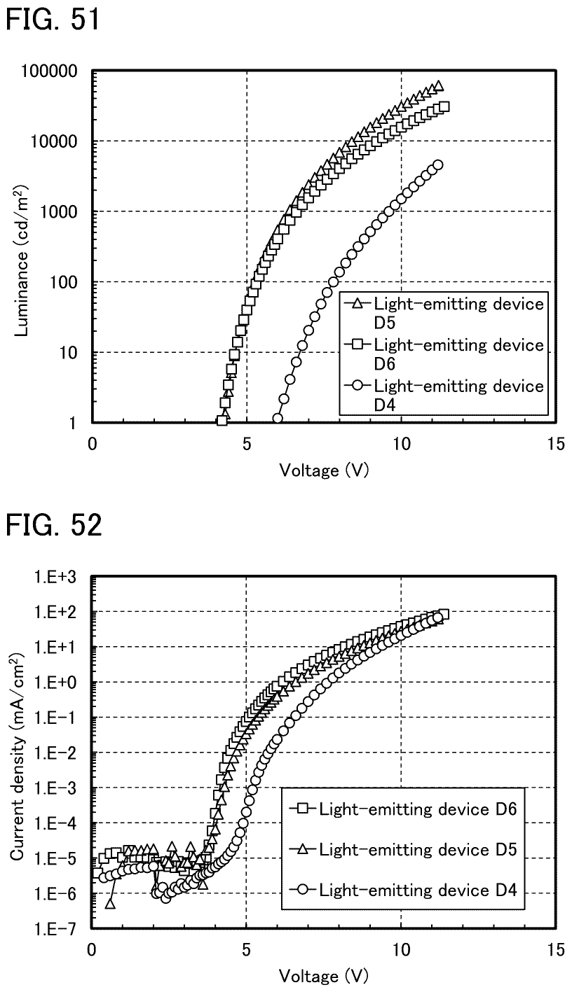

FIG. 51 shows voltage-luminance characteristics of the light-emitting devices fabricated in this example.

FIG. 52 shows voltage-current density characteristics of the light-emitting devices fabricated in this example.

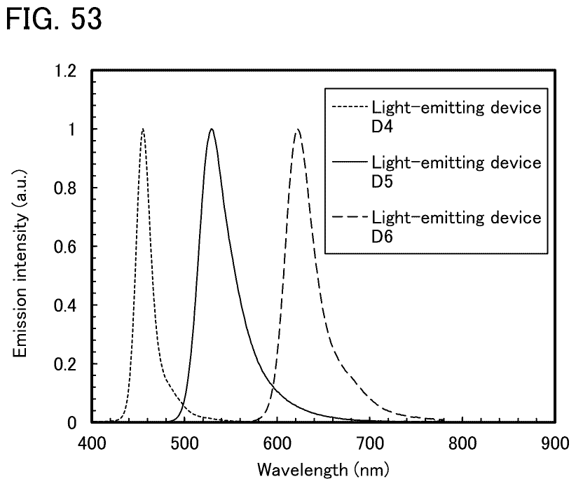

FIG. 53 shows emission spectra of the light-emitting devices fabricated in this example emitting light at a luminance of 1000 cd/m².

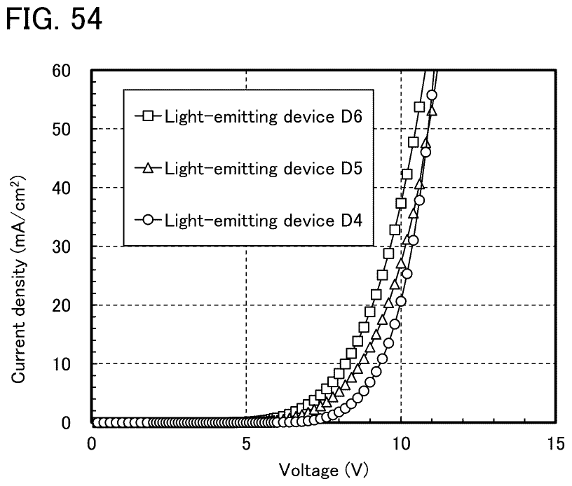

FIG. 54 shows voltage-current density characteristics of the light-emitting devices fabricated in this example.

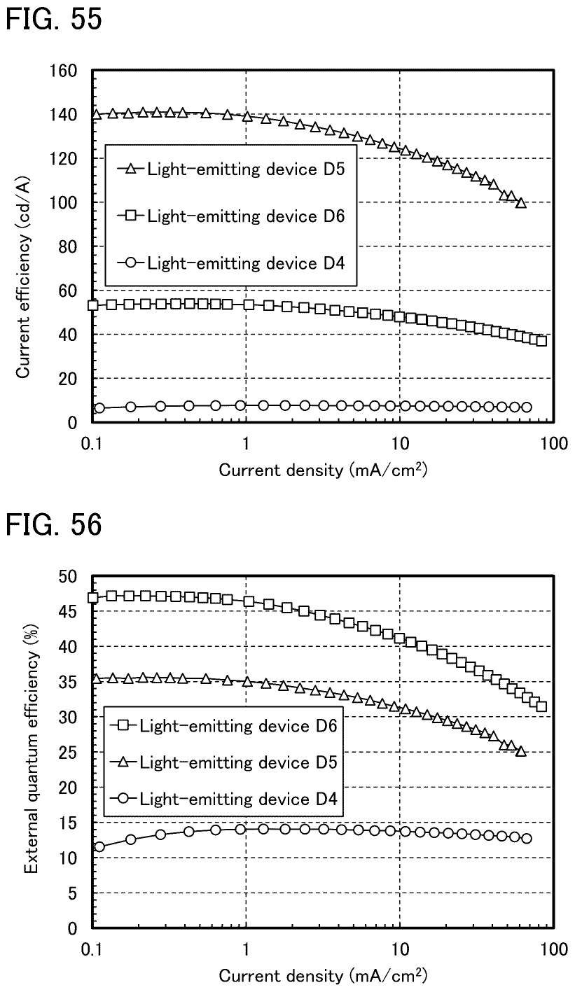

FIG. 55 shows current density-current efficiency characteristics of the light-emitting devices fabricated in this example.

FIG. 56 shows current density-external quantum efficiency characteristics of the light-emitting devices fabricated in this example.

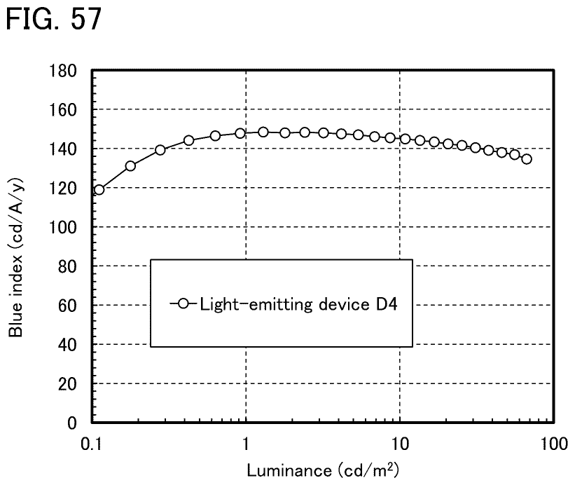

FIG. 57 shows luminance-blue index characteristics of the light-emitting devices fabricated in this example. Note that the blue index (BI) is one of the indicators of characteristics of a blue light-emitting device, and is a value obtained by dividing current efficiency (cd/A) by chromaticity y. In general, blue light with high color purity is useful in expressing a wide color gamut. In addition, blue light with higher color purity tends to have lower chromaticity y. Thus, a value obtained by dividing current efficiency (cd/A) by chromaticity y is the indicator of usefulness of a blue light-emitting device. In other words, a blue light-emitting device with a large BI is suitable for providing a highly efficient display device capable of displaying an image with a wide color gamut.

### <Example 2 Of Workpiece WP>

A fabricated workpiece WP that is described in this example includes the pixel set 703. The pixel set 703 includes light-emitting devices D4, D5, and D6 (see FIG. 48). Note that the pixel set 703 of the workpiece WP described in this example is smaller than that described in Example 1. The workpiece WP described in this example includes the pixel set 703 with a resolution of 5009 ppi. Different portions are described in detail here, and the above description is referred to for portions that have similar structures.

### <<Structure of Light-Emitting Device D4>>

The light-emitting device D4 has a rectangular front surface with a size of 3.98 μm long and 1.10 μm width (see FIG. 48). The area of the light-emitting device D4 is approximately 4.38 μm², and the perimeter is approximately 10.16 μm. Like the light-emitting device D1, the light-emitting device D4 includes two units that emit blue light.

### <<Structure of Light-Emitting Device D5>>

The light-emitting device D5 has a rectangular front surface with a size of 1.775 μm length and 1.79 μm width (see FIG. 48). The area of the light-emitting device D5 is approximately 3.18 μm², and the perimeter is approximately 7.13 μm. Like the light-emitting device D2, the light-emitting device D5 includes two units that emit green light.

### <<Structure of Light-Emitting Device D6>>

The light-emitting device D6 has a rectangular front surface with a size of 1.115 μm length and 1.79 μm width (see FIG. 48). The area of the light-emitting device D6 is approximately 2.00 μm², and the perimeter is approximately 5.81 μm. Like the light-emitting device D3, the light-emitting device D6 includes two units that emit red light.

### <<Operation Characteristics of Light-Emitting Devices D4, D5, and D6>>

On the supply of electric power, the light-emitting devices D4, D5, and D6 emitted light. The operation characteristics of the light-emitting devices D4, D5, and D6 were measured at room temperature (see FIGS. 49 to 57). Note that luminance and emission spectra were measured with a spectroradiometer (SR-UL1R manufactured by TOPCON TECHNOHOUSE CORPORATION).

The light-emitting devices D4, D5, and D6 exhibited favorable characteristics. Table 1 shows typical operation characteristics. Note that the blue index of the light-emitting device D4 was 145.1 (cd/A/y) at a current density of 10 mA/cm².

TABLE 1

| | | | | External |
|---|---|---|---|---|
| | Current | | Current | quantum |
| | density | Voltage | efficiency | efficiency |
| | mA/cm² | V | cd/A | % |
| Light-emitting device D4 | 10 | 9.32 | 7.45 | 13.8 |
| Light-emitting device D5 | 10 | 8.70 | 124.4 | 31.3 |
| Light-emitting device D6 | 10 | 8.21 | 47.9 | 41.1 |

For example, a wasted current flowing through the light-emitting devices D4, D5, and D6 at a voltage lower than the voltage at which light emission starts was able to be reduced. Current that does not contribute to light emission was able to be reduced. Current flowing through side surfaces of the light-emitting devices at a voltage lower than the voltage at which light emission starts was able to be reduced. A current component that flows depending on the perimeters of the light-emitting devices at a voltage lower than the voltage at which light emission starts was able to be reduced. In addition, high current efficiency was exhibited in the range of 1 cd/m² to 10000 cd/m². In addition, favorable current density-voltage characteristics were with a voltage at which current starts to flow of 3 V to 5 V. Furthermore, an emission spectrum with no color mixture was obtained.

### <Method for Fabricating Workpiece WP>

The workpiece WP was fabricated by a method similar to that described in Embodiment 2.

This application is based on Japanese Patent Application Serial No. 2024-030328 filed with Japan Patent Office on Feb. 29, 2024 and Japanese Patent Application Serial No. 2024-192652 filed with Japan Patent Office on Nov. 1, 2024, the entire contents of which are hereby incorporated by reference.

What is claimed is:

1. A method for manufacturing a display device, the method comprising:
a first phase;
a second phase;
a third phase;
a fourth phase;
a fifth phase; and
a sixth phase,
wherein in the first phase, a first electrode, a second electrode, and a first gap are formed over an insulating layer,
wherein the first gap is sandwiched between the first electrode and the second electrode,
wherein in a first step of the second phase, a first film is formed over the first electrode and the second electrode,
wherein in a second step of the second phase, a second film is formed over the first film,
wherein in a third step of the second phase, a third film is formed over the second film,
wherein in a fourth step of the second phase, a fourth film is formed over the third film,
wherein in a fifth step of the second phase, the fourth film is removed from above the second electrode by a photolithography method to form a first layer overlapping with the first electrode,
wherein in a sixth step of the second phase, the third film and the second film are removed from above the second electrode by an etching method using the first layer to form a second layer, a first unit, and a third layer,
wherein the second layer is sandwiched between the first layer and the first electrode,
wherein the first unit is sandwiched between the second layer and the first electrode,
wherein in a first step of the third phase, a fifth film is formed over the first layer and the second electrode,
wherein in a second step of the third phase, a sixth film is formed over the fifth film,
wherein in a third step of the third phase, a seventh film is formed over the sixth film,
wherein in a fourth step of the third phase, an eighth film is formed over the seventh film,
wherein in a fifth step of the third phase, the eighth film is removed from above the first layer by a photolithography method to form a fourth layer overlapping with the second electrode,
wherein in a sixth step of the third phase, the seventh film and the sixth film are removed from above the first layer and the first gap by an etching method using the fourth layer to form a fifth layer, a second unit, a sixth layer, and a second gap,
wherein the fifth layer is sandwiched between the fourth layer and the second electrode,
wherein the second unit is sandwiched between the fifth layer and the second electrode,
wherein the second gap overlaps with the first gap,
wherein in a first step of the fourth phase, a ninth film is formed and then a photoresist is formed,
wherein in a second step of the fourth phase, a seventh layer and an eighth layer are formed by an etching method using the photoresist,
wherein the seventh layer overlaps with the first electrode and comprises an outer shape smaller than an outer shape of the first layer,
wherein the eighth layer overlaps with the second electrode and comprises an outer shape smaller than an outer shape of the fourth layer,
wherein in a third step of the fourth phase, the outer shape of the first layer and the outer shape of the fourth layer are made smaller by an etching method using the seventh layer and the eighth layer,
wherein in a fourth step of the fourth phase, an outer shape of each of the second layer, the fifth layer, the first unit, the second unit, the third layer, and the sixth layer is made smaller by an etching method using the first layer and the fourth layer,
wherein in a fifth step of the fourth phase, the first layer and the fourth layer are removed by an etching method,
wherein in a first step of the fifth phase, a ninth layer is formed,
wherein the ninth layer is in contact with the insulating layer in the first gap and covers the first unit and the second unit,
wherein in a second step of the fifth phase, a tenth layer is formed,
wherein the tenth layer fills the first gap and the second gap,
wherein the tenth layer comprises a first opening portion overlapping with the first electrode and a second opening portion overlapping with the second electrode,
wherein in a third step of the fifth phase, by an etching method using the tenth layer, the ninth layer and the second layer overlapping with the first opening portion are removed, and the ninth layer and the fifth layer overlapping with the second opening portion are removed,
wherein in a first step of the sixth phase, an eleventh layer is formed over the first unit and the second unit, and
wherein in a second step of the sixth phase, a conductive film is formed over the eleventh layer.

2. The method for manufacturing a display device according to claim 1,
wherein in a first step of the first phase, a tenth film is formed over the insulating layer,
wherein in a second step of the first phase, the first electrode, the second electrode, and the first gap are formed over the tenth film,
wherein the first gap is sandwiched between the first electrode and the second electrode,
wherein in the fifth step of the fourth phase, the first layer, the fourth layer, and the tenth film are removed by an etching method to form a twelfth layer, a thirteenth layer, and a third gap,
wherein the twelfth layer is sandwiched between the first electrode and the insulating layer,
wherein the thirteenth layer is sandwiched between the second electrode and the insulating layer, and
wherein the third gap overlaps with the first gap.

3. A display device comprising:
a first light-emitting device;
a second light-emitting device; and
an insulating layer,
the first light-emitting device comprising:
a first electrode;
a second electrode;
a first unit; and
a first layer,
the second light-emitting device comprising:
a third electrode;
a fourth electrode;
a second unit; and
a second layer,
wherein the first electrode is over the insulating layer,
wherein the first unit is sandwiched between the first electrode and the second electrode,
wherein the first unit comprises a first light-emitting material,
wherein the first unit has a first side surface,
wherein the first layer is sandwiched between the first electrode and the first unit,
wherein the first layer is in contact with the first electrode,
wherein the first layer comprises a carrier-injection material,
wherein the first layer has a higher concentration of the carrier-injection material than the first side surface,
wherein the third electrode is over the insulating layer,
wherein the third electrode is adjacent to the first electrode,
wherein a first gap is between the third electrode and the first electrode,
wherein the second unit is sandwiched between the second layer and the fourth electrode,
wherein the second unit comprises a second light-emitting material,
wherein a second gap is between the second unit and the first unit,
wherein the second gap overlaps with the first gap,
wherein the second unit has a second side surface,
wherein the second side surface faces the first side surface,
wherein the second layer is sandwiched between the third electrode and the second unit,
wherein the second layer is in contact with the third electrode,
wherein a third gap is between the second layer and the first layer,
wherein the third gap overlaps with the first gap,
wherein the second layer comprises the carrier-injection material, and
wherein the second layer has a higher concentration of the carrier-injection material than the second side surface.

4. The display device according to claim 3, wherein in etching treatment using an oxygen-containing gas, an etching rate of the insulating layer is lower than an etching rate of the first unit.

5. The display device according to claim 3, further comprising:
a third layer; and
a fourth layer,
wherein the first electrode comprises a region sandwiched between the first layer and the third layer,
wherein the third electrode comprises a region sandwiched between the second layer and the fourth layer,
wherein the third layer comprises a region sandwiched between the first electrode and the insulating layer,
wherein in etching treatment using an oxygen-containing gas, an etching rate of the third layer is lower than an etching rate of the first unit,
wherein the third layer has conductivity,
wherein the fourth layer comprises a region sandwiched between the third electrode and the insulating layer,
wherein the fourth layer is adjacent to the third layer,
wherein a fourth gap is between the fourth layer and the third layer, and
wherein the fourth layer comprises a material identical to a material of the third layer.

6. The display device according to claim 3, further comprising:
a fifth layer;
a sixth layer; and
a conductive film,
wherein the fifth layer overlaps with the first gap,
wherein the fifth layer is in contact with the insulating layer,
wherein the fifth layer comprises a first opening portion and a second opening portion,
wherein the first opening portion overlaps with the first electrode,
wherein the second opening portion overlaps with the third electrode,
wherein the sixth layer fills the first gap and the second gap,
wherein the sixth layer is sandwiched between the conductive film and the fifth layer,
wherein the sixth layer comprises a third opening portion and a fourth opening portion,
wherein the third opening portion overlaps with the first electrode,
wherein the fourth opening portion overlaps with the third electrode, and
wherein the conductive film comprises the second electrode and the fourth electrode.

7. A display module comprising:
the display device according to claim 3; and
at least one of a connector and an integrated circuit.

8. An electronic device comprising:
the display device according to claim 3; and
at least one of a battery, a camera, a speaker, and a microphone.
